(19) United States
(12) Patent Application Publication
(10) Pub. No.: US 2014/0087483 A1
(43) Pub. Date: Mar. 27, 2014

(54) MANUFACTURING METHOD OF MAGNETORESISTIVE EFFECT ELEMENT AND MANUFACTURING APPARATUS OF MAGNETORESISTIVE EFFECT ELEMENT

(71) Applicant: KABUSHIKI KAISHA TOSHIBA, Tokyo (JP)

(72) Inventors: Yuichi OHSAWA, Yokohama-shi (JP); Junichi Ito, Yokohama-shi (JP); Saori Kashiwada, Yokohama-shi (JP); Chikayoshi Kamata, Kawasaki-shi (JP); Naoki Tamaoki, Tokyo (JP)

(73) Assignee: Kabushiki Kaisha Toshiba, Tokyo (JP)

(21) Appl. No.: 13/847,069

(22) Filed: Mar. 19, 2013

(30) Foreign Application Priority Data
Sep. 25, 2012 (JP) 2012-211521

(51) Int. Cl. H01L 43/12

(52) U.S. Cl. CPC H01L 43/12
USPC 438/3; 156/345.4

(57) ABSTRACT

According to one embodiment, a manufacturing method of a magnetoresistive effect element includes forming a laminated structure on a substrate, the laminated structure including a first magnetic layer having a variable magnetization direction, a second magnetic layer having an invariable magnetization direction, and a non-magnetic layer between the first and second magnetic layers, forming a first mask layer having a predetermined plane shape on the laminated structure, and processing the laminated structure based on the first mask layer by using an ion beam whose solid angle in a center of the substrate is 10° or more.

### CROSS-REFERENCE TO RELATED APPLICATIONS

This application is based upon and claims the benefit of priority from Japanese Patent Application No. 2012-211521, filed Sep. 25, 2012, the entire contents of which are incorporated herein by reference.

### FIELD

Embodiments described herein relate generally to a manufacturing method of a magnetoresistive effect element and a manufacturing apparatus of a magnetoresistive effect element.

### BACKGROUND

Memory devices using magnetism such as hard disk drives (HDD) and magnetoresistive random access memories (MRAM) have been developed.

“Spin transfer switching” that reverses the orientation of magnetization of a magnetic body by passing a current through the magnetic body as a technology applied to MRAM is studied as one method of writing data to an MRAM. The spin transfer switching is a technology that reverses the orientation of magnetization of a magnetic body (magnetic layer) in a magnetoresistive effect element by passing a write current into the magnetoresistive effect element and using spin-polarized electrons generated therein. Using such spin transfer switching makes it easier to control the magnetized state in a nano-scale magnetic body by a local magnetic field and further can reduce the value of the current needed to reverse the magnetization in accordance with minuteness of the magnetic body.

The development of MRAM for high storage density is promoted by using the spin transfer switching. Thus, forming a magnetoresistive effect element as a memory element in an element size of 30 nm or less is desired.

Materials containing magnetic metals like Co and Fe used for a magnetoresistive effect element are generally difficult to dry-etch (for example, RIE) and thus are frequently etched physically by irradiation of an ion beam using an inert gas such as Ar.

### BRIEF DESCRIPTION OF THE DRAWINGS

FIG. 1 is a sectional view showing the structure of a magnetoresistive effect element according to a first embodiment;

FIGS. 2 to 6 are sectional views showing a process of a manufacturing method of the magnetoresistive effect element according to the first embodiment;

FIGS. 7A and 7B are diagrams illustrating irradiation of a processed layer with an ion beam;

FIGS. 8A and 8B are diagrams illustrating irradiation of the processed layer with the ion beam;

FIGS. 9A and 9B are diagrams illustrating a solid angle of the ion beam;

FIG. 10 is a diagram illustrating an incident angle and the solid angle of the ion beam;

FIG. 11 is a diagram showing a relationship between the solid angle of the ion beam and a short probability of the element;

FIGS. 12 and 13 are diagrams illustrating the energy of the ion beam output by an ion source;

FIG. 14 is a diagram showing the relationship between properties of the ion beam and magnetic properties of a magnetic body;

FIGS. 15A and 15B are diagrams showing a physical relationship between the processed layer and the ion source and a distribution of the ion beam;

FIG. 16 is a diagram showing the relationship between properties of the ion beam and magnetic properties of the magnetic body;

FIGS. 17A and 17B are diagrams showing a manufacturing apparatus of the magnetoresistive effect element according to the first embodiment;

FIGS. 18A, 18B and 18C are diagrams showing a manufacturing apparatus of the magnetoresistive effect element according to the first embodiment;

FIGS. 19A, 19B and 19C are diagrams showing a manufacturing apparatus of the magnetoresistive effect element according to the first embodiment;

FIGS. 20A and 20B are diagrams showing a manufacturing apparatus of the magnetoresistive effect element according to the first embodiment;

FIGS. 21A, 21B, 21C, 21D, 21E, 21F and 21G are diagrams showing a manufacturing apparatus of the magnetoresistive effect element according to the first embodiment;

FIGS. 22A and 22B are diagrams showing a manufacturing apparatus of the magnetoresistive effect element according to the first embodiment;

FIGS. 23A and 23B are diagrams showing a manufacturing apparatus of the magnetoresistive effect element according to the first embodiment;

FIGS. 24A, 24B and 24C are diagrams showing a manufacturing apparatus of the magnetoresistive effect element according to the first embodiment;

FIGS. 25A, 25B and 25C are diagrams showing a manufacturing apparatus of the magnetoresistive effect element according to the first embodiment;

FIGS. 26A and 26B are diagrams showing a manufacturing apparatus of the magnetoresistive effect element according to the first embodiment;

FIGS. 27A, 27B and 27C are diagrams showing a manufacturing apparatus of the magnetoresistive effect element according to the first embodiment;

FIGS. 28A and 28B are diagrams showing a manufacturing apparatus of the magnetoresistive effect element according to the first embodiment;

FIGS. 29A and 29B are diagrams showing a manufacturing apparatus of the magnetoresistive effect element according to the first embodiment;

FIGS. 30A, 30B and 30C are diagrams showing a manufacturing apparatus of the magnetoresistive effect element according to the first embodiment;

FIGS. 31A, 31B, 31C, 31D and 31E are diagrams showing a manufacturing apparatus of the magnetoresistive effect element according to the first embodiment;

FIGS. 32A and 32B are diagrams showing a manufacturing apparatus of the magnetoresistive effect element according to the first embodiment;

FIGS. 33 and 34 are diagrams showing a manufacturing apparatus of the magnetoresistive effect element according to the first embodiment;

FIGS. 35A, 35B, 35C and 35D are diagrams showing a manufacturing apparatus of the magnetoresistive effect element according to the first embodiment;

FIG. 36 is diagram showing a manufacturing apparatus of the magnetoresistive effect element according to the first embodiment;

FIGS. 37A and 37B are diagrams showing a manufacturing apparatus of the magnetoresistive effect element according to the first embodiment;

FIGS. 38 and 39 are diagrams showing a manufacturing apparatus of the magnetoresistive effect element according to the first embodiment;

FIGS. 40A, 40B, 40C and 40D are diagrams showing a manufacturing apparatus of the magnetoresistive effect element according to the first embodiment;

FIGS. 41A, 41B and 41C are diagrams showing a manufacturing apparatus of the magnetoresistive effect element according to the first embodiment;

FIGS. 42A and 42B are diagrams showing a manufacturing apparatus of the magnetoresistive effect element according to the first embodiment;

FIGS. 43A and 43B are diagrams showing a manufacturing apparatus of the magnetoresistive effect element according to the first embodiment;

FIGS. 44 to 48 are diagrams showing an application example of the manufacturing apparatus of the magnetoresistive effect element according to the first embodiment;

FIG. 49 is a sectional view showing the structure of a magnetoresistive effect element according to a second embodiment;

FIGS. 50 to 54 are sectional views showing a process of the manufacturing method of the magnetoresistive effect element according to the second embodiment;

FIG. 55 is a sectional view showing the structure of the magnetoresistive effect element according to the second embodiment;

FIGS. 56 and 57 are sectional views showing a process of the manufacturing method of the magnetoresistive effect element according to the second embodiment;

FIGS. 58 and 59 are diagrams showing a magnetoresistive memory as an application example of an embodiment;

FIGS. 60A, 60B and 60C are diagrams showing a modification example of an embodiment;

FIGS. 61A and 61B are diagrams showing a design example of a manufacturing apparatus of the magnetoresistive effect element according to the embodiment;

FIGS. 62A, 62B and 62C are diagrams showing a design example of a manufacturing apparatus of the magnetoresistive effect element according to the embodiment;

FIGS. 63A, 63B and 63C are diagrams showing a design example of a manufacturing apparatus of the magnetoresistive effect element according to the embodiment;

FIG. 64 is diagram showing a design example of a manufacturing apparatus of the magnetoresistive effect element according to the embodiment;

FIGS. 65A, 65B, 65C and 65D are diagrams showing a design example of a manufacturing apparatus of the magnetoresistive effect element according to the embodiment;

FIGS. 66A, 66B, 66C, 66D, 66E, 66F and 66G are diagrams showing a design example of a manufacturing apparatus of the magnetoresistive effect element according to the embodiment;

FIGS. 67A, 67B, 67C, 67D and 67E are diagrams showing a design example of a manufacturing apparatus of the magnetoresistive effect element according to the embodiment;

FIGS. 68 and 69 are diagrams showing a design example of a manufacturing apparatus of the magnetoresistive effect element according to the embodiment;

FIGS. 70A, 70B, 70C and 70D are diagrams showing a design example of a manufacturing apparatus of the magnetoresistive effect element according to the embodiment;

FIGS. 71A and 71B are diagrams showing a design example of a manufacturing apparatus of the magnetoresistive effect element according to the embodiment;

FIGS. 72A and 72B are diagrams showing a design example of a manufacturing apparatus of the magnetoresistive effect element according to the embodiment;

FIGS. 73, 74 and 75 are diagrams showing a design example of a manufacturing apparatus of the magnetoresistive effect element according to the embodiment;

FIGS. 76A and 76B are diagrams showing a design example of a manufacturing apparatus of the magnetoresistive effect element according to the embodiment;

FIGS. 77A, 77B and 77C are diagrams showing a design example of a manufacturing apparatus of the magnetoresistive effect element according to the embodiment;

FIG. 78 is diagram showing a design example of a manufacturing apparatus of the magnetoresistive effect element according to the embodiment;

FIGS. 79A, 79B and 79C are diagrams showing a design example of a manufacturing apparatus of the magnetoresistive effect element according to the embodiment;

FIGS. 80 and 81 are diagrams showing a design example of a manufacturing apparatus of the magnetoresistive effect element according to the embodiment;

FIGS. 82A and 82B are diagrams showing a design example of a manufacturing apparatus of the magnetoresistive effect element according to the embodiment;

FIGS. 83, 84 and 85 are diagrams showing a design example of a manufacturing apparatus of the magnetoresistive effect element according to the embodiment; and

FIGS. 86A and 86B are diagrams showing a design example of a manufacturing apparatus of the magnetoresistive effect element according to the embodiment.

### DETAILED DESCRIPTION

Hereinafter, embodiments will be described in detail with reference to the drawings. In the following description, elements having the same function and constitution are denoted with the same signs, and repeated descriptions will be made if necessary.

In general, according to one embodiment, forming a laminated structure on a substrate, the laminated structure including a first magnetic layer having a variable magnetization direction, a second magnetic layer having an invariable magnetization direction, and a non-magnetic layer between the first and second magnetic layers; forming a first mask layer having a predetermined plane shape on the laminated structure; and processing the laminated structure based on the first mask layer by using an ion beam whose solid angle in a center of the substrate is 10° or more.

### [A] First Embodiment

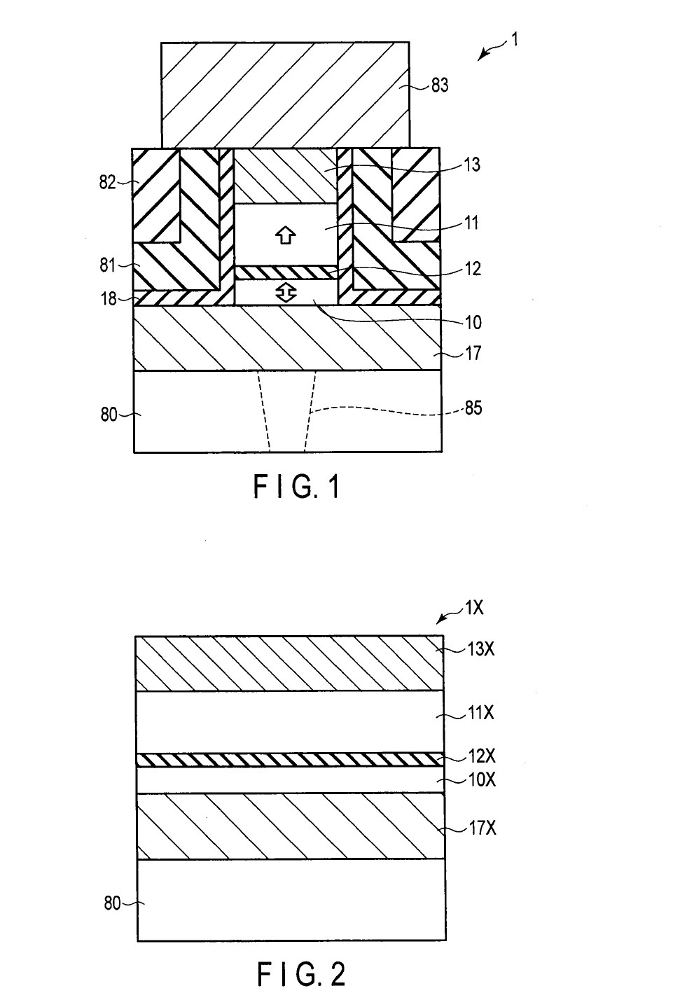

A manufacturing method of a magnetoresistive effect element according to a first embodiment and a manufacturing apparatus of the magnetoresistive effect element will be described with reference to FIGS. 1 to 48.

### (1) Configuration Example 1

(a) Structure

The basic structure of a magnetoresistive effect element formed according to the present embodiment will be described by using FIG. 1.

FIG. 1 shows a sectional structure of a magnetoresistive effect element 1 formed by the manufacturing method and the manufacturing apparatus of a magnetoresistive effect element according to the first embodiment.

The magnetoresistive effect element 1 includes a laminated structure formed from a foundation layer 17 including a lower electrode, an upper electrode 13, two magnetic layers 10, 11 provided between the upper electrode 13 and the foundation layer 17, and a non-magnetic layer (tunnel barrier layer) 12 provided between the two magnetic layers 10, 11.

The two magnetic layers 10, 11 and the tunnel barrier layer 12 sandwiched therebetween form a magnetic tunnel junction. The magnetoresistive effect element may also be called an MTJ element below.

The arrow in each of the magnetic layers 10, 11 in FIG. 1 indicates the direction of magnetization of each of the magnetic layers 10, 11.

The direction of magnetization of the one magnetic layer 10 of the two magnetic layers is variable and the direction of magnetization of the other magnetic layer 11 is fixed (invariable). The magnetic layer 10 in which the direction of magnetization is variable is called a storage layer (or a recording layer or a magnetizing free layer) and the magnetic layer 11 in which the direction of magnetization is fixed is called a reference layer (or a fixed layer or a magnetizing invariable layer).

The direction of magnetization (or spins) of the storage layer 10 is reversed by the transfer of angular momentum of spin-polarized electrons generated by supplying a current to reverse the direction of magnetization (spin) of the storage layer 10 when the current flowing in a direction perpendicular to the film surface of the magnetic layer 10 (lamination direction of the magnetic layer) is supplied to the storage layer 10. That is, the direction of magnetization of the storage layer 10 varies in accordance with the orientation in which a current flows.

In contrast, the direction of magnetization of the reference layer 11 is fixed and invariable. That the direction of magnetization of the reference layer 11 is “invariable” or “fixed” means that the direction of magnetization of the reference layer 11 does not change when a magnetic reversing current to reverse the direction of magnetization of the storage layer 10 flows through the reference layer 11.

Therefore, the magnetoresistive effect element 1 including the storage layer 10 in which the direction of magnetization is variable and the reference layer 11 in which the direction of magnetization is invariable is formed by using a magnetic layer in which the magnetic reversing current is large as the reference layer and a magnetic layer in which the magnetic reversing current is smaller than that of the reference layer 11 as the storage layer 10 in the magnetoresistive effect element 1.

When the magnetic reversal is caused by spin-polarized electrons, the magnitude of the magnetic reversing current (magnetic reversal threshold) is proportional to the attenuation constant of a magnetic layer, an anisotropic magnetic field, and the volume and thus, a difference between the magnetic reversing current of the storage layer 10 and the magnetic reversing current of the reference layer 11 can be provided by appropriately adjusting these values.

When the magnetic reversing current of the storage layer is supplied to a magnetoresistive effect element (MTJ element), the orientation of magnetization of the storage layer changes in accordance with the direction in which the current flows and a relative magnetic arrangement between the storage layer and the reference layer changes. Accordingly, the magnetoresistive effect element 1 is in one of a high resistance state (the magnetic arrangement is antiparallel) and a low resistance state (the magnetic arrangement is parallel).

As shown in FIG. 1, the storage layer 10 and the reference layer 11 have magnetic anisotropy in a direction perpendicular to the film surface of each of the magnetic layers 10, 11 (or the lamination direction of magnetic layers). The easy-magnetization direction of the storage layer 10 and the reference layer 11 is perpendicular to the film surface of magnetic layers. In the easy-magnetization direction (magnetic anisotropy) as a direction perpendicular to the film surface, magnetization oriented in a direction perpendicular to the film surface is called perpendicular magnetization.

The magnetoresistive effect element 1 in the present embodiment is a perpendicular magnetic magnetoresistive effect element in which the storage layer 10 and the reference layer 11 are each perpendicular to the film surface.

When a ferromagnetic body of a certain macro size is assumed, the easy-magnetization direction is a direction having the lowest internal energy when the spontaneous magnetization is in that direction without any external magnetic field given. On the other hand, when a ferromagnetic body of a certain macro size is assumed, a hard-magnetization direction is a direction having the highest internal energy when the spontaneous magnetization is in that direction without any external magnetic field given.

As the material of the storage layer 10, a ferromagnetic material such as FePd, FePt, CoPd, or CoPt, a Co—Fe alloy, a Co—Fe alloy to which boron (B) is added or the like is used. The storage layer 10 may have an artificial lattice formed from a magnetic material (for example, NiFe, Fe, or Co) and a non-magnetic material (Cu, Pd, or Pt).

As the material of the reference layer 11, for example, a ferromagnetic material having an L1₀ structure or L1₁ structure such as FePd, FePt, CoPd, or CoPt, a soft magnetic material such as CoFeB, or a ferrimagnetic material such as TbCoFe is used. Like the storage layer 10, an artificial lattice may be used for the reference layer 11.

As the tunnel barrier layer 12, an insulating material such as magnesium oxide (MgO), magnesium nitride (MgN), aluminum oxide (Al₂O₃), aluminum nitride, or a laminated film thereof is used. In addition, boron may be added to these films.

The MTJ element 1 in the present embodiment is a top-pin MTJ element. That is, the storage layer 10 is provided on the foundation layer 17 and the reference layer 11 is stacked on the storage layer 10 via the tunnel barrier layer 12.

The foundation layer 17 is provided on a substrate 80. The foundation layer 17 crystal-orients the magnetic layer (here, the storage layer) 10.

For example, the foundation layer 17 is a layer serving as a lower electrode and also a leader of the magnetoresistive effect element. The foundation layer 17 includes a thick metallic film as a lower electrode and a buffer layer to allow a flat magnetic layer of vertical magnetization to grow. However, a laminated film may be formed from the foundation layer and the lower electrode as separate films or the foundation layer and the lower electrode may be formed from a film with a leader formed separately.

The foundation layer 17 as an example has a laminated structure in which metallic layers of tantalum (Ta), copper (Cu), ruthenium (Ru), iridium (Ir) or the like are stacked.

The upper electrode 13 is provided on the reference layer 11. The upper electrode 13 also has a function as a hard mask to form a magnetoresistive effect element. For example, Ta is used for the upper electrode 13.

A sidewall insulating film 18 is provided on the sidewall of the MTJ element 1. The MTJ element 1 is covered with insulating films 81, 82 via the sidewall insulating film 18.

In order to bring the magnetic field (shift magnetic field) from the reference layer 11 to the storage layer 10 close to zero, a magnetic film (called a shift correction layer or a bias magnetic layer) may be provided next to the reference layer 11 to reduce the amount of magnetization of the reference layer 11. The magnetization of the shift correction layer is fixed and the orientation of magnetization of the shift correction layer is set to the opposite direction of magnetization of the reference layer 11.

For example, the magnetoresistive effect element 1 in FIG. 1 is used as a memory element of a magnetoresistive memory (for example, MRAM). An MRAM includes at least a memory cell. When an MRAM includes a plurality of memory cells, the memory cells are arranged in a matrix form in a memory cell array. The memory cell includes at least a magnetoresistive effect element (MTJ element) as a memory element. For example, “1” data and “0” data are allocated to the high resistance state and the low resistance state of the MTJ element.

If, for example, the substrate 80 is the inter-layer insulating film 80, the inter-layer insulating film 80 covers an element (for example, a MOS transistor) on the semiconductor substrate. A contact plug 85 connected to the lower electrode 17 is provided in the inter-layer insulating film 80 as the substrate 80. An interconnect (for example, a bit line) 83 is provided on the insulating films 81, 82 and on the upper electrode 13 of the MTJ element 1.

The contact plug 85 is formed from tungsten (W) and molybdenum (Mo). The interconnect 83 is formed from aluminum (Al) and copper (Cu).

(b) Manufacturing Method

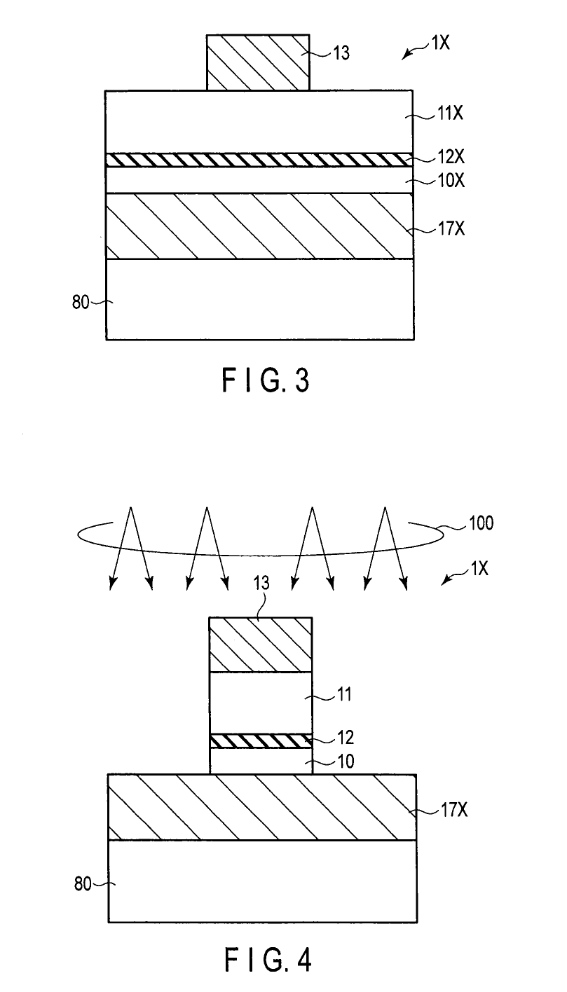

The manufacturing method of a magnetoresistive effect element according to the embodiment will be described with reference to FIGS. 2 to 6. FIGS. 2 to 6 are sectional process drawings showing each process of the manufacturing method of a magnetoresistive effect element according to the embodiment. The manufacturing method of a magnetoresistive effect element according to the present embodiment will be described by appropriately using FIG. 1, in addition to FIGS. 2 to 6.

As shown in FIG. 2, a conductive layer (foundation layer) 17X, a magnetic layer (here, a storage layer) 10X, a tunnel barrier layer 12X, a magnetic layer (here, a reference layer) 11X, and a hard mask (conductive layer) 13X are successively formed on the substrate 80 by, for example, a sputtering process. A laminated structure 1X to form a magnetoresistive effect element (MTJ element) is formed on the substrate 80.

The foundation layer 17X is a layer to allow the perpendicular magnetic film (storage layer) 10X having a flat film surface to grow and is formed by using Ta, Cu, Ru, Ir and the like.

As the material of the storage layer 10X and the reference layer 11X, for example, a ferromagnetic material having the L1₀ structure or L1₁ structure, a soft magnetic material (for example, CoFeB), a ferrimagnetic material (for example, TbCoFe), an artificial lattice or the like is used.

As the material of the tunnel barrier layer 12X, for example, magnesium oxide (MgO) is used. As the hard mask 13X, for example, tantalum (Ta) is used.

Incidentally, an interface layer including a CoFeB film may be inserted between the tunnel barrier layer 12X and the magnetic layers 10X, 11X. Inside the laminated structure 1X, a shift correction layer to cancel a leakage magnetic field from the reference layer may be formed. The foundation layer 17X may contain a shift correction layer.

When the substrate 80 is an inter-layer insulating film, the foundation layer 17 of the laminated structure 1X is formed on the inter-layer insulating film 80 so as to be connected to a contact plug (not shown) in the inter-layer insulating film as the substrate 80. The substrate 80 may be an insulating substrate.

Next, the laminated structure 1X is etched by using lithography and etching to form an independent MTJ element. More specifically, an MTJ element is formed from a laminated structure as described below.

A mask (not shown) formed from a resist film is formed on the hard mask 13.

The formed resist mask is patterned by using RIE or ion milling (ion beam machining) so as to correspond to a predetermined element shape (plane shape) and size.

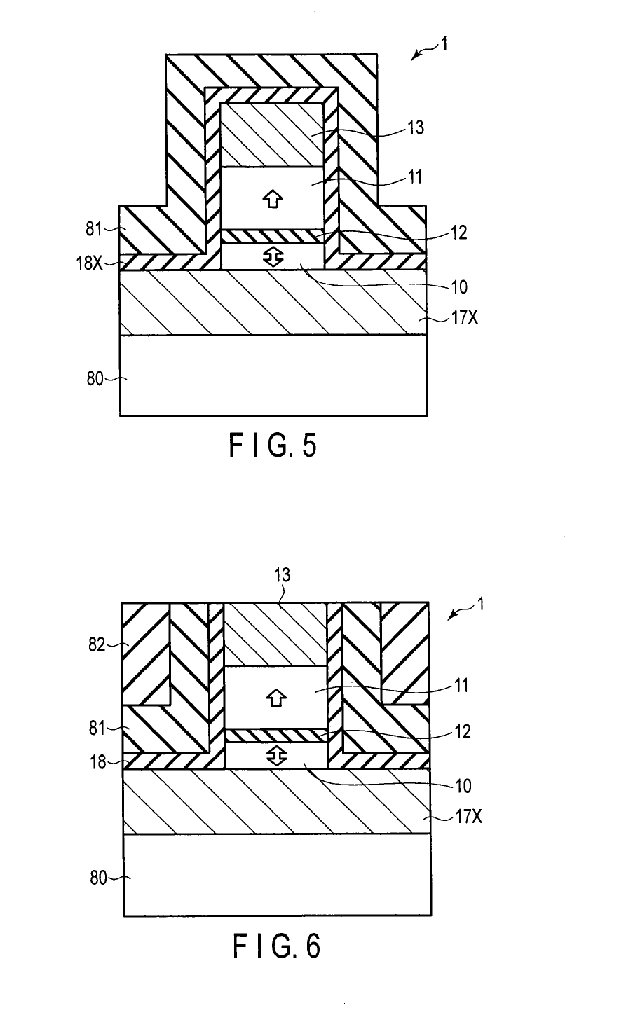

As shown in FIG. 3, the pattern of the resist mask is transferred to the hard mask 13. For example, a resist mask and a hard mask are processed by using an ion beam with a narrow beam spread.

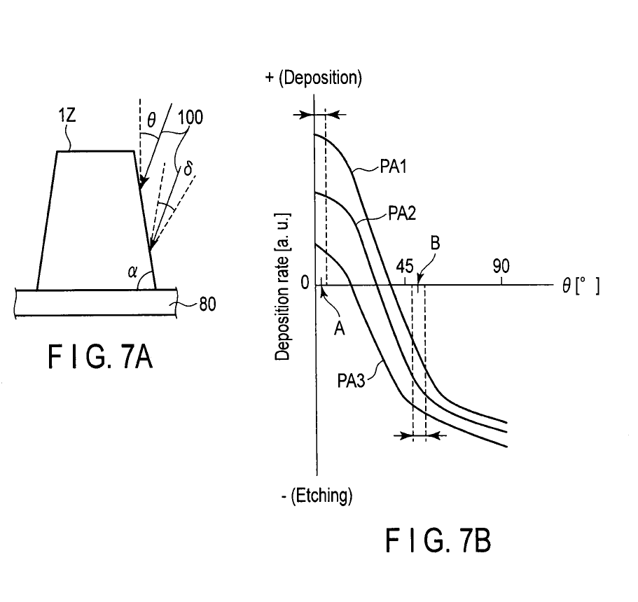

Then, as shown in FIG. 4, the patterned hard mask 13 is used to process (etch) the reference layer 11, the tunnel barrier layer 12, and the storage layer 10 successively from the side of the hard mask by using an ion beam 100 according to the present embodiment. The ion beam 100 to be irradiated on the laminated structure (MTJ element) is generated by an ion source (ion beam generator) so as to have a relatively large solid angle, for example, a solid angle of 10° or more. For example, the beam spread of the ion beam 100 irradiated on the laminated structure 1X to process the magnetic layers 10, 11 is wider than that of an ion beam used for processing of a resist mask (or a hard mask).

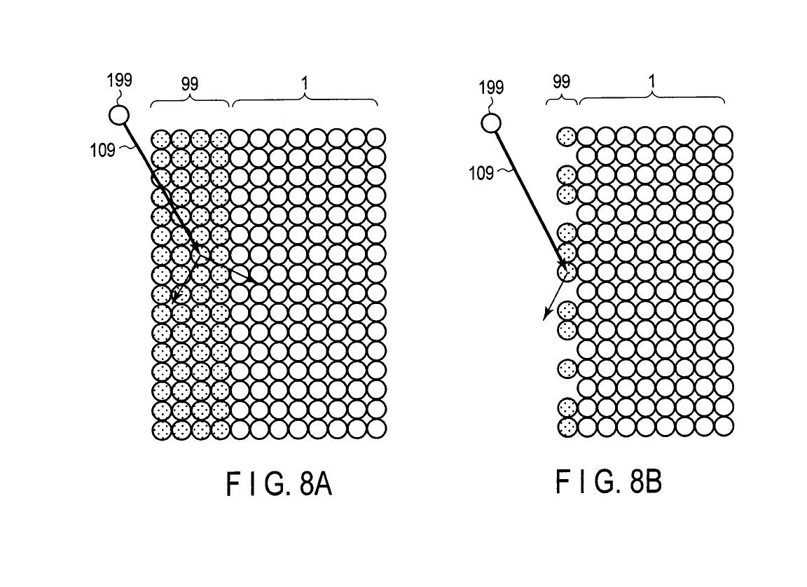

As shown in FIG. 5, a thin insulating film (sidewall insulating film) 18X is deposited on the surface of the processed laminated structure 1 including the foundation layer 17, the storage layer 10, the tunnel barrier layer 12, the reference layer 11, and the hard mask (upper electrode) 13.

For example, the sidewall insulating film 18X covering the laminated structure is desirably dense and conformal silicon nitride (SiN) or aluminum oxide formed by the ALD (Atomic Layer Deposition) method. With a conformal film formed on the laminated structure as described above, no gap is formed between the processed laminated structure (MTJ element) 1 and the insulating film 18X. After the insulating film 18X is formed, for example, an inter-layer insulating layer 81 made of silicon oxide (SiO₂) or SiN is deposited on the substrate 80 by, for example, the CVD method to cover the laminated structure 1.

When a plurality of MTJ elements are formed on the substrate 80, for example, a mask (not shown) made of a photoresist is formed on the top surface of the inter-layer insulating layer 81 to electrically isolate the adjacent laminated structure 1. Then, the resist mask is used to pattern the inter-layer insulating film 81, the insulating film 18X, and the foundation layer 17X by using anisotropic etching (for example, RIE) so that the foundation layer 17X is divided for each MTJ element. Accordingly, laminated structures (MTJ elements) independent of each other are formed on the substrate 80.

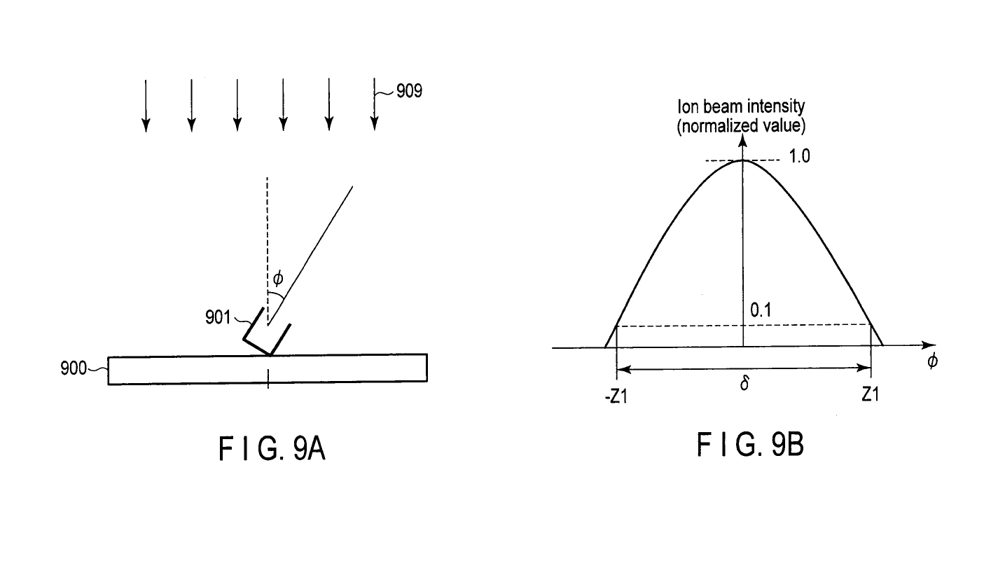

Then, as shown in FIG. 6, an inter-layer insulating film 82 is deposited on the inter-layer insulating film 81 and the sidewall insulating film 18 by, for example, the CVD method to cover the processed laminated structure 1.

The inter-layer insulating film 82 is planarized by CMP. The inter-layer insulating film 82, the inter-layer insulating film 81, and the interlayer insulating film 18 are removed from the hard mask 13 by CMP so that the top surface of the hard mask 13 on the MTJ element 1 is exposed.

As shown in FIG. 1, the interconnect 83 is formed on the MTJ element 1 and the inter-layer insulating films 81, 82 so as to be electrically connected to the upper electrode 13. In this manner, a magnetoresistive effect element according to the first embodiment and a memory cell of MRAM are formed by the manufacturing method in the present embodiment.

In the present embodiment, the ion beam 100 used for processing of a laminated structure to form a magnetoresistive effect element is irradiated on the laminated structure so as to have a large solid angle. For example, the solid angle of an ion beam in the center of the substrate is set to 10° or more.

According to the manufacturing method of a magnetoresistive effect element in the present embodiment described above, the occurrence of magnetoresistive effect element shorts can be suppressed and element characteristics of magnetoresistive effect elements can be enhanced.

### (2) Element Processing by an Ion Beam Having a Solid Angle

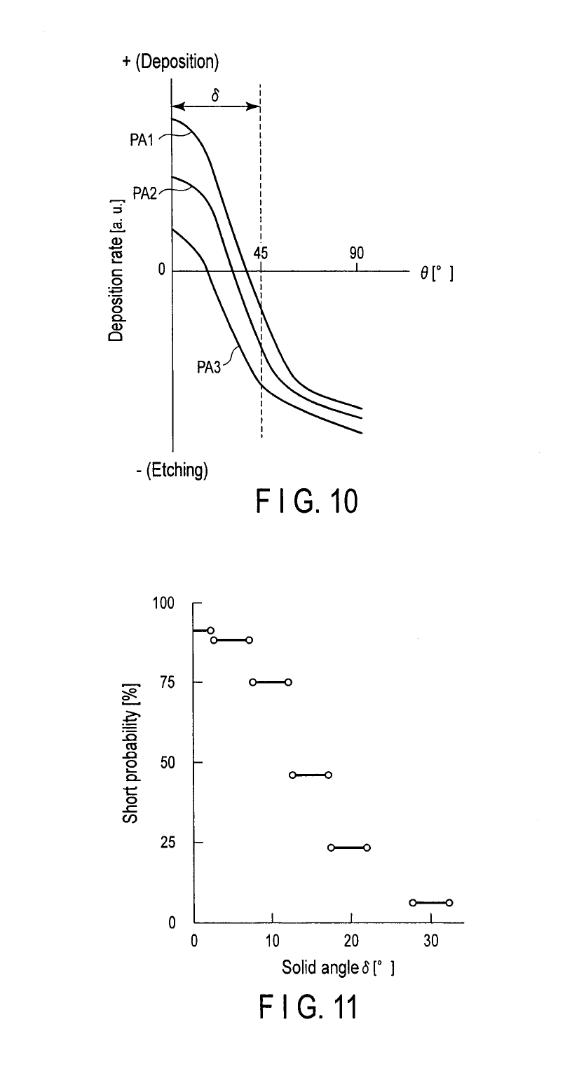

An ion beam used for forming a magnetoresistive effect element according to the present embodiment will be described with reference to FIGS. 7A to 16.

<Influence of the Solid Angle of an Ion Beam>

The solid angle of the ion beam 100 when a laminated structure (magnetoresistive effect element) in the present embodiment is processed and the influence thereof will be described by using FIGS. 7A to 11.

As described above, an element is processed by the ion beam 100 having a relatively large solid angle in a manufacturing process of a magnetoresistive effect element according to the present embodiment.

The dependence of the formation/removal of a reattachment (residue) on the side face of the MTJ element 1 on the incident angle θ of an ion beam to process the MTJ element (laminated structure, processed layer) 1 during an etching process (for example, the process in FIG. 4) to form the MTJ element 1 will be described by using FIGS. 7A and 7B.

FIG. 7A shows the incident angle θ of an ion beam on an MTJ element (laminated structure, processed layer).

As shown in FIG. 7A, the ion beam 100 irradiated on an MTJ element 1Z is incident from a predetermined direction with respect to the direction perpendicular to the surface of the substrate 80. Thus, the incident angle θ of the ion beam 100 (hereinafter, called the ion beam incident angle) is formed between the direction of incidence of the ion beam 100 and the direction perpendicular to the surface of the substrate 80.

The ion beam 100 includes a solid angle (also called a dispersion angle or incident solid angle) δ in the center of the surface (the surface of the substrate or the surface of the laminated structure to be processed) on which an ion beam is incident as variations of the beam spread (straightness) of the ion beam. The solid angle of an ion beam corresponds to the magnitude of an angle with respect to the preset reference (0°) of the incident angle of the ion beam. Because an ion beam having a solid angle is irradiated on a substrate on which one or more laminated structures are formed as a whole, the magnitude of the solid angle of the ion beam may be used to refer to, for example, the magnitude in the center of the substrate.

The MTJ element 1 is formed so as to have a tapered sectional shape in accordance with the magnitude of the ion beam incident angle θ and the side face of the MTJ element 1 is inclined with respect to the direction perpendicular to the substrate surface. As a result, an angle (hereinafter, called a taper angle) α is formed between a bottom face (front side of the substrate 80) of the MTJ element 1 and the side face of the MTJ element 1.

FIG. 7B shows the relationship between the formation/removal of reattachment on the side face of the MTJ element and the ion beam incident angle using the taper angle α of the MTJ element as a parameter. In FIG. 7B, the relationship between the ion beam incident angle θ and the deposition rate when the taper angle α of the MTJ element 1 is 60°, 70°, and 90°. A characteristic line PA1 in FIG. 7B shows the relationship between the deposition rate and the ion beam incident angle when the taper angle α is set to 90°. A characteristic line PA2 in FIG. 7B shows the relationship between the deposition rate and the ion beam incident angle when the taper angle α is set to 70°. A characteristic line PA3 in FIG. 7B shows the relationship between the deposition rate and the ion beam incident angle when the taper angle α is set to 60°.

The horizontal axis of the graph of FIG. 7B represents the ion beam incident angle θ (unit: °). The vertical axis of the graph of FIG. 7B represents the deposition rate (any unit) of reattachment on the side face of the MTJ element. The deposition rate of a positive value corresponds to a state in which a reattachment attaches to the side face of the MTJ element (hereinafter, called a deposition mode) and the deposition rate of a negative value corresponds to a state in which a reattachment is removed from the side face of the MTJ element (hereinafter, called an etching mode).

When the taper angle α of the MTJ element is, for example, 90°, the formation/removal of reattachment changes from the deposition mode to the etching mode when the ion beam incident angle θ with respect to the side face of the MTJ element is about 40°.

When the taper angle α of the MTJ element is, for example, 70°, the formation/removal of reattachment changes from the deposition mode to the etching mode when the ion beam incident angle θ is about 30°. When the taper angle α of the MTJ element is, for example, 60°, the formation/removal of reattachment changes from the deposition mode to the etching mode when the ion beam incident angle θ is about 15°.

With the decreasing ion beam incident angle θ (as the direction of incidence of the ion beam becomes closer to the direction perpendicular to the substrate surface), the magnitude of the deposition rate changes to a positive value (deposition mode) so that a reattachment is more likely to attach to the side face of the MTJ element. Also, with the increasing taper angle α of the MTJ element, the positive deposition rate in deposition mode increases.

In the present embodiment, the dispersion (solid angle) of the ion beam incident angle is denoted by “δ”. The solid angle δ of a general ion beam to process an element is set to within about 5 degrees.

In FIG. 7B, cases when the ion beam incident angle for ion beam etching is set to two conditions A, B are considered.

In FIG. 7B, under the one condition A of the set conditions, the ion beam incident angle θ is set to about 2.5° (range of 0° to 5° when the solid angle δ is) 5° and the laminated structure (processed layer) to form an MTJ element is etched in the depth direction thereof (lamination direction of layers). However, in the etching under the condition A, constituent atoms of the material sputtered by etching are attached (deposited) to (on) the side face of the processed laminated structure.

In FIG. 7B, under the condition B of the set conditions, the ion beam incident angle θ is set to about 50° (range of 47.5° to 52.5° when the solid angle δ is 5°) and reattachment deposited on the side face of the processed laminated structure is removed.

The following method is known as an example of the method of forming an MTJ element.

The ion beam irradiation under the condition A is performed to process an MTJ element into a predetermined shape, and the ion beam irradiation under the condition B is performed to remove a reattachment attached to the side face of the laminated structure processed under the condition A. An MTJ element in a predetermined shape is formed by repeatedly performing the ion beam irradiation under the condition A and the condition B alternately (that is, condition A→condition B→condition A→condition B→ . . . ).

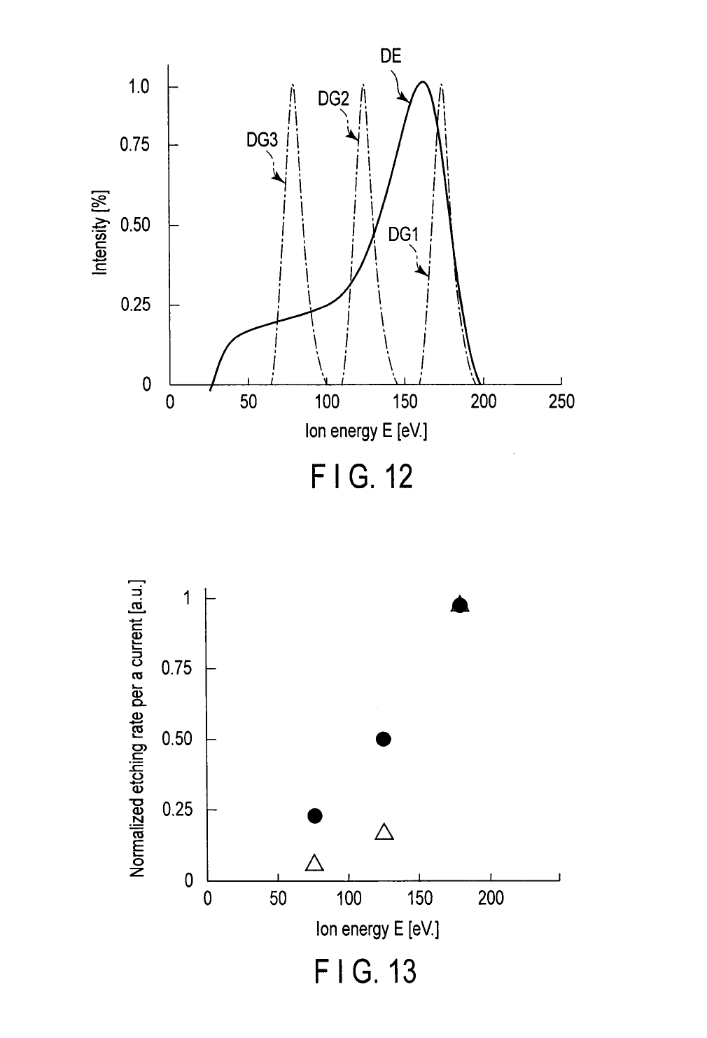

FIGS. 8A and 8B show the state of the side face of an MTJ element when an ion beam under the condition B is irradiated by modeling the side face.

When, as a general manufacturing method, irradiation of the ion beam under the condition B is performed after an MTJ element is processed into a predetermined shape, as shown in FIG. 8A, a reattachment layer (reattachment) 99 is in a film state.

In this case, ions 199 of an incident ion beam 109 collide against atoms constituting the reattachment layer 99 and constituent atoms of the reattachment layer 99 are repelled in the inner direction of the MTJ element 1 or the outer direction of the MTJ element 1 by sputtering based on a certain probability. Atoms repelled in the outer direction are removed from the side face of the MTJ element 1.

When the reattachment layer 99 is filmy as shown in FIG. 8A, however, the probability that constituent atoms of the reattachment layer 99 remain on the side face of the MTJ element 1 or are retrapped inside the MTJ element 1 increases. The probability thereof increases when the filmy reattachment layer 99 is thick or the ion beam 109 is of low energy.

On the other hand, when the irradiation time (processing time) of an ion beam under the condition A is short and the ion beam irradiation under the condition B is performed immediately thereafter, as shown in FIG. 8B, the reattachment layer 99 is still a non-uniform film (island film). When the thin reattachment layer 99 in such a non-uniform state is irradiated with the ion beam 109 through irradiation of the MTJ element 1, constituent atoms of the reattachment layer 99 are almost all repelled in the outer direction of the MTJ element 1 and mostly removed by sputtering.

When an ion beam of low energy is used for processing the MTJ element 1, it is desirable to perform the ion beam irradiation under the condition B in a state (state in which reattachment is not filmy) in FIG. 8B to process a fine MTJ element whose diameter (maximum dimension in a direction parallel to a surface of the substrate) is 30 nm or less by incurring only slight damage.

However, frequent changes of the ion beam incident angle (for example, switching between the condition A and the condition B in FIG. 7B) are physically difficult to implement because the angle of the stage (substrate on which the laminated structure is formed) will be mechanically changed at high speed. Further, frequent switching of the angle of the stage increases mechanical loads and may affect manufacturing costs of MTJ elements or MRAMs in terms of maintenance costs of the manufacturing apparatus of magnetoresistive effect elements (MTJ elements) or downtime of manufacturing.

The influence of the solid angle (range of dispersion/variation of the ion beam incident angle with the processed layer) of an ion beam on the laminated structure (processed layer) to form an MTJ element will be described.

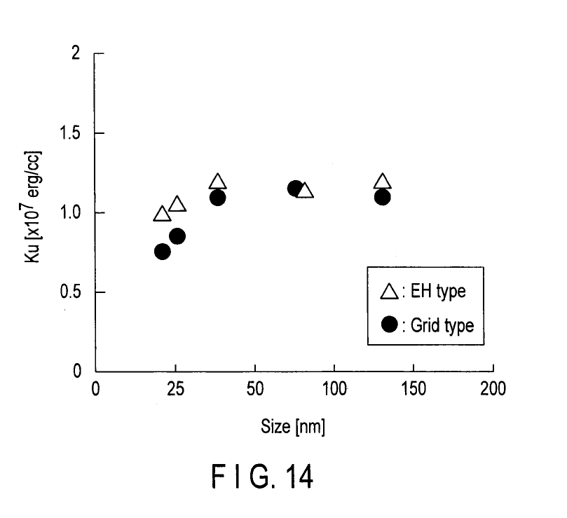

The solid angle of an ion beam in the present embodiment will be described by using FIGS. 9A and 9B.

As shown in FIG. 9A, a Faraday cup 901 is provided in a place corresponding to the center of the surface of a substrate 900. An ion beam 909 is irradiated on the substrate 900 from a direction perpendicular to the surface of the substrate 900. When ions enter the Faraday cup 901, a current in accordance with the amount of ions is generated in the Faraday cup 901.

The current caused by the ion beam 909 entering the Faraday cup 901 via an opening of the cup is measured by changing an angle φ of the opening of the Faraday cup 901 with respect to the direction perpendicular to the surface of the substrate 900 (normal of the substrate surface).

Based on the measurement result, the solid angle of an ion beam in the present embodiment is defined.

FIG. 9B shows a measurement result of irradiating the Faraday cup in FIG. 9A with an ion beam.

FIG. 9B is a graph showing the relationship between an angle δ formed by the Faraday cup and the substrate and the intensity of an ion beam entering the Faraday cup. The horizontal axis of the graph of FIG. 9B represents the angle φ formed by the normal with respect to the substrate surface and the opening of the Faraday cup and the vertical axis of the graph of FIG. 9B represents the normalized value of the intensity of an ion beam (detected current value) entering the Faraday cup.

The intensity of a current caused by the ion beam 909 entering the Faraday cup 901 in FIG. 9A peaks when the angle φ formed by the normal with respect to the surface of the substrate 900 and the inclination of the Faraday cup 901 is 0°. When the angle φ is Z1 or −Z1, the intensity of the ion beam 909 is 10% of the peak intensity of the beam 909.

In the present embodiment, the range (that is, 2×Z1) of the angle at which the intensity of an ion beam reaches 10% of the peak intensity is defined as the solid angle δ of the ion beam. For example, the energy peak of a certain ion beam is reached at an incident angle of the ion beam and the range of the angle centered at the incident angle in which the energy is +10% to −10% thereof is defined as the solid angle δ of the ion beam.

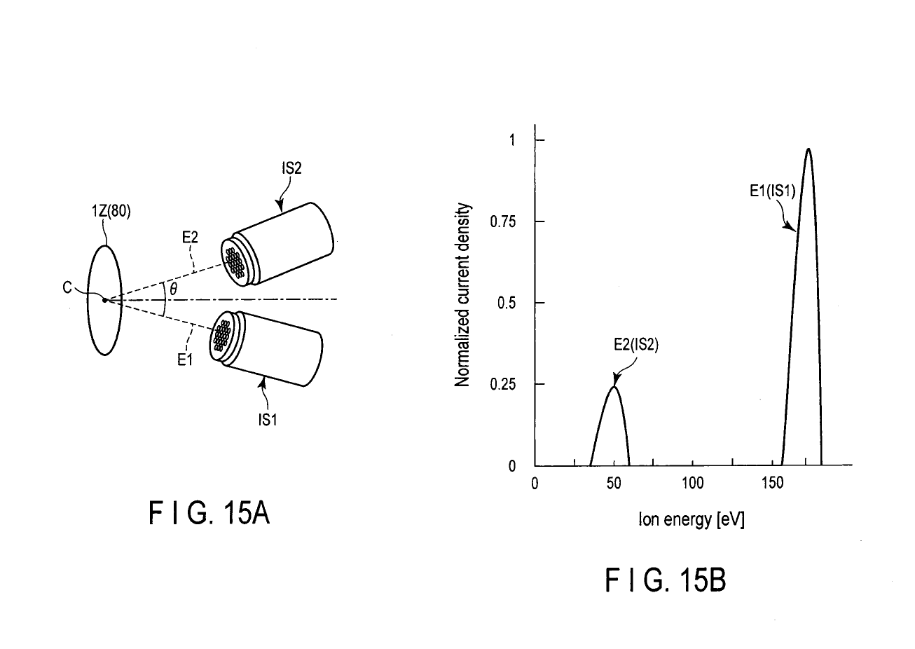

FIG. 10 shows the relationship between the incident angle of an ion beam with respect to the processed layer and the deposition rate (formation/removal of reattachment) when the ion beam having a relatively large solid angle in which the solid angle δ (=2×Z1) of the ion beam is about 45 degrees is irradiated on the laminated structure to form an MTJ element.

To make the amount of reattachment formed in deposition mode and the amount of reattachment removed in etching mode equal, the area (integral value) surrounded by the characteristic line and the vertical axis (line orthogonal to the horizontal axis at some incident angle) in the range of the incident angle θ for each of the characteristic lines PA1, PA2, PA3 may be made equal on the deposition mode side and the etching mode side.

Thus, it is clear that the deposition rate on the side face of the laminated structure (MTJ element, magnetic layer) can be made almost zero by not changing the incident angle θ of an ion beam or changing the incident angle θ only slightly in accordance with the magnitude of the solid angle δ of the ion beam. As a result, an etching state before reattachment becomes filmy as shown in FIG. 8B can be obtained.

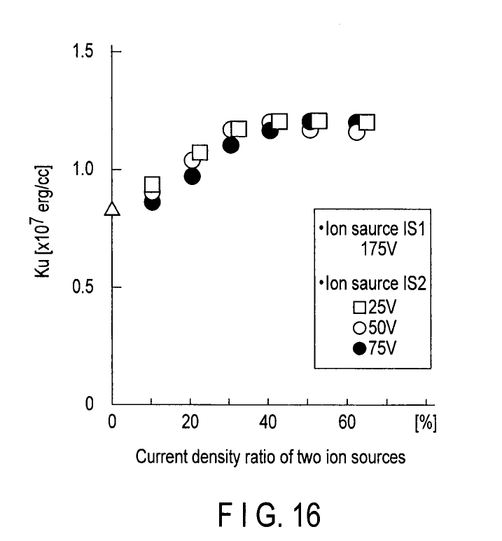

FIG. 11 shows the dependence of the probability of MTJ element shorts on the solid angle of an ion beam to form an MTJ element. The horizontal axis of the graph of FIG. 11 represents the solid angle δ (unit: °) of the ion beam and the vertical axis of the graph of FIG. 11 represents the probability of a short occurrence of the MTJ element (unit: %). In FIG. 11, probabilities of shorts of MTJ elements caused by attachment on the side face of 30 MTJ elements formed by an ion beam of each solid angle are shown.

In a formation process of MTJ elements in the experiment of FIG. 11, the MTJ element processed by an ion beam is exposed to the atmosphere and a protective film (silicon nitride film) is formed on the side face of the MTJ element by natural oxidation of the side face of the MTJ element. Each formed MTJ element has the diameter of 20 nm to 30 nm.

In FIG. 11, the solid angle δ of an ion beam can be increased to some extent by controlling conditions for the voltage applied to the grid of an ion source. By bringing the position of the substrate on which an MTJ element is formed closer to the grid of the ion source, the solid angle δ of an ion beam can further be increased. The angle (set incident angle of an ion beam) θ during irradiation of an ion beam is changed in the range of 10° to 30°.

As shown in FIG. 11, when the magnitude of the solid angle δ of an ion beam set to a certain incident angle becomes about 10°, the tendency for the probability of MTJ element shorts to decrease increases. Then, when the magnitude of the solid angle δ of an ion beam becomes about 20°, the probability of MTJ element shorts decreases to about 25% and when the magnitude of the solid angle δ of an ion beam becomes about 30°, the probability of MTJ element shorts decreases to about 5%.

Thus, when the magnitude of the solid angle δ of an ion beam becomes 10° or more, the tendency for the probability of shorts caused by a conductive attachment on the side face of MTJ elements to decrease becomes more pronounced.

Therefore, like in the present embodiment, the occurrence of MTJ element shorts can be reduced by processing MTJ elements using an ion beam having a large solid angle.

From the viewpoint of integration of memory cell arrays, a region of an MTJ element shadow in the direction of incidence of an ion beam on the MTJ element arises when the solid angle of the ion beam increases so that the ion beam may be less likely to hit the sidewall of the MTJ element. Therefore, the solid angle of an ion beam is desirably set to 60° or less, more desirably to 45° or less.

<Influence of the Energy Dispersion of Ion Energy>

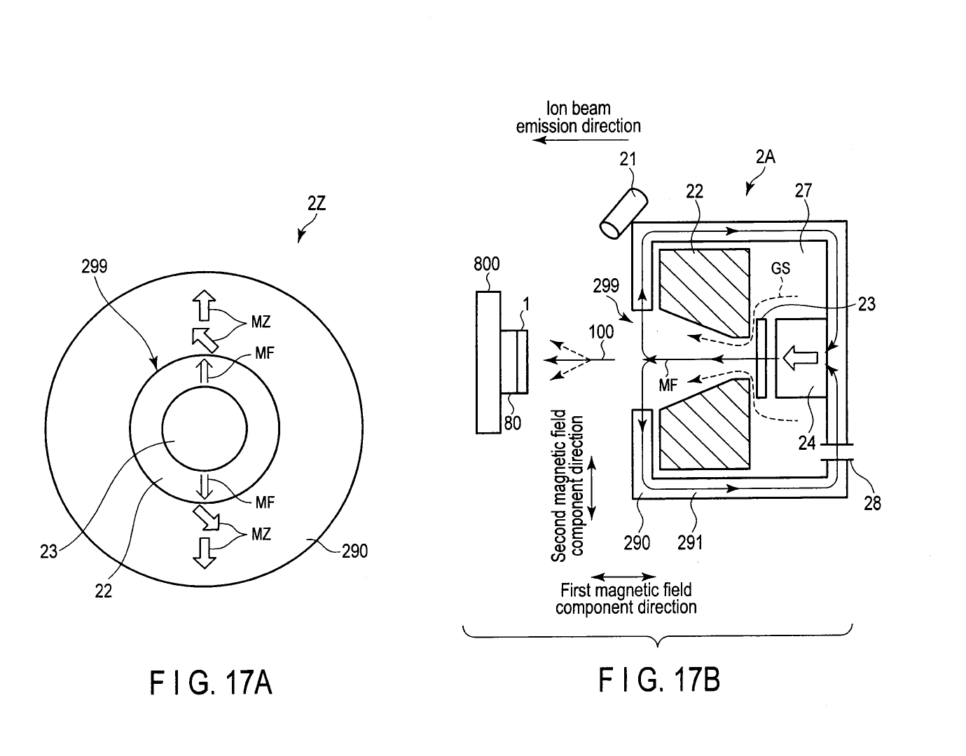

The energy dispersion of an ion beam to process a magnetoresistive effect element will be described with reference to FIGS. 12 to 15B.

FIG. 12 shows the energy dispersion of an ion beam output by a grid ion source or end Hall ion source.

In FIG. 12, the horizontal axis of the graph corresponds to ion energy (unit: eV) and the vertical axis corresponds to the intensity (unit: %) of detected energy.

In FIG. 12, characteristic lines DG1, DG2, DG3 indicated by alternate long and short dashed lines show the energy dispersion (energy distribution) of an ion beam output by the grid ion source and a characteristic line DE indicated by a solid line shows the energy dispersion (energy distribution) of an ion beam output by the end Hall ion source.

As shown in FIG. 12, the full width at half maximum (FWHM) of the energy dispersion DG1, DG2, DG3 of ion energy of an ion beam from the grid ion source is about 10 eV. An ion beam from the grid ion source has small dispersion of energy.

On the other hand, an ion beam from the end Hall ion source has energy dispersion DE larger than the energy dispersion of the grid ion source.

An ion beam from the end Hall ion source has, like the grid ion source, a peak energy near 175 eV. In addition, an ion beam from the end Hall ion source has an energy distribution spreading from the peak energy of 175 eV to 50 eV or less.

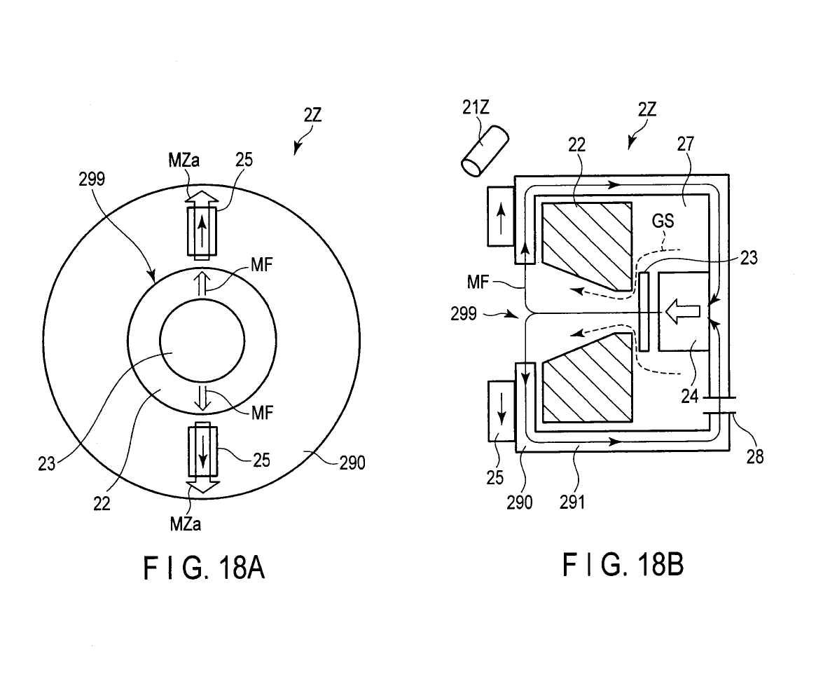

FIG. 13 shows the dependence of a normalized etching rate per unit current of a Co/Pt artificial lattice on the energy of an ion beam. The horizontal axis of the graph of FIG. 13 corresponds to the ion energy (unit: eV) of an ion beam and the vertical axis of the graph of FIG. 13 corresponds to the normalized etching rate (any unit). The normalized etching rate in FIG. 13 is obtained by normalization of the ion energy of 175 eV. FIG. 13 shows the results when the incident angle of an ion beam from the grid ion source is set to 0° (right angle).

Regarding the etching rate (denoted by black circles in FIG. 13) of the grid ion source, as shown in FIG. 13, the normalized etching rate for an ion beam of 175 eV is “1”, the normalized etching rate for an ion beam of 125 eV is “0.5”, and the normalized etching rate for an ion beam of 75 eV is “0.2”. Thus, for an ion beam of the grid ion source, the etching rate tends to fall rapidly as the energy decreases.

If, for example, an ion beam output from the end Hall ion source is assumed to be formed of beams an energy dispersion of 175 eV, 125 eV, and 75 eV, the ratio (hollow triangles in FIG. 13) occupied by the energy in each case to the unit etching depth is “0.175” at 125 eV and “0.04” at 75 eV based on an etching rate at 175 eV of “1” when the energy intensity in FIG. 12 is taken into consideration.

As shown in this case, the ratio of energy occupied by ions (ion beam) of 125 eV and 75 eV to the total etching in the energy distribution of ion beams from the end Hall ion source is only about 18%.

Therefore, when an ion beam irradiated from the end Hall ion source is used, most etching of a processed layer (magnetic layer) is shown to be performed by ions having an energy near 175 eV.

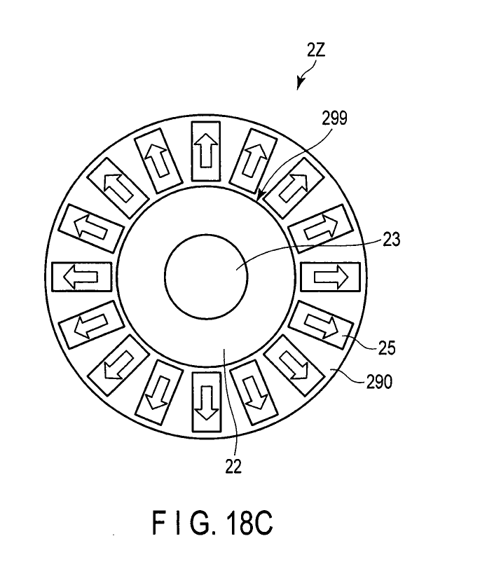

FIG. 14 shows the result of measuring the magnetic anisotropic energy of Co/Pt artificial lattice dots, which are formed as a magnetic layer, from an anisotropic magnetic field of the artificial lattice dots. The measurement result of the magnetic anisotropic energy of artificial lattice dots involves calibration of a demagnetizing field.

The horizontal axis of the graph of FIG. 14 represents the size (diameter) of the formed Co/Pt artificial lattice and the vertical axis of the graph of FIG. 14 represents the magnetic anisotropic energy Ku (×10⁷ erg/cc).

In the experiment of FIG. 14, the dispersion (solid angle) of the incident angle of an ion beam from the end Hall ion source and the dispersion of an ion beam from the grid ion source are set to be almost the same magnitude by adjusting the distance between the ion source and artificial lattice dots (increasing the distance). Also, the etching rate of the artificial lattice by an ion beam from the end Hall ion source and the etching rate by an ion beam from the grid ion source are set to be almost the same magnitude by controlling the current supplied to the ion source.

Then, patterning (etching) of the dotted artificial lattice is performed while the peak ion beam energy of the end Hall ion source and the peak ion beam energy of the grid ion source are both set to about 175 eV.

In FIG. 14, the measurement result of the grid ion source is shown by black circles and the measurement result of the end Hall ion source is shown by hollow triangles.

If, as a result of patterning artificial lattice dots, the diameter of the artificial lattice dots is 35 nm or more, artificial lattice dots processed by an ion beam from the grid ion source and artificial lattice dots processed by an ion beam from the end Hall ion source have almost the same magnetic anisotropic energy Ku.

If the diameter of artificial lattice dots is about 25 nm or less, compared with artificial lattice dots processed by an ion beam from the grid ion source, artificial lattice dots processed by an ion beam from the end Hall ion source are seen to have a smaller drop in the anisotropic energy Ku.

Etching by an ion beam from the end Hall ion source is performed mainly by, as described above, ions of 175 eV and based on the experiment result in FIG. 14, the effect of irradiation of an ion beam of low energy, which makes almost no contribution to the etching, manifests itself in artificial lattice dots of 30 nm or less.

Particularly, the ion energy in the region of 50 eV or less approaching the sputtering threshold of artificial lattice dots is converted into lattice vibration of artificial lattice dots as a processed layer. In a simulation result using TRIM (the Transport of Ions in Matter), the ion implantation depth for artificial lattice dots is estimated to be about 1 nm near 50 eV. Atoms that move after collision with ions (for example, Ar ions) at 175 eV are estimated to move about 1.5 nm, which is not a big difference from the amount of movement of atoms due to collision with ions at 50 eV.

Therefore, the energy of ions of a few tens of eV making almost no contribution to etching is estimated to be converted into lattice vibration of artificial lattice dots (processed layer) and with the rise of temperature accompanying the lattice vibration, defects in the magnetic layer such as distortions formed resulting from collision with ions at 175 eV are repaired.

As described above, repairing of a film (magnetic body) in a depth of about 1 nm from the processed surface by an ion beam of low energy is judged to have the effect of preventing degradation of the magnetic properties of the structure that can be handled as magnetic dots, such as MTJ elements of 30 nm or less in diameter.

The above energy dispersion (a plurality of energy values) of an ion beam does not have to be included in an ion beam emitted from an ion source and may collectively be formed by irradiation of ion beams from a plurality of ion sources.

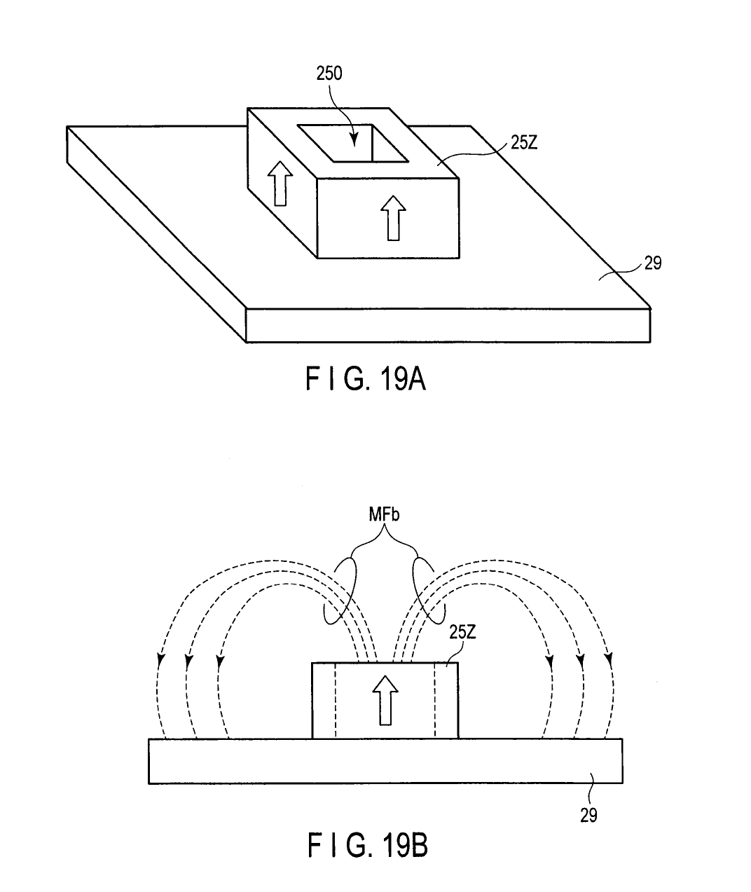

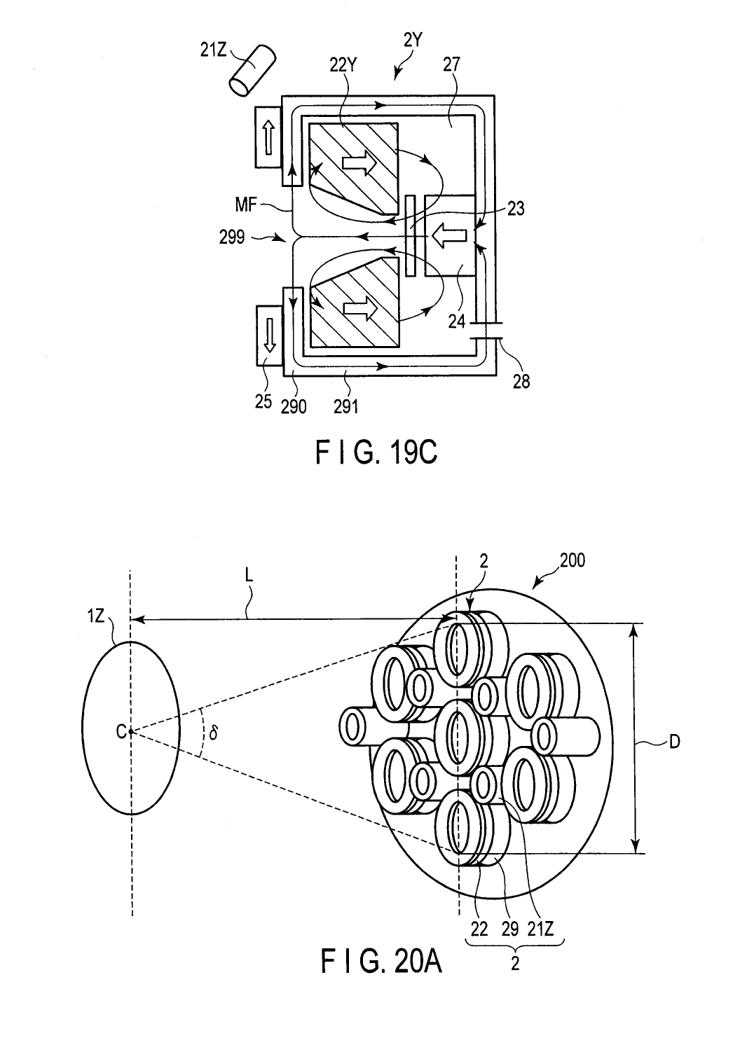

A result of verifying the ratio of ions of low energy making almost no contribution to etching to ions (or the whole ion beam) making a direct contribution to etching so that the repairing effect of a damaged layer by etching is obtained will be described by using FIGS. 15A, 15B, and 16.

FIGS. 15A and 15B show the configuration of an experiment to verify a repairing effect of a magnetic body by ions (ion beam) of low energy.

FIG. 15A shows the configuration of ion sources and a processed layer. FIG. 15B shows the energy of an ion beam output by the ion sources. The horizontal axis of the graph of FIG. 15B represents energy of an ion beam and the vertical axis of the graph of FIG. 15B represents the normalized current value of an ion beam.

As shown in FIG. 15A, ion beams are irradiated on a processed layer (magnetic body) 1Z from two ion sources IS1, IS2.

Ion beams E1, E2 are simultaneously irradiated on the processed layer 1Z in a state in which the ion sources IS1, IS2 are tilted 10° from the direction perpendicular (normal) to the film surface of the processed layer 1Z. The angle formed by the ion beams E1, E2 from the two ion sources IS1, IS2 is 20°.

For example, as shown in FIG. 15B, the ion beam E1 having the center energy of 175 eV is irradiated from the ion source IS1 in the normalized current density of the magnitude “1”. The ion beam E2 having the center energy of 50 eV is irradiated from the other ion source IS2 on the processed layer 1Z in the normalized current density of “0.25” simultaneously with the ion beam from the ion source IS1.

The experiment in the configuration of FIGS. 15A and 15B is conducted, like the experiment in FIG. 14, by forming Co/Pt artificial lattice dots and evaluating the value of the anisotropic energy Ku of the dots to evaluate damage to the artificial lattice dots and the repairing effect.

FIG. 16 shows the result of the experiment using the configuration of FIGS. 15A and 15B. The horizontal axis of the graph of FIG. 16 represents the current ratio of the ion source IS2 to the ion source IS1 and the vertical axis of the graph of FIG. 16 represents the magnetic anisotropic energy Ku (×10⁷ [erg/cc]) of the formed artificial lattice dots. In FIG. 16, the energy of an ion beam from the ion source IS1 is fixed to 175 eV and the energy and current density of an ion beam from the ion source IS2 are changed. The incident angle θ of an ion beam is set to 20°.

Based on the above conditions of the direction of incidence of an ion beam and energy of an ion beam, artificial lattice dots having the diameter of 25 nm are each formed and magnetic properties of the formed magnetic dots are evaluated.

A plot in a triangular form on the vertical axis of the graph of FIG. 16 shows magnetic anisotropic energy of artificial lattice dots when the artificial lattice dots are formed only by an ion beam from the ion source IS2.

Regarding the dependence of the anisotropic energy Ku of the formed artificial lattice dots on the current density ratio of the ion sources IS1, IS2, as shown in FIG. 16, when the energy of Ar ions from the ion source IS2 is set to 25 eV, 50 eV, and 75 eV, the magnetic anisotropic energy of the artificial lattice dots rises in all cases of energy even if the current density ratio is about 10%. When the current density ratio becomes 30% to 40%, the repairing effect of distortion of the magnetic layer by irradiation of an ion beam of low energy is almost saturated.

Based on the above result, when the repairing effect of distortion of the magnetic layer by irradiation of an ion beam of low energy should be obtained, the ratio of an ion beam of low energy (for example, 100 eV or less) to the whole ion beam irradiated on the laminated structure (processed layer) to form an MTJ element is preferably 10% or more.

However, it is preferable to set the current density ratio of two ion sources to 80% or less to suppress an excessive rise of temperature caused by an ion beam of low energy.

<Adjustment of Ion Energy by the Substrate Bias>

The energy of the whole ion beam can be increased or decreased without changing an energy distribution of the ion beam by applying a negative or positive potential to a substrate on which a processed layer (laminated structure to form an MTJ element) is formed while utilizing a wide energy distribution characteristic of a Hall ion source such as an end Hall ion source.

An ion beam can quickly be adjusted to an optimum energy distribution state in a stable discharge state to change the substrate bias to reach the optimum energy distribution for each magnetic layer etched by the ion beam. As a result, the throughput of a magnetoresistive effect element and a magnetoresistive memory including the magnetoresistive effect element can be increased so that manufacturing costs can be reduced.

<Irradiation of an Ion Beam of a Reactive Gas>

An ion beam emitted by the end Hall ion source may be formed by using a reactive gas. In the irradiation of the processed layer with an ion beam (reactive ion beam) of a reactive gas from the end Hall ion source, the reactive ions of low energy can be caused to collide against the processed layer so that damage of the processed layer by processing can be reduced.

In RIE and RIBE (Reactive Ion Beam Etching) by a grid ion source, a gas is discharged at low gas pressure to narrow the beam spread of an ion beam.

Further, in RIE and RIBE (Reactive Ion Beam Etching) by a grid ion source, ions (molecules/atoms) accelerated by an energy of 200 eV to 300 eV are generally caused to collide against the processed layer to suppress damage of the grid when ions are extracted from the grid.

In RIE and RIBE, it is preferable to raise the temperature of the substrate on which the processed layer is formed to increase the reaction probability of colliding active ions (reactive ions). If the rise of temperature of the substrate is insufficient, the probability of ions of RIE and RIBE being implanted in the substrate and processed layer increases, causing corrosion after patterning. On the other hand, if the substrate is heated too much, interdiffusion of constituent elements arises between films when the magnetic layer has a multi-layer structure, which may degrade magnetic properties of the magnetic layer.

When, like an end Hall ion source, an ion beam of 100 eV or less can be formed relatively easily, the depth in which ions are implanted can be made smaller so that damage of the processed layer by processing can be reduced.

Further, compared with RIE, an ion beam of a reactive gas from the end Hall ion source has more flexibility as regards the incident angle with the processed layer, which makes the processing shape of element more controllable. Thus, the side face of a formed MTJ element can more easily be formed to have a shape close to perpendicular to the substrate surface. As a result, power saving of a magnetoresistive memory by reducing a recording/reproducing current of the memory (write current/read current of the MTJ element) can be achieved.

When compared with RIBE of the grid ion source, an ion beam of a reactive gas from the end Hall ion source can be generated as an ion beam using a large current and also can achieve the irradiation of an ion beam of low energy. Thus, an ion beam of a reactive gas from the end Hall ion source can improve the speed of processing the processed layer and also can perform processing with less damage to the magnetic layer.

When, for example, methanol ions as reactive ions are irradiated on the processed layer (magnetic layer) from the end Hall ion source and Ta is used as a mask (upper electrode) of the processed layer, the etching selection ratio of elements of the magnetic layer to the element (Ta) of the mask can be increased.

Incidentally, it is preferable to set the peak energy of an ion beam of a reactive gas to about 150 eV or less (particularly preferably 100 eV or less) to process an MTJ element of the element size (diameter) of 30 nm or less.

When a plurality of gases are used and ion beams of the reactive gases are separately irradiated from a plurality of end Hall ion sources, the energy of the ion beam and the current value can be controlled for each reactive gas and the incident angle of an ion beam with the processed layer can be adjusted. As a result, compared with RIE, processing using an ion beam of a reactive gas is easier to control as a process.

For example, ion beams of reactive gases can independently be irradiated from ion sources supplying carbon monoxide (CO) and ammonia (NH₃) as reactive gases.

On the other hand, RIE can control the partial pressure (flow rate) of carbon monoxide and ammonia inside the apparatus, but cannot control the ion energy of each gas independently.

Thus, when a plurality of ion sources supplying different gases are provided, not only the partial pressure/flow rate of gases, but also the energy for ionization of each gas can independently be controlled and also the effect of the dependence on the incident angle of an ion beam with respect to the processed layer can be added. As a result, compared with processing by RIE, process windows of a magnetoresistive effect element and a magnetoresistive memory are broadened by ion beams using mutually different reactive gases being formed for each ion source.

Reactive gases to form an ion beam include, in addition to the above gases, a halogen containing gas, CO₂, N₂, O₂, N₂O, CH₃OCH₃ (methyl ether), and CH₃COOH (acetic acid). Also, when a mixed gas of these gases and a rare gas is used, the same effect as that of gases forming reactive gases can be obtained.

As the halogen containing gas, for example, F₂, CHF₃, CF₄, C₂F₆, C₂HF₅, CHClF₂, NF₃, SF₆, ClF₃, Cl₂, HCl, CClF₃, CHCl₃, CBrF₃, or Br₂ is used. As the rare gas, He, Ne, Ar, Kr, or Xe is used.

### (3) Concrete Examples

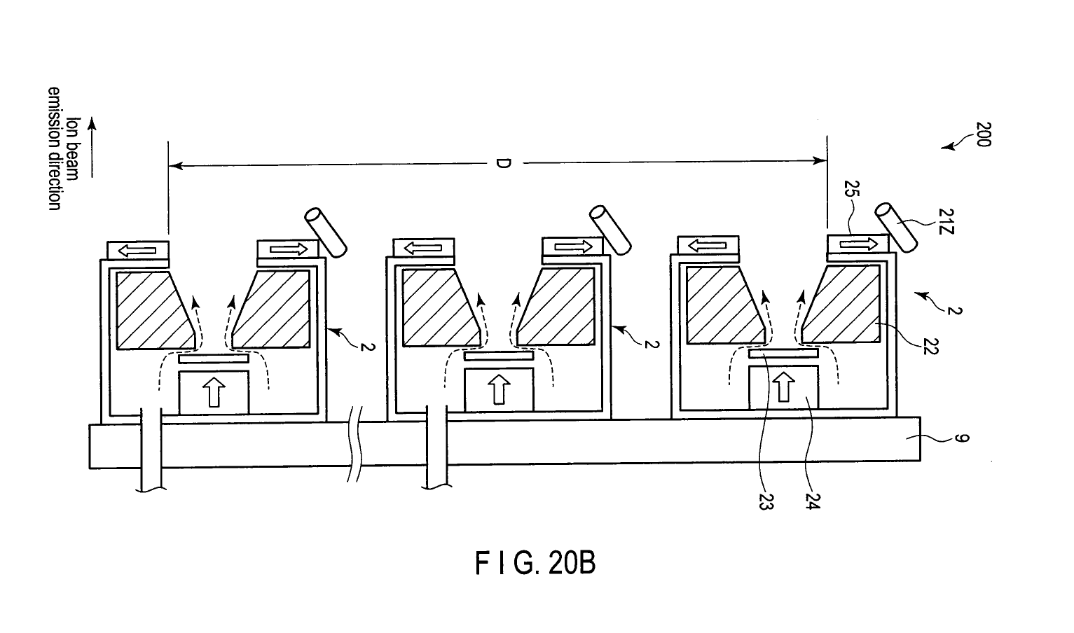

Concrete examples of the manufacturing apparatus of a magnetoresistive effect element according to the present embodiment will be described below with reference to FIGS. 17A to 43.

In the magnetoresistive effect element (MTJ element) 1 having the structure shown in FIG. 1, the top-pin MTJ element including a storage layer made of CoFeB, a tunnel barrier layer made of MgO, and a reference layer made of TbCoFe is processed by etching using, as described above, an ion beam having the solid angle of 10° or more. The MTJ element has an interface layer (not shown) provided in the tunnel barrier layer (MgO film), the reference layer (TbCoFe film), and a boundary neighborhood region. The interface layer has a laminated structure (hereinafter, denoted by a CoFeB/Ta/CoFeB film) including a CoFeB film on the tunnel barrier layer side, a CoFeB film on the reference layer side, and a Ta film sandwiched between the two CoFeB films. The Ta film is used as a foundation layer (lower electrode) for the CoFeB film as the storage layer. A hard mask (upper electrode) in which the Ta film is stacked in a Ru film is provided on the TbCoFe film as the reference layer.

The Ta film of the upper electrode (hard mask) is formed so as to have a height (thickness) of 50 nm and patterned so as to have a circular plane shape of 25 nm in diameter.

To form an MTJ element (laminated structure) configured as described above, the ion beam 100 having a dispersion angle to irradiate on the laminated structure in the process shown in FIG. 4 is generated by, for example, an ion source configured as described below.

(a) Configuration of the Ion Source

The configuration of the ion source to output an ion beam irradiated on a magnetoresistive effect element according to the present embodiment will be described with reference to FIGS. 17A to 31.

<End Hall Ion Source>

The laminated structure (or the magnetic layer) to form a magnetoresistive effect element is processed into a predetermined element shape by using an ion beam formed from a monomer gas (hereinafter, also called a monomer ion beam). An ion beam of a monomer gas is generated by using, for example, an end Hall ion source.

FIGS. 17A and 17B show an example of the structure of an end Hall ion source as a manufacturing apparatus of a magnetoresistive effect element according to the present embodiment. FIG. 17A schematically shows a top view of the end Hall ion source on the side of an emission port of an ion beam. FIG. 17B schematically shows a sectional structure of the end Hall ion source.

An end Hall ion source 2A includes an anode 22 and a cathode 21 functioning as an ion generator and an ion irradiator. In the end Hall ion source 2A, the anode 22 includes an opening through which a gas passes and an opening through which the ion beam 100 is emitted and has a through hole formed from an emission port 299 of the ion beam 100 toward a supply port of gas. The dimensions of the opening 299 on the side on which the ion beam 100 is emitted are larger than those of the opening through which a gas passes and the inner wall of the anode 22 is inclined. A potential is applied to the anode 22 from a power supply (not shown).

The ion source 2A as a manufacturing apparatus of a magnetoresistive effect element includes a substrate holding stage 800 holding the substrate 80 on which the processed layer (layered product) 1 is formed. The substrate holding stage 800 is provided in the apparatus in such a way that the substrate holding stage 800 and the emission port 299 of an ion beam are opposed to each other with regard to the emission direction of an ion beam. Accordingly, the ion beam 100 from the ion source is irradiated on the processed layer 1 on the substrate holding stage 800.

The end Hall ion source 2A includes a cylindrical plasma generating container (also called a plasma chamber, plasma generation region, or discharge region). A region (for example, a hollow region in a truncated conical shape) surrounded by the inner wall of the anode 22 becomes a discharge region and the anode 22 functions practically as a plasma generating container. To generate plasma (ions) efficiently, for example, the inside of the plasma generating container (ion source, ion beam generator) is maintained in a vacuum by a vacuum pump (not shown).

A gas (here, a monomer gas such as Ar or Xe) GS supplied from a gas introduction hole 28 into a gas pressure chamber 27 is supplied from the gas pressure chamber 27 to the discharge region on the anode 22 side via a gas distributor 23. The discharge of a monomer gas is started by electrons supplied from the cathode 21. The monomer gas supplied to the discharge region of the anode 22 (for example, the center region of the anode 22) is thereby ionized to form the ion beam 100.

A magnetic body (for example, a permanent magnet) 24 is installed near the opening to supply a gas to the discharge region of the anode 22, for example, on the opposite side of the anode 22 across the gas distributor 23. In FIGS. 17A and 17B, the direction of the arrow inside the magnet 24 indicates the direction of magnetization of the magnet 24. A magnetic field MF is generated by the magnet 24 inside the discharge region of the anode 22. Instead of the permanent magnet 24, an electromagnet may be provided.

For example, yokes (ferromagnets) 290, 291 are provided around the anode 22. The yoke 290 provided on the emission port side of the ion beam 100 in the anode 22 has a disc-like plane shape. The opening 299 to be the emission port of the ion beam 100 is formed in the position corresponding to the emission port of the anode 22 inside the disc-like (ring-shaped) yoke 290.

Also, the cylindrical yoke 291 is provided to cover the side and bottom of the anode 22. The gas distributor 23 and the permanent magnet 24 are provided inside the cylindrical yoke 291 together with the anode 22. The permanent magnet 24 is preferably provided on the center axis of the cylindrical plasma generating container. The permanent magnet 24 is in contact with, for example, the cylindrical yoke 291. The anode 22 and the yokes 290, 291 as a whole may be called the plasma generating container.

The magnetic flux (magnetic field) MF generated by the permanent magnet 24 returns to the permanent magnet 24 through the through hole of the anode 22 and the yokes 290, 291.

The magnetic field MF has a first magnetic component (ion beam parallel component) along the emission direction of an ion beam from the ion source side toward the substrate side and a second magnetic component (ion beam orthogonal component) in a direction orthogonal to the emission direction of an ion beam. The emission direction of an ion beam having a solid angle is defined as a direction obtained by averaging the directions in which ions forming the ion beam are emitted.

The first magnetic component along the emission direction of an ion beam has the highest magnetic field strength on the center axis of the plasma generating container (anode, discharge region). The magnetic field strength of the first magnetic component decreases from the region surrounded by the anode (center of the plasma generation region) in the emission direction of an ion beam to the side of the emission port of an ion beam (outer circumference of the plasma generation region).

In the distribution of the first magnetic component along the emission direction of an ion beam, the magnetic field strength of the first magnetic component on the side of the emission port of an ion beam of the ion source 2A is lower than the magnetic field strength of the first magnetic component in the region surrounded by the anode 22 (inside the plasma generating container).

The second magnetic component along the direction orthogonal to the emission direction of an ion beam (for example, the plane direction of the emission port of an ion beam or the radial direction of an opening) has a small magnetic field strength (for example, the minimum value) on the center axis of the plasma generating container. The magnetic field strength of the second magnetic component in the opening of the emission port 299 of an ion beam increases from the center of the opening of the plasma generating container to the edge side (outer circumference of the plasma generation region) in the direction orthogonal to the emission direction of an ion beam.

In the distribution of the second magnetic component in the direction orthogonal to the emission direction of an ion beam, the magnetic field strength of the second magnetic component on the edge side of the plasma generating container in the direction orthogonal to the emission direction of an ion beam is higher than the magnetic field strength of the second magnetic component in the center of the opening 299 of the plasma generating container (discharge region).

The trajectory of electrons supplied from the cathode 21 is curved by a Lorentz force near the anode 22 and the opening 299 of the yoke 290, increasing the moving distance for electrons to reach the anode 22 from the cathode 21. With an increasing moving distance of electrons, the collision cross section of electrons and gases increases. As a result, dense plasma is formed near the opening and in the through hole of the anode 22.

Ions are extracted from the formed high-density plasma by the cathode (for example, a hollow cathode) 21 and the flow of extracted ions is discharged from the emission port 299 of the anode 22 as the ion beam 100.

To form a preferable solid angle δ (for example, 45° or less) of the ion beam 100, it is desirable to lower the gas pressure of the region where the ion beam 100 travels toward the substrate 80. By reducing the gas pressure, ion scattering caused by collision of gases and accelerated ions can be suppressed. To lower the gas pressure, it is desirable to increase the strength of the magnetic field MF in the through hole (discharge region) of the anode 22.

However, as schematically shown in FIG. 17A, the magnetized state of magnetization MZ of the yoke 290 is likely to be disturbed by a demagnetizing field near the emission port 299 of an ion beam. Due to the disturbance of the magnetized state of the yoke 290, the strength of the magnetic field MF may decrease in the emission port 299 of an ion beam. As a result, the collision cross section of electrons and gases may decrease, leading to a higher gas pressure during operation (when an ion beam is generated).

When an MTJ element is formed by an ion beam, the substrate on which a laminated structure (MTJ element) is formed is provided inside a vacuum chamber to which the ion source 2A is connected or inside a vacuum chamber common to the ion source 2A. The substrate on which a laminated structure (MTJ element) is formed is mounted on a substrate holding unit (not shown) inside the apparatus including the ion source 2A.

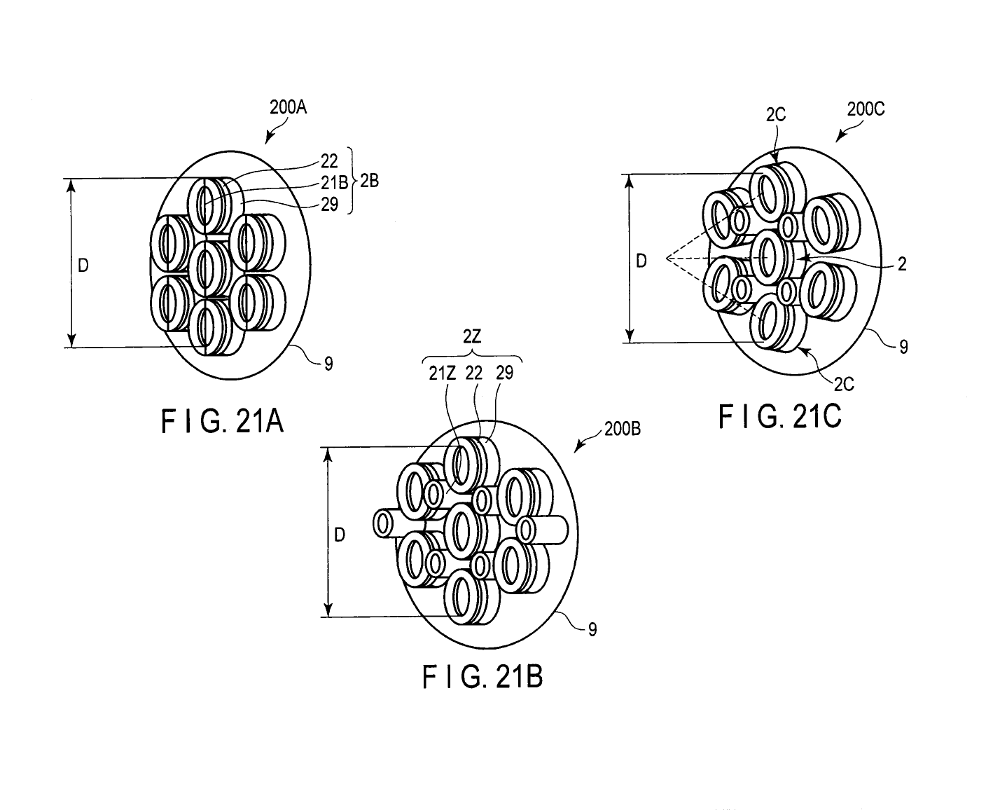

FIG. 18A is a schematic diagram showing the configuration of an ion source different from the ion source in FIGS. 17A and 17B.

FIG. 18A schematically shows a top view of an end Hall ion source on the side of the emission port of an ion beam. FIG. 18B schematically shows a sectional structure of the end Hall ion source. In FIGS. 18A and 18B, the direction of the arrow inside a magnet 25 indicates the direction of magnetization of the magnet 25.

For example, a hollow cathode neutralizer (electron beam emitter) 21Z may be used as the cathode of the end Hall ion source 2Z. The neutralizer 21Z functions as a cathode during irradiation of an electron beam. The neutralizer 21Z may be provided in such a way that the emission direction of electrons of the neutralizer 21Z is inclined toward the side of the emission port 299 of an ion beam of the ion source 2Z.

As shown in FIGS. 18A and 18B, the annular or rod permanent magnet 25 is provided directly on the yoke (ferromagnet) 290 provided on the side of the emission port 299 of an ion beam. The permanent magnet 25 is in contact with, for example, the yoke 290. A non-magnetic body may be provided between the permanent magnet 25 and the yoke 290.

In the ion source 2Z in FIGS. 18A and 18B, as described by using FIGS. 17A and 17B, a monomer gas to form ions is supplied to the center region (discharge region) of the anode 22 via the gas distributor 23. The monomer gas sent to the anode 22 is discharged by electrons supplied from the neutralizer (hollow cathode) 21Z. In the ion source 2Z in FIGS. 18A and 18B, electrons from the neutralizer 21Z are trapped by the magnetic flux (magnetic field) MF from the magnets 24, 25, increasing the density of electrons to start the discharge of gas. In this manner, a monomer gas is ionized relatively easily.

Incidentally, a filament discharging thermal electrons generated by Joule heat may be used as the cathode.

The polarity of the permanent magnet 25 on the yoke 290 is oriented toward the side of the emission port 299 of an electron beam so as to be opposite to the polarity appearing on the surface of the permanent magnet 25 when viewed from the anode 22 side.

Thus, with the magnet 25 provided on the yoke 290 as shown in FIG. 18A, the state of magnetization MZa of the yoke 290 near the emission port 299 of an ion beam where the magnetization is likely to be disturbed by a demagnetizing field is maintained with stability. As a result, the magnetic field MF of high strength can be formed inside the emission port 299 of an ion beam. Accordingly, the density of plasma (ions/gases) near the emission port 299 (and in the discharge region) of an ion beam can be increased so that the density of gas can be decreased on the traveling path of an ion beam from the emission port of an ion beam to the substrate. Therefore, the ion source 2Z in FIGS. 18A and 18B can decrease the gas pressure when an ion beam is generated and can decrease the dispersion of an ion beam to a preferable value.

The magnets 24, 25 to excite ions (plasma) are preferably magnets of a large energy product, such as Sm—Co (samarium-cobalt).

The ion source 2Z in FIGS. 18A and 18B has the two permanent magnets 25 arranged on the yoke 290. However, the three or more permanent magnets 25 may be arranged on the yoke 290.

FIG. 18C schematically shows a top view of the end Hall ion source on the side of the emission port of an ion beam. As shown in FIG. 18C, a plurality of the permanent magnets 25 may be provided on the yoke 290 on the side of the emission port 299 of an ion beam. The permanent magnets 25 are arranged along the shape of the emission port 299 of an ion beam and arranged radially around the emission port 299 of an ion beam. When viewed from the side of the emission port 299 of an ion beam, the magnetization of the permanent magnet 25 is oriented toward the opposite side (outer edge side) of the emission port 299.

The magnets 25 on the yoke 290 may be heated to a high temperature by plasma heat, thus it is desirable to arrange the rod magnets 25 along the circumferential direction.

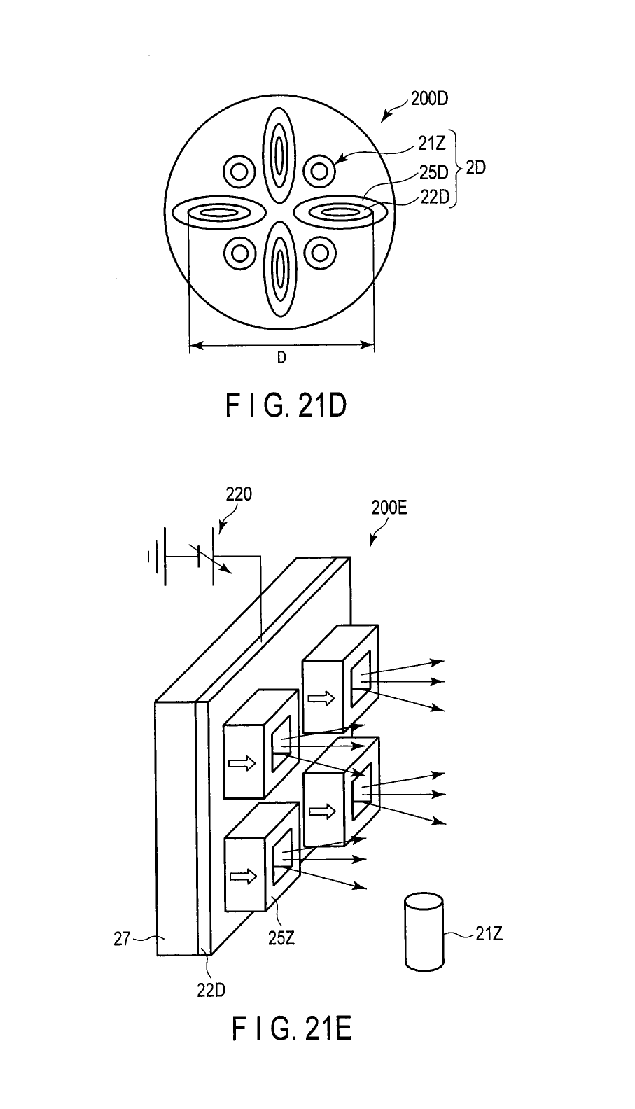

A modification of the end Hall ion source will be described by using FIGS. 19A and 19B.

FIGS. 19A and 19B are schematic diagrams illustrating principle diagrams of the modification of the end Hall ion source. FIG. 19A shows a bird's-eye view illustrating the principle of the modification of the end Hall ion source and FIG. 19B shows a sectional view illustrating the principle of the modification of the end Hall ion source.

For example, as shown in FIGS. 19A and 19B, for example, a square-pole cylindrical (quadrangular cylindrical) permanent magnet 25Z is provided on a yoke 29 of a ferromagnet. The permanent magnet 25Z has, for example, a through hole 250 in a quadrangular shape. A cylindrical permanent magnet has a higher magnetic field strength inside the tube than outside the tube.

When the cylindrical permanent magnet 25Z is provided on the yoke 29, the magnetic flux density (magnetic field strength) MFb generated by the permanent magnet 25Z has the maximum value inside the permanent magnet 25Z (inside the through hole 250).

FIG. 19C is a sectional view showing the structure of an end Hall ion source using the principle in FIGS. 19A and 19B. The structure from the top surface of the end Hall ion source in FIG. 19C is substantially the same as in (a) of FIG. 18A, thus the description thereof is omitted.

An ion source 2Y shown in FIG. 19C has a permanent magnet embedded in an anode 22Y having a through hole. The anode 22Y is formed by using, for example, a cylindrical magnetic body.

The polarity of the magnet in the anode 22Y (hereinafter, called an anode magnet) is oriented in the opposite direction of the polarity of the permanent magnet 24 inside gas pressure chamber 27. The polarity (magnetization) of the anode 22Y is oriented toward the side of the gas pressure chamber 27 (opposite side of the emission port 299).

With the magnets 22Y, 24 inside the yokes 290, 291 having polarities in mutually opposite directions, the strength of the magnetic field MF inside the through hole of the anode 22Y is increased by a magnetic flux from the anode 22Y having magnetism and a magnetic flux from the permanent magnet 24 provided on the opposite side of the emission port of an ion beam. As a result, the discharge (plasma formation) is enabled at a still lower gas pressure.

Each of the end Hall ion sources 2A, 2Z, 2Y shown in FIGS. 17A to 19C has, as described above, the cylindrical plasma generating containers 22, 290, 291 and the magnetic field source 24.

The magnetic field MF from the magnetic field sources 22Y, 24 included in the ion sources 2A, 2Z, 2Y has a magnetic component along the emission direction of an ion beam and a magnetic component along the direction orthogonal to the emission direction thereof. In the magnetic field MF from the magnetic field source 24 included in the ion sources 2A, 2Z, 2Y, the strength of the magnetic field MF in the center of the tube (circle) regarding the magnetic field component along the emission direction of an ion beam is higher than the strength of the magnetic field MF at an edge (opening side) of the tube. Regarding the magnetic field component along the direction orthogonal to the emission direction of an ion beam, the strength of the magnetic field MF is higher at an edge of the tube than in the center of the tube.

A monomer gas is discharged for ionization by each of the end Hall ion sources 2A, 2Z, 2Y shown in FIGS. 17A to 19C in a state in which the magnetic field distributed as described above is formed. Accordingly, an ion beam is generated by each of the end Hall ion sources 2A, 2Z, 2Y.

However, the configuration of an end Hall ion source that outputs an ion beam to form an MTJ element is not limited to the example shown in FIGS. 17A to 19C.

A laminated structure to form an MTJ element may be processed by irradiating the laminated structure with ion beams from a plurality of end Hall ion sources.

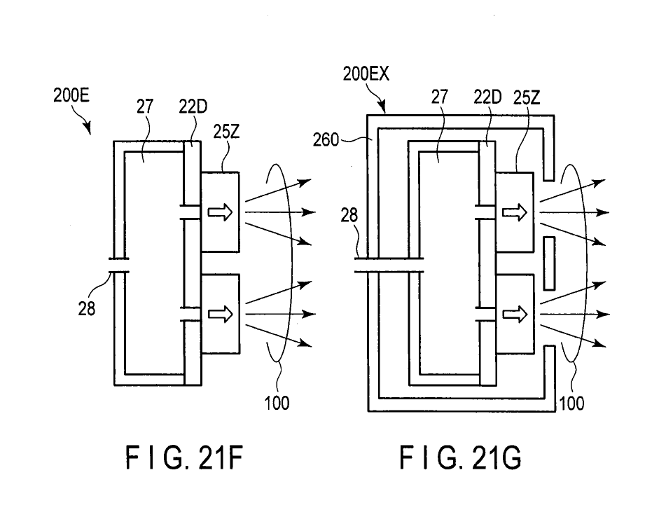

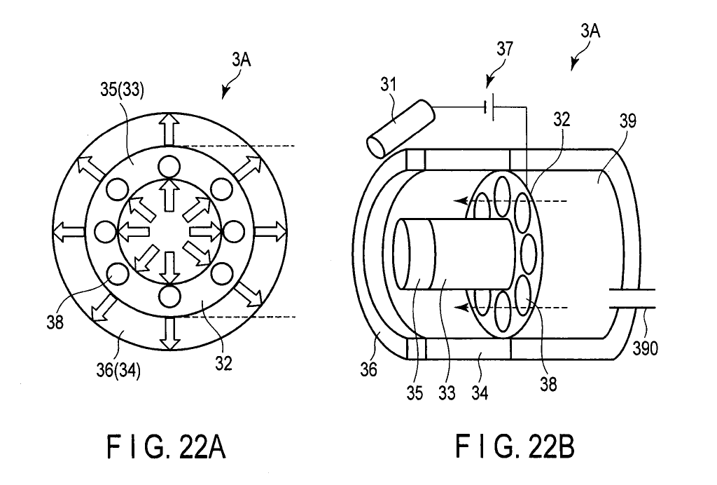

A configuration example of an ion beam generator (ion beam etching apparatus) formed from a plurality of end Hall ion sources will be described with reference to FIGS. 20A to 21C.

FIG. 20A is a bird's-eye view schematically showing the geometric arrangement of the substrate 1Z on which a processed layer is formed and an end Hall ion source 2. FIG. 20B is a schematic sectional view illustrating a distance D between anodes of ion sources.

As shown in FIGS. 20A and 20B, a plurality of the end Hall ion sources 2 are provided on an installation stage 9 to configure an ion beam generator.

The distance between anodes of a plurality of ion sources forming an ion beam generator is denoted by “D” and the distance between the substrate center (C) where a processed layer is formed and the center of the ion source 2 is denoted by “L”.

When, as shown in FIGS. 20A and 20B, an ion beam irradiated on the processed layer is formed of output from a plurality of ion sources, ion beams overlap between the ion sources 2 adjacent to each other, thus the distance that is the longest distance between anodes is denoted by “D”. For example, the distance between ends of openings of ring-shaped anodes arranged on the same straight line is defined to be “D”.

When ion beams from a plurality of ion sources are irradiated on the processed layer, the relationship between the ion beam solid angle δ and the distances D, L can be expressed as “tan δ=0.5×D/L”.

When, as described by using FIG. 11, the solid angle (dispersion) of an ion beam becomes 10°, the probability of shorts due to residues on the side face of an MTJ element starts to decrease. Thus, it is preferable to arrange ion sources inside the apparatus and set the positions of ion sources with respect to the substrate (laminated structure, processed layer) by adjusting the two intervals D, L so that the solid angle δ of an ion beam formed from a plurality of the ion sources 2 (aggregation of ion beams of ion sources) becomes 10° or more.

FIGS. 21A to 21C show a configuration example of the ion beam generator (ion beam etching apparatus) formed from a plurality of end Hall ion sources.

FIG. 21A shows a configuration example of an ion beam generator 200A using a plurality of end Hall ion sources using a filament as a cathode.

The ion beam generator (ion beam etching apparatus, etching gun) 200A is formed by a plurality (for example, seven) of end Hall ion sources 2B using a filament 21B emitting thermal electrons as a cathode being provided. In this case, as described by using FIGS. 20A and 20B, the maximum interval between ends of openings (emission ports of ion beams) of a plurality of the ion sources 2A aligned on the same straight line is defined as “D” to set the solid angle δ of an ion beam.

FIG. 21B shows a configuration example of an ion beam generator 200B using a plurality of end Hall ion sources using the neutralizer 21Z as a cathode. The neutralizer 21Z as a cathode is, for example, a hollow cathode electron beam emitter. As shown in FIG. 21B, the neutralizer 21Z in the ion beam generator 200B is provided in an intermediate position between the adjacent ion sources 2Z in such a way that the emission direction of electrons is perpendicular to the surface of the stage on which ion sources are provided. However, if even the processed layer is irradiated with ion beams from a plurality of ion sources, as shown in FIG. 18A, the neutralizer 21Z may be provided in such a way that the emission direction of electrons from the neutralizer 21Z is inclined toward the emission port side of an ion beam of the ion source 2Z.

FIG. 21C shows a configuration example of an ion beam generator 200C that is different from FIGS. 21A and 21B.

Among a plurality of ion sources 2, 2C provided in the ion beam generator 200C, the ion source 2C is provided in such a way that the emission port of the ion source 2C on the outer circumferential side of the stage 9 is inclined toward the center axis of the stage 9.

Because an end Hall ion source has a large ion beam solid angle δ, the ion beam is irradiated on the inner wall of a chamber (or the inner wall of an ion source) of the etching apparatus, thus, a formed object of the inner wall of the chamber or an attachment on the inner wall may be sputtered due to irradiation of the ion beam. If the amount of sputtering of a formed object of the inner wall of the chamber or an attachment on the inner wall increases, the sputtered formed object of the inner wall or attachment on the inner wall is incorporated into the MTJ element being processed as impurities and characteristics and operation of the MTJ element may adversely be affected.

Thus, as shown in FIG. 21C, with the ion source 2C on the outer circumferential side of the stage 9 installed in the stage 9 by being inclined toward the center axis of the stage 9, irradiation of the inner wall of the chamber of the apparatus with an ion beam can be reduced and so etching of the wall surface of the chamber can be decreased.

FIG. 21D shows a configuration example of the ion beam generator using an end Hall ion source having a structure different from that in FIG. 21A.

In FIG. 21D, an end Hall ion source 2D having a rotationally asymmetric emission port is provided inside an ion beam generator 200D. For example, the ion source 2D includes an anode 22D having an elliptic opening and a magnet 290D having elliptic processing. The emission port of each of the ion sources 2D has an elliptic plane shape.

When an ion beam is irradiated while the substrate on which a processed layer is formed is rotated, uniformity of the irradiation of an ion beam can be increased by extending the emission port of an ion beam in the radial direction.

FIGS. 21E to 21G shows a configuration example of the ion beam generator formed by using anodes (anode magnets) 25Z made of a plurality of cylindrical (quadrangular cylindrical) magnets.

FIG. 21E is a bird's-eye view showing a configuration example of an ion source 200E including a plurality of the anode magnets 25Z and FIG. 21F is a sectional view showing the configuration example of the ion source 200E including the anode magnets 25Z.

The ion beam generator 200E in FIGS. 21E and 21F has the anodes (anode magnets) 25Z made of cylindrical magnets provided on a common anode plate 22D. The anode plate 22D is formed from a ferromagnet.

A positive potential from a variable DC power supply 220 is applied to the anode plate 22D. For example, the potential is applied to the magnets 25Z via the anode plate 22D.

The magnetic field strength is the highest inside the cylindrical anode magnet 25Z and electrons supplied from the cathode 21Z have an increased collision cross section with gases from the gas supply chamber 27 inside the anode magnet 25Z. As a result, high-density plasma is formed inside the anode magnet 25Z.

Due to a potential difference between the anodes 22D, 25Z and the cathode 21Z, an ion flow is discharged from inside the anode magnet 25Z toward the cathode 21Z.

Accordingly, an ion beam is output from the ion beam generator 200E.

With small anode magnets 25Z arranged on an anode plate 22E, an ion source capable of irradiating an ion beam close to a sheet distribution on the processed surface can be formed so that uniformity within the processed surface by etching in the processed laminated structure can be improved.

FIG. 21G shows a modification of the ion beam generator in FIG. 21F.

For example, as shown in FIG. 21G, a cabinet 260 may be provided in an ion beam generator 200EX to cover the anode plate 22D and the anode magnets 25Z. The emission port of an ion beam is provided in the position corresponding to the anode magnet 25Z inside the cabinet 260. Also, the gas introduction hole 28 is connected to the cabinet 260.

For example, the cabinet 260 is preferably formed of a material resistant to etching by an ion beam.

Thus, with the cabinet 260 covering the anode magnets 25Z being provided, leakage of plasma can be prevented so that unnecessary etching of constituent members of the ion beam generator 200E can be prevented.

When, as shown in FIGS. 20A to 21C, ion beams from a plurality of end Hall ion sources are emitted on the laminated structure to form an MTJ element, an ion beam approximating to a sheet distribution can be formed so that the laminated structure can be irradiated with a converged ion beam.

When an ion beam etching apparatus is formed by using a plurality of end Hall ion sources, the peak of energy of the ion beam is distributed between the ion sources to provide an ion beam of high energy for processing of the processed layer and, in addition, the effect of repairing magnetic layer defects such as distortion is obtained by increasing the amount of ion beams of 100 eV or less.

By using, as described above, one or more end Hall ion sources, an ion beam of a relatively large solid angle, for example, an ion beam of the solid angle of 10° or more with the center (or the processed surface) of the substrate on which the processed layer is provided can be generated.

<Cylindrical Ion Source>

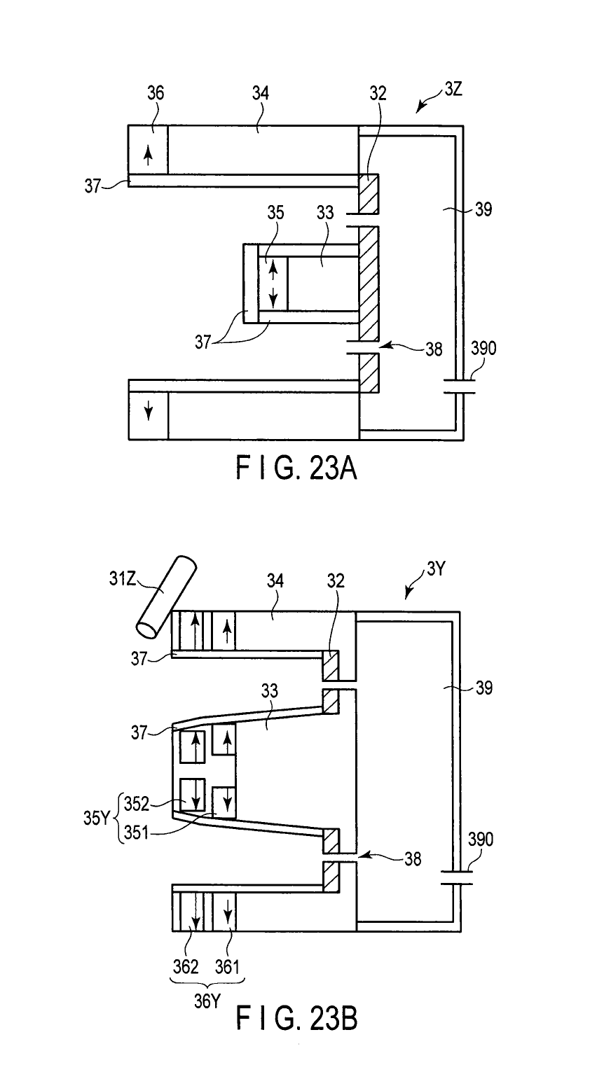

An example of irradiating the laminated structure (processed layer) to form an MTJ element with an ion beam having a large solid angle (for example, the solid angle of 10° or more) by using an ion source other than the end Hall ion source will be described by using FIGS. 22A to 25.

For example, a cylindrical ion source (also called a magnetic layer or anode layer ion source) may be used, instead of the end Hall ion source, to generate an ion beam to form an MTJ element.

Like the end Hall ion source, the cylindrical ion source has no grid. An ion beam output by the cylindrical ion source has a relatively large solid angle (dispersion). Thus, instead of the end Hall ion source, the cylindrical ion source may be used to perform etching to form an MTJ element by an ion beam having a solid angle.

FIGS. 22A and 22B show a structure example of the cylindrical ion source. FIG. 22A shows a plan view of the cylindrical ion source. FIG. 22B shows a bird's-eye view of the cylindrical ion source.

As shown in FIGS. 22A and 22B, a cylindrical ion source 3A includes a cylindrical (cylinder structure) plasma generating container 34.

An anode 32 is provided on the one end (gas supply side) of the cylindrical plasma generating container 34. The anode 32 has a ring plane shape. A through hole (gas introduction hole) 38 to introduce a gas in a gas chamber 39 is provided in a metallic plate 32.

A gas capable of forming an ion beam such as Ar is introduced into the plasma generating container 34 from the gas chamber 39 via the gas introduction hole 38 formed in the anode 32. A gas to form an ion beam is supplied to the gas pressure chamber 39 via a gas introduction hole 390.

A cylinder 33 is provided in the center of the plasma generating container and a magnet 35 is provided on the cylinder 33. Accordingly, a magnetic field source is formed on the center axis of a discharge chamber.

A magnet 36 is provided on the container 34 on the other end (the side of the emission port of an ion beam) of the cylindrical plasma generating container 34. When an ion beam is generated, ring-shaped plasma is formed by a magnetic field from the magnets 35, 36.

Magnetic lines of force extending in the radial direction of the cylinder are generated by the magnets 35, 36 provided on the cylinder 33 and near the emission port of an ion beam of the plasma generating container 34 respectively. The magnetic lines of force trap electrons discharged from a hollow cathode electron beam 31 as a cathode along the circumferential direction. Accordingly, the electron density inside the plasma generating container (discharge region) 34 increases and plasma is generated by ionized gases. The generated plasma is accelerated by an electric field from the anode 32 and is discharged toward the outside (for example, the substrate side on which the processed layer is formed) as an ion beam.

A DC power supply 37 is connected to the cathode 31 and the anode 32.

In the cylindrical ion source 3A in FIGS. 22A and 22B, for example, because the wall of the plasma generating container 34 and the cylinder 33 in the center inside the container 34 have a ring shape, the discharge region is narrowed by the magnet 35 on the center axis of the container 34.

Like the end Hall ion source, an ion beam output by the cylindrical ion source 3A has a wide beam spread and a relatively large solid angle (dispersion angle).

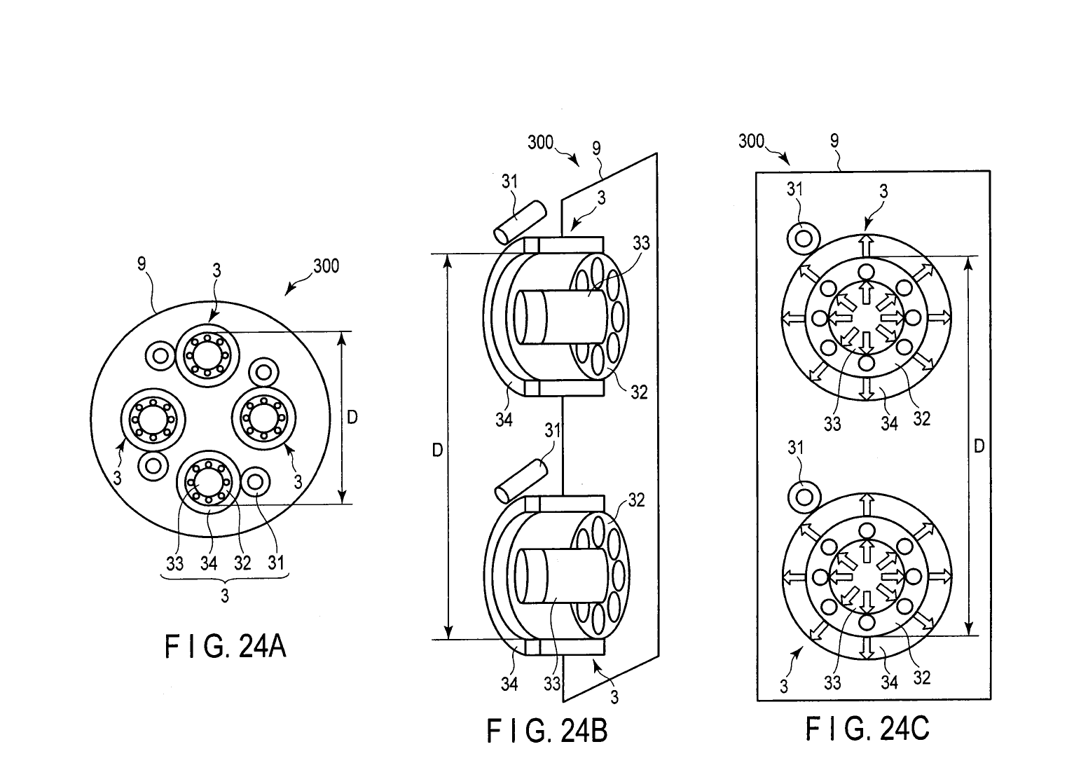

A modification of the cylindrical ion source according to the present embodiment will be described by using FIGS. 23A and 23B.

FIGS. 23A and 23B show a sectional structure of a cylindrical ion source.

In a cylindrical ion source 3Z shown in FIG. 23A, the height of the cylinder 33 and the magnet 35 (dimension in the axial direction of the tube) provided in the center inside the cylindrical plasma generating container 34 is lower than the height of the magnet 36 on the outer wall of the plasma generating container 34. The position of the magnet 35 on the cylinder 33 is set closer to the anode 32 regarding the axial direction of the tube than the position of the magnet 36 on the outer wall of the plasma generating container 34.

The discharge region in the plasma generating container 34 is thereby increased.

Like the ion source 3Z shown in FIG. 23A, for example, the side face of the cylinder 33, the inner wall of the wall 34, and the side face of the magnets 35, 36 in the plasma generating container 34 are covered with a protecting plate 37 formed from a hard-to-etch material such as boron nitride and alumina. Accordingly, impurities resulting from etching of the inside of the plasma generating container 34 by an ion beam can be prevented from being generated. As a result, constituent materials of the ion source 3Z can be prevented from attaching to or mixing into the MTJ element 1.

In a cylindrical ion source 3Y shown in FIG. 23B, the side face of a magnet (magnetic block) 35Y on the inner side (center side) of the plasma generating container 34 is formed in a tapered shape to increase the area of the discharge region and the magnet (magnetic block) 35Y on the cylinder 33 has a trapezoidal shape. The inside of the cylinder 33 and the magnet 35Y of the plasma generating container has a sectional shape in which the surface on the side of the ion beam emission port of the magnet 35Y is narrowed. As a result, the interval between the magnet 35Y on the cylinder 33 and a magnet 36Y on the outer wall of the plasma generating container 34 in the radial direction of the tube (plasma generating container) increases, enlarging the discharge region.

However, depending on the size of the interval between the magnet 35Y in the center of the container 34 and the magnet 36Y on the outer side of the container, the magnetic field strength inside the plasma generating container 34 may fall. For example, among a plurality of magnets 351, 352, 361, 362 provided on the cylinder 33 and the outer wall 34, compared with the magnets 351, 361 with a smaller interval between the center side and the outer side, the magnets 352, 362 with a larger interval between the center side and the outer side are devised to generate a larger magnetic field.

As concrete examples, the magnets 352, 362 are formed by using a material whose saturation magnetic density is large or increasing the area of the magnet opposed to the discharge region (area of the side face of the magnet).

For example, a hollow cathode neutralizer may be provided as a cathode 31Z of the cylindrical ion source. An electron flow discharged from the hollow cathode neutralizer becomes the cathode 31Z and an Ar gas or Xe gas supplied from a gas introduction port provided in the anode 32 into the plasma generating container 34 is ionized to form plasma. In the cylindrical ion sources 3A, 3Z, 3Y, the value of “D” to set the solid angle δ is set to the diameter of the ring-shaped anode (diameter on the inner wall side of the plasma generating container 34).

A DC discharge may be used or an ECR discharge may be used to form plasma by the cylindrical ion source 3 (and the end Hall ion source 2). For the DC discharge, as shown in FIG. 22B, the DC power supply 37 may be used, which has a simple configuration by eliminating the need for an oscillator and thus is cost-effective. The ECR discharge is characterized by wide discharge conditions. The ECR discharge can reduce the capacity of a vacuum pump to maintain a vacuum inside the plasma generating container 34 and thereby can reduce manufacturing costs and maintenance costs.

Like the end Hall ion source, an ion beam etching apparatus may be formed by using a plurality of cylindrical ion sources.

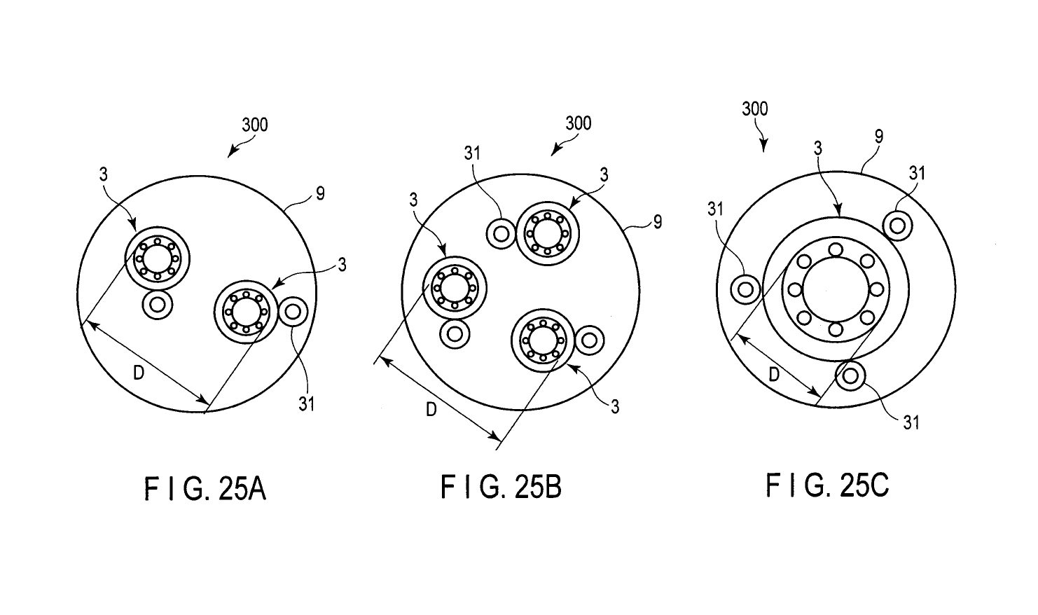

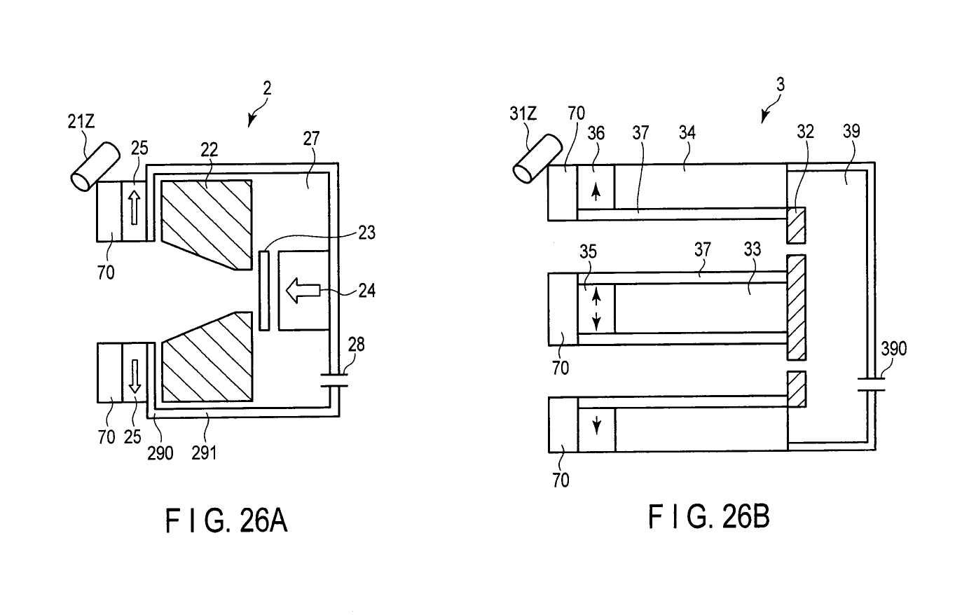

FIGS. 24A to 25C show a configuration example of the ion beam generator (ion beam etching apparatus) configured by a plurality of cylindrical ion sources.

FIG. 24A shows a top view of the configuration example of the ion beam generator formed by using the cylindrical ion sources. FIG. 24B shows a bird's-eye view extracting a portion of the ion beam etching apparatus including the cylindrical ion sources. FIG. 24C shows a top view extracting a portion of the ion beam etching apparatus including the cylindrical ion sources.

FIG. 24A shows an example in which four cylindrical ion sources form an ion beam etching apparatus.

For example, the neutralizer 31 as the cathode may be mounted on each of the ion sources 3 or between the ion sources 3 so as to be shared by the adjacent ion sources 3 in an apparatus 300.

When an ion beam etching apparatus is formed by using a plurality of the cylindrical ion sources 3, as shown in FIGS. 24A to 24C, “D” to set the solid angle δ corresponds to the maximum distance between the ring-shaped anodes 32 of the cylindrical ion source 3 aligned on the same straight line.

For example, the maximum distance between the ring-shaped anodes 32 of the cylindrical ion source 3 to decide the value of “D” is set to the distance between outer edges of the anodes 32 along the arrangement direction of the ion source 3 aligned on the same straight line.

FIG. 25A shows an example in which the two cylindrical ion sources 3 are provided inside the one ion beam generator 300 and FIG. 25B shows an example in which the three cylindrical ion sources 3 are provided inside the one ion beam generator 300.

When the ion beam etching apparatus 300 is formed from the two or three cylindrical ion sources 3, like the example shown in FIGS. 24A to 24C, among the ion sources 3 aligned on the same straight line, the maximum value as the distance between edges on the outer side of anodes (on the side on which other anodes are not adjacent to each other) is set as the value of “D” to decide the solid angle.

As shown in FIG. 25C, a plurality of the cathodes (for example, neutralizers) 31 may be provided for the one cylindrical ion source 3.

As described above, an ion beam having a large solid angle (for example, the solid angle of 10° or more) can be generated by using one or more cylindrical ion beams.

Incidentally, an end Hall ion source and a cylindrical ion source may form an ion beam generator. When compared with the end Hall ion source, the cylindrical ion source can more easily output an ion beam having high energy and a narrow beam spread. Thus, etching in the initial stage of processing of a laminated structure may be performed by irradiation of an ion beam from the cylindrical ion source to perform repairing processing of damage of the final processed laminated structure by ion beam irradiation from the end Hall ion source.

<Control of an Ion Beam>

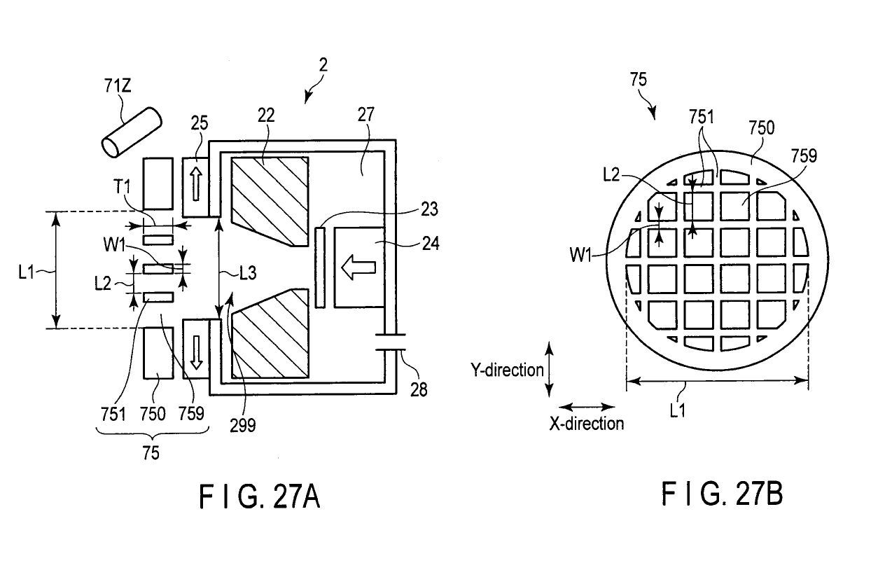

The control of an ion beam output from an ion source will be described with reference to FIGS. 26A to 32B.

FIGS. 26A and 26B show the structure of an ion source including the configuration to control an ion beam. FIG. 26A shows a sectional structure of an end Hall ion source and FIG. 26B shows a sectional structure of a cylindrical ion source.

In FIGS. 26A and 26B, each of the ion sources 2, 3 is provided with a ring for convergence of an ion beam.

In the end Hall ion source 2, as shown in FIG. 26A, a convergence ring 70 having a through hole (opening) through which an ion beam passes is provided on the magnet 25 on the emission port side of an ion beam. In the cylindrical ion source 3, as shown in FIG. 26B, the convergence ring 70 is provided on the magnets 35, 36 on the emission port side of an ion beam.

By installing the convergence ring (collimator) 70 of an ion beam on the magnets 25, 35, 36 to form high-density plasma, the angle of divergence of an ion beam can be controlled, and, for example, the divergence of an ion beam can be suppressed. The convergence ring 70 has a partition wall parallel to the emission direction of an ion beam.

Ions forming an ion beam vary in the direction in which they are emitted from an ion source and are directed from the ion source side to the substrate side. In the present embodiment, the direction obtained by averaging the directions in which ions are emitted is defined as the emission direction of an ion beam having a solid angle. For example, the emission direction of an ion beam (average emission direction of an ion beam) corresponds to the direction along a straight line connecting the center of the emission port 299 of an ion beam of the ion source and the center of the substrate 80.

By forming the convergence ring 70 using, for example, boron nitride (BN), ceramics of alumina, or a hard-to-etch material such as carbon, the convergence ring 70 can also be used as a physical inhibit cover for a divergent ion beam.

For example, an ion beam can electrostatically be converged by forming the convergence ring 70 using a conductive material such as carbon and metal and setting the ring 70 made of the conductive material to a floating state. Incidentally, the convergence of an ion beam may be controlled by applying a voltage to the ring 70 made of the conductive material.

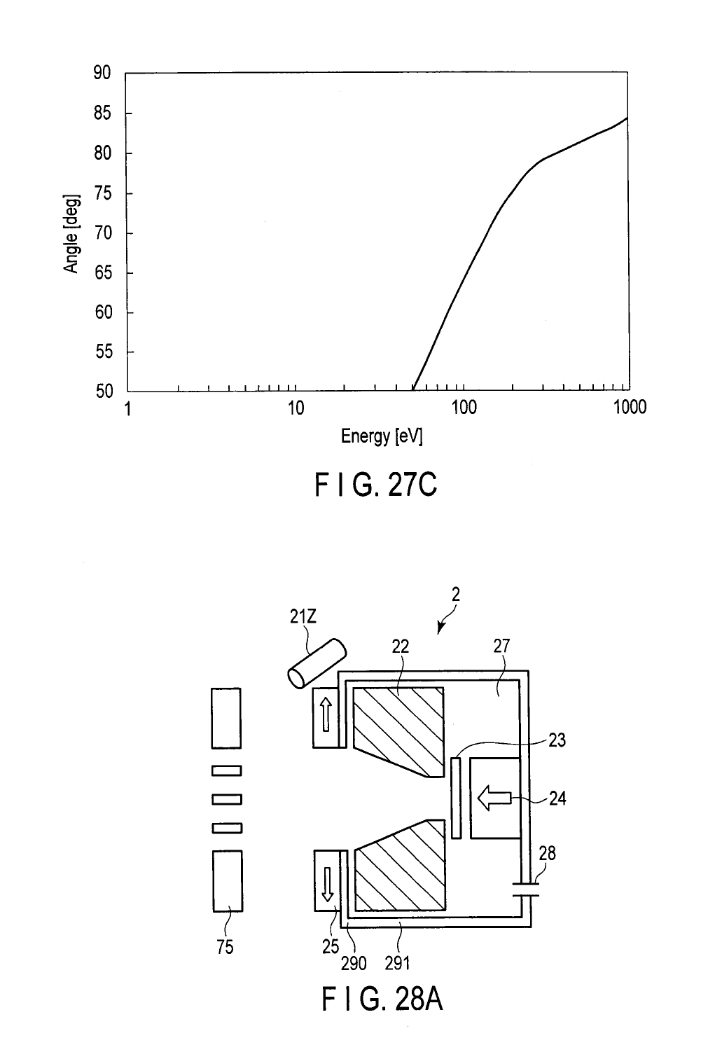

FIGS. 27A and 27B show a structure example of an ion source configured differently from FIGS. 26A and 26B and capable of controlling an ion beam. FIG. 27A shows a sectional structure of an ion source (here, an end Hall ion source).

As shown in FIG. 27A, a collimator 75 may be provided in the emission port of an ion beam of the ion source 2. Like the convergence ring 70, the collimator 75 includes at least a through hole through which an ion beam passes and has a partition wall parallel to the emission direction of an ion beam.

The collimator 75 is preferably provided, for example, closer to the side of the ion source 2 from the intermediate position between the ion source 2 and the substrate on which a laminated structure is formed to improve controllability of an ion beam. The collimator 75 adjusts an ion beam so that the solid angle of the ion beam is, for example, 60° or less and further, 45° or less.

In addition to the ring shape as the collimator 75 for ion beam convergence, an ion beam can be adjusted by providing a wall (or a plate or lattice) extending in a direction crossing the ion beam emission direction (direction from the ion source toward the processed layer) in the ring. In FIG. 27A, a plurality of walls (lattices) 751 are inserted into a ring 750.

FIG. 27B shows an example of the plane shape of the collimator. The collimator 75 in FIG. 27B has a grid-like (meshed) plane shape.

In the collimator 75, the walls (lattices) 751 are provided on the inner side of the ring 750. The walls 751 are provided in the ring 750 so as to cross the X direction and the Y direction. With the inserted walls 751, the inside of the ring 750 becomes like a grid. Portions surrounded by the walls 751 become rectangular voids 759.

As shown in FIGS. 27A and 27B, the inside diameter of the ring 750 in the collimator 75 is denoted by “L1”. The line width of the wall (lattice) 751 between the voids 759 (dimension in the direction parallel to the surface of the collimator) is denoted by “W1”. The dimension of one side of the rectangular void 759 (interval between the walls 751) is denoted by “L2”. The thickness of the wall 751 (height, the dimension along the emission direction of an ion beam) is denoted by “T1”.

If the opening dimension (diameter) of an anode of the end Hall ion source 2 is denoted by “L3”, the dimension (diameter of the ring 750) L1 is preferably larger than the dimension L3 (L1>L3).

Further, to suppress mixing of impurities resulting from the ion source 2, it is preferable to set the angle of divergence (solid angle) of an ion beam to 45° or less. Thus, the dimension (thickness of the wall 751) T1 is preferably equal to or more than the dimension (interval between the walls 751) L2 (T1≧L2).

By decreasing the line width W1 of the wall 751 of the collimator 75, constituent members of the collimator 75 can be inhibited from being etched by an ion beam. As a result, constituent members of the collimator 75 etched by an ion beam can be prevented from attaching to the anode 22 (or the MTJ element) as impurities. Thus, the dimension L2 of the void 759 is preferably larger than 10 times the dimension W1 of the wall 751 (L2≧10×W1).

Examples of dimensions of components included in the collimator 75 are, for example, L1=50 mm, L2=12 mm, L3=40 mm, W1=1 mm, and T1=12 mm.

The collimator 75 is set to a floating state in terms of potential when, for example, an ion beam is emitted. The wall 751 and the ring 750 of the collimator 75 are formed by using, for example, carbon as the material.

When the processed layer (MTJ element) is processed by setting the energy of an ion beam to 100 eV or less, the amount of the wall 751 of the collimator 75 etched by ions (for example, ions of 100 eV or less) passing through the voids 759 of the collimator 75 (sputtering rate at a shallow ion beam incident angle) decreases when compared with a case in which the energy of an ion beam is set to larger than 100 eV.

FIG. 27C shows the relationship between an ion beam energy at which sputtering for Mo no longer occurs and the incident angle of ion energy when a member made of Mo is irradiated with an ion beam of Xe. The horizontal axis of the graph of FIG. 27C represents the energy of an ion beam (unit: eV) on the log scale and the vertical axis of the graph of FIG. 27C represents the incident angle (unit: °) of an ion beam on a member when the sputtering rate of the member becomes 0. Incidentally, the incident angle of an ion beam in FIG. 27C is an angle formed by the normal of the surface of the substrate on which the member is formed and the direction of incidence of the ion beam.

As shown in FIG. 27C, when the energy of an ion beam becomes 200 eV or less, the decrease of the incident angle of an ion beam at which the sputtering rate becomes 0 becomes steep.

Then, when the energy of an ion beam decreases to 100 eV or less, no etching (sputtering) of Mo on the substrate occurs even if the substrate is irradiated with an ion beam at an angle of 65° with respect to the normal of the substrate surface, in other words, at an angle of 25° with respect to the surface (0°) of the substrate.

This shows that if an ion beam has a low energy of 100 eV or less, a collimator formed of an Mo material is in principle not etched even if the solid angle of the ion beam is 50° (+25° to −25°).

That is, when an ion beam of low energy of 100 eV or less is used, impurities resulting from the collimator can be inhibited from being mixed into the processed layer.

Therefore, etching of members forming the collimator by irradiation of an ion beam of 100 eV or less can be suppressed.

When used for etching by an ion energy of 100 eV or less, the collimator 75 having the above voids 759 can inhibit constituent components of the collimator 75 from being implanted in the substrate when the processed layer (MTJ element) is processed and the constituent components from being mixed into the processed layer.

In addition to the conductive material such as carbon, an insulator such as boron nitride (BN) and alumina may also be used as a material to form the collimator 75. The shape of the voids 759 in the collimator 75 is not limited to the rectangular shape (grid-like) and may be circular, elliptic, or polygonal.

In the example shown in FIGS. 27A and 27B, the collimator 75 is provided between the cathode 21Z and the anode 22 of the ion source 2. An electron flow from the cathode 21Z is supplied to a region on the opposite side of the anode with respect to the collimator 75.

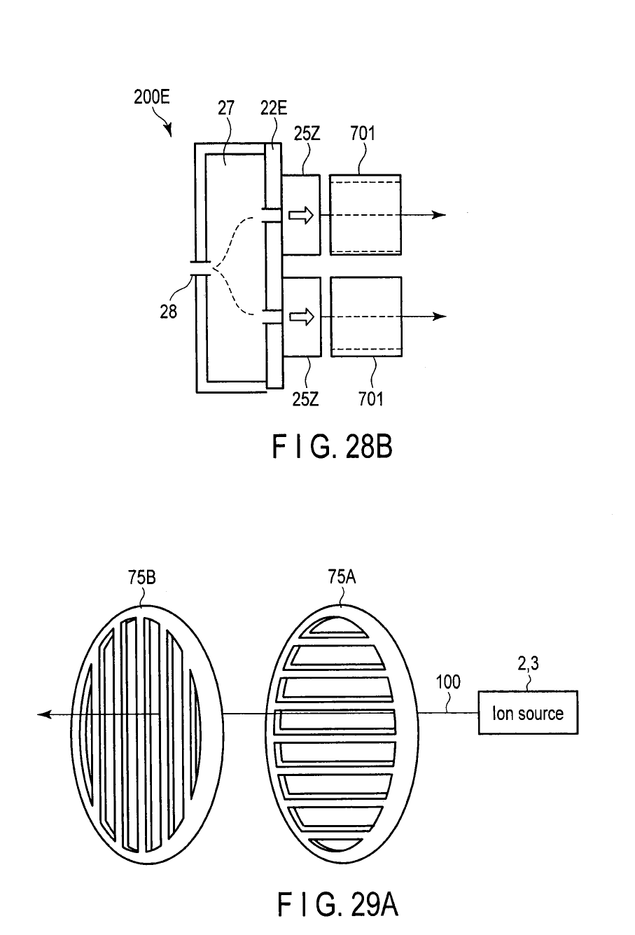

FIG. 28A shows a modification of the ion source having a collimator shown in FIGS. 27A and 27B.

As shown in FIG. 28A, the collimator 75 may be provided on the outer side (processed layer side) from the cathode 21Z. An electron flow from the cathode 21Z is supplied to a region between the collimator 75 and the anode 22 along the emission direction of an ion beam.

A plurality of collimators may be provided for an ion source.

As shown in FIG. 28B, a collimator may be provided in an ion beam generator (ion source) using an anode (anode magnet) made of a cylindrical magnetic body.

FIG. 28B is a sectional view showing a configuration example of the ion beam generator using an anode magnet including a collimator.

As shown in FIG. 28B, each of the cylindrical anode magnets 25Z is provided with a collimator 701. By setting, for example, the potential of the collimator 701 to a floating state, the solid angle of an ion beam can be controlled to a preferable angle.

A collimator may be provided for a plurality of anode magnets so that the collimator is shared by the anode magnets 25Z.

Incidentally, the above collimator may be provided in a cylindrical ion source.

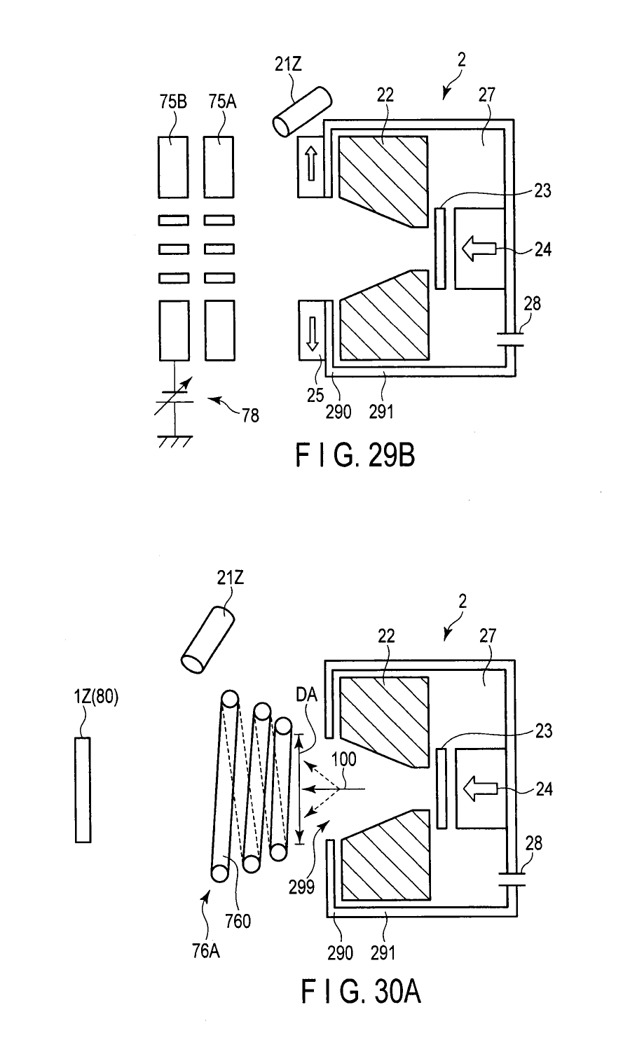

FIGS. 29A and 29B show a configuration example when an ion beam from an ion source is controlled by using a plurality of collimators.

For example, as shown in FIG. 29A, a plurality of collimators 75A, 75B with different wall orientations (lattice extending directions) may be arranged for the ion sources 2, 3 so as to overlap in the emission direction of an ion beam.

When, as shown in FIG. 29B, the collimators 75A, 75B are provided for the one ion source 2, a potential may be applied to the collimators 75A, 75B. In FIG. 29B, for example, the collimator 75A on the side of the ion source 2 is set to a floating state. The collimator 75B provided on the outer side (processed layer side) of the collimator 75A is connected to a power supply (variable DC power supply) 78. A predetermined potential is applied to the collimator 75B. Thus, controllability of the angle of divergence (solid angle) of an ion beam can be improved by the collimators 75A, 75B in different potential states being provided in the one ion source 2.

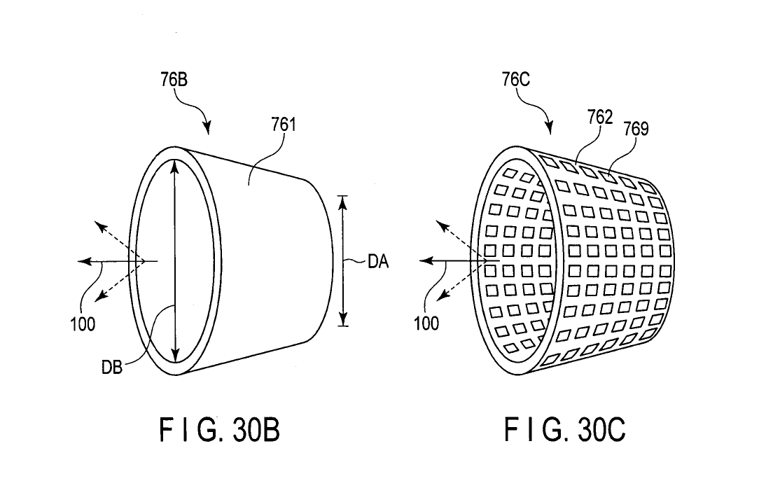

FIGS. 30A to 30C show a modification of the collimator provided in an ion source.

As shown in FIG. 30A, a collimator 76A may have a coiled structure.

The coiled collimator 76A is arranged near the ion beam emission port 299 of the ion source 2. As described above, the hollow cathode 21Z may be provided between the substrate and the collimator 76A (the opposite side of the anode across the collimator) or between the ion source 2 and the collimator 76A.

The potential state applied to the collimator 76A is propagated to plasma (ions) to form the ion beam 100 by the coiled collimator 76A so that the discharge region (ion beam passing region) of the ion source 2 can be limited.

The coiled collimator 76A can be formed by using a wire (for example, a metal wire) 760, thus the area of the collimator 76a where the ion beam 100 hits is small. Thus, even if the constituent member 760 of the collimator 76A is etched by the ion beam 100, mixing of impurities resulting from the collimator 76A can be reduced to a minimum.

For example, in FIG. 30A, the coiled collimator 76A is formed in consideration of the spread of an ion beam so as to have a shape in which the diameter of the coil gradually increases from the side of the ion source 2 toward the side of the substrate. An opening dimension (coil diameter) DA on the side of the ion source 2 in the collimator 76A is smaller than an opening dimension DB on the side of the substrate in the collimator 76A.

Incidentally, as shown in FIG. 30B, a collimator 76B may be formed from a cylindrical partition wall 761 extending from the side of the ion source to the side of the substrate. The opening through which an ion beam passes has a ring shape. The opening to emit the ion beam 100 in the collimator 76B to the substrate may be circular or polygonal (for example, hexagonal). For example, the dimension DA of the opening portion on the side of the ion source in the cylindrical collimator 76B is smaller than the dimension DB of the opening portion on the side of the substrate in the collimator 76B.

As shown in FIG. 30C, a partition wall 762 of a collimator 76C may be like a grid. In FIG. 30C, rectangular (quadrangular) voids (through holes) 769 are formed in the partition wall 762.

However, the polygonal voids 769 may be formed in the partition wall 762 such that the partition wall 762 has a honeycomb structure made of a plurality of the hexagonal voids 769. The opening shape of the void 769 formed in the grid-like partition wall 762 in the collimator may be circular.

The discharge state to form plasma is stabilized by the collimators 76A, 76B, 76C in the FIGS. 30A to 30C being provided for the ion sources 2, 3 so that ion beam conditions can be expanded and the discharge at low gas pressure is enabled.

By providing a structure like a collimator or convergence ring between the ion source and the substrate on which a member to form a magnetoresistive effect element is formed and devising the shape of the collimator (or the convergence ring) as described above, excessive dispersion of an ion beam can be suppressed and also the magnetoresistive effect element and the process windows of the magnetoresistive effect element and devices including the magnetoresistive effect element can be expanded.

By providing a magnetic field generation mechanism in the collimator, the solid angle of an ion beam from the ion source may be adjusted.

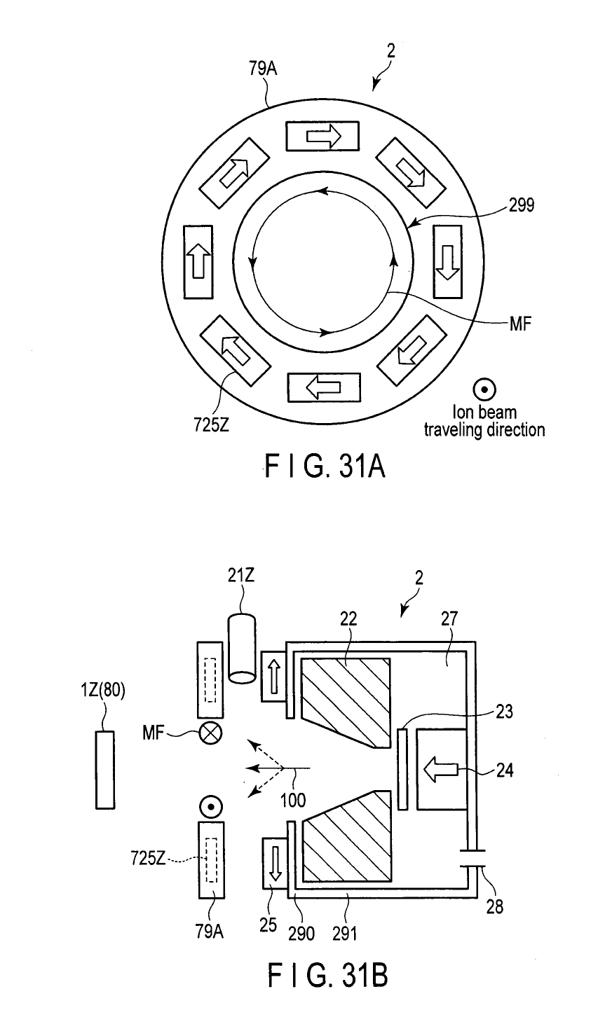

FIGS. 31A to 31C show a configuration example of a collimator having a magnetic field generation mechanism.

FIG. 31A shows a plan view when the collimator having a magnetic field generation mechanism is viewed from the side of the substrate (processed layer side). FIG. 31B shows a sectional structure of the ion source 2 with a collimator having a magnetic field generation mechanism.

As shown in FIG. 31B, an ion beam from the ion source is emitted from the drawing depth side toward the drawing front side.

In FIGS. 31A and 31B, a magnet (for example, a permanent magnet) 725Z is embedded in a collimator (or a convergence ring) formed by using a non-magnetic body such as a ceramic. The magnet 725Z is provided along the circumferential direction of the opening 299 in the collimator 79A having the circular opening (emission port) 299 so that the polarity of a magnetic field is generated.

The magnet 725Z is provided in such a way that the orientation of the N pole of the magnet 725Z is an RLC direction in the traveling direction (emission direction) of an ion beam from the side of the ion source toward the side of the substrate (counterclockwise when viewed from the side of the ion beam). The magnetic field (magnetic flux) MF generated in the opening 299 of the collimator 79A by the magnet 725Z is an RRC direction in the traveling direction (emission direction) of an ion beam in the opposite direction of the N pole of the magnet 725Z (clockwise when viewed from the side of the ion beam). The strength of the magnetic field MF (magnetic flux density) increases rapidly when moving closer to the collimator 79A. Thus, the annular magnetic field MF is formed by the collimator 79A.

Due to an interaction between a current of positive ions and the magnetic field MF of the collimator 79A, vector components of ions moving toward the collimator 79A are curved toward the beam emission direction (center side of the opening 299).

As a result, a positive ion beam emitted from the plasma generation region (anode) in a widely dispersed state is curved from the side of the collimator 79A toward the center side of the emission port 299 in the trajectory thereof when moving closer to the collimator 79A. Thus, the ion beam 100 can be prevented from etching the collimator 79A and constituent components of the collimator 79A can be inhibited from attaching to the substrate and the processed layer.

An electron beam output from the hollow cathode 21Z flows into the collimator 79A having the annular magnetic field MF from the opposite direction of an ion beam. The electron beam is also deflected by a Lorentz force of the magnetic field MF toward the center of the collimator 79A. Ions converge toward the electron beam converged toward the center of the collimator 79A. Thus, when an electron beam is supplied to the collimator 79A generating the annular magnetic field MF from the direction opposite to the traveling direction of an ion beam, the convergence of the ion beam is improved when compared with a case in which only ions are supplied.

FIG. 31C shows a modification of the ion source including the collimator having a magnetic field generation mechanism.

As shown in FIG. 31C, the collimator 79A having a magnetic field generation mechanism may also be used for the cylindrical ion source 3.

FIGS. 31D and 31E show an example of the ion source including the collimator having a magnetic field generation mechanism configured differently from FIGS. 31A to 31C.

FIG. 31D shows a plan view when the collimator having a magnetic field generation mechanism is viewed from the side of the substrate (laminated structure/processed layer side) and FIG. 31E shows a sectional view of the ion source including the collimator having a magnetic field generation mechanism.

As shown in FIGS. 31D and 31E, a plurality of collimators 79A, 79B may be stacked in the traveling direction (emission direction) of an ion beam.

When the collimators 79A, 79B are provided, a diameter (opening dimension) DD2 of the collimator 79B on the side of the substrate 80 (the opposite side of the anode) of the collimators 79A, 79B is set larger than a diameter DD1 of the collimator 79A on the side of the ion source 2 (anode side).

Thus, with the collimators 79A, 79B being provided between the ion source 2 and the substrate, if the dispersion (solid angle) of the ion beam 100 is excessive, the excessive dispersion can efficiently be suppressed.

With the magnetic field generation mechanism 725Z being provided in the collimators as shown in FIGS. 31A to 31E, the opening dimensions of the collimators 79A, 79B do not have to be limited to the size close to the opening dimension of the ion source 2. For example, even if the opening dimensions of the collimators 79A, 79B are close to the opening dimension of a vacuum chamber (not shown) surrounding the ion source 2, the inner wall of the vacuum chamber can be inhibited from being sputtered by an ion beam.

As well as being installed adjacent to the ion source, the collimator may be installed in an intermediate position of the ion source and the substrate or near the substrate on which a laminated structure to form an MTJ element is formed. The collimators 79A, 79B may be provided in a region between the cathode 21Z and the ion source 2. The cathode 21Z may be provided between the two collimators 79A, 79B. Further, a collimator may be provided for a plurality of ion sources so that ion beams from the ion sources 2, 3 pass through a collimator.

Thanks to the collimator 75, as described above, an excessive solid angle of an ion beam can be suppressed and the solid angle of an ion beam can be adjusted to 60° or less, preferably 45° or less.

Incidentally, the collimator (and the convergence ring) provided to adjust the solid angle of an ion beam may be viewed as part of an irradiation unit/generation unit (ion beam generator) of an ion beam.

The dispersion of an ion beam may be controlled by controlling the distribution of an electron beam discharged from the cathode.

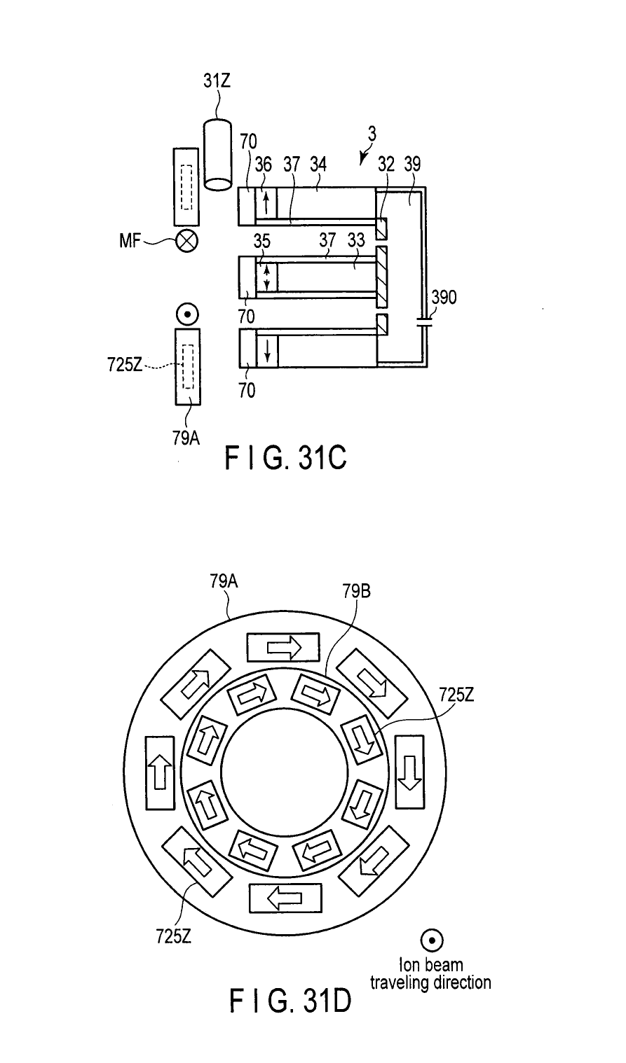

FIG. 32A schematically shows the principle of an ion source (ion beam generator) to control the dispersion of an ion beam by controlling the distribution of an electron beam from the cathode.

As shown in FIG. 32A, the cathode 21Z (31Z) is provided between the substrate 80 on the substrate holding unit (substrate fixing stage) 800 and the end Hall ion source 2 (or the cylindrical ion source 3). The laminated structure (processed layer) 80 to form an MTJ element is formed on the substrate 80.

The ion beam 100 is emitted from the ion source 2 toward the substrate 80 in a shape following the distribution of an electron beam EF discharged from the cathode (for example, the hollow cathode) 21Z.

Therefore, the ion beam 100 irradiated on the substrate 80 on which the processed layer 1Z is formed is a narrowed shape from the ion source 2 toward the side of the substrate 80 following the distribution of the electron beam EF by the electron beam EF being discharged from the neighborhood of the substrate 80 on which the laminated structure to form an MTJ element is provided toward the anode of the ion source 2. A portion of the electron beam EF from the cathode 21Z reaches the substrate 80 on the installation stage 800 before being neutralized.

Thus, when an ion beam is controlled according to the distribution of the electron beam, the cathode 21Z to supply the electron beam EF is desirably arranged on the side of the substrate from the intermediate point between the ion source 2 and the substrate 80.

By supplying electrons from the cathode to the anode by considering the distribution of the electron beam EF from the cathode 21Z, excessive dispersion of the ion beam 100 can be suppressed.

Incidentally, when electrons are supplied to the anode of the ion source 2, it is desirable to set a positive potential to the cathode 21Z with respect to the vacuum chamber (not shown) set to the ground potential.

FIG. 32B shows an example in which a collimator is provided between the ion source and the substrate on which a processed layer is formed.

As shown in FIG. 32B, more than half the traveling path of the ion beam 100 from the ion source 2 to the substrate 80 may be covered with collimators 700. The collimator 700 includes a partition wall extending in a direction parallel to the emission direction of an ion beam.

For example, the path of more than half the distance from the ion source 2 to the substrate 80 of the traveling path of the ion beam 100 output from a plurality of the Hall ion sources 2 is covered with the cylindrical collimators 700 formed of boron nitride. The ion beam 100 passes through the inside (through hole) of the collimator 700.

The cathode 21Z is provided between the collimator 700 and the substrate 80.

When, as described by using FIGS. 27A to 27C, an ion beam of 100 eV or less is irradiated, etching of the material (for example, Mo) forming the collimator 700 is significantly suppressed. Thus, by covering more than half the traveling path of an ion beam from the ion source 2 to the substrate 80 with collimators, excessive dispersion of an ion beam can be controlled without the processed layer on the substrate being contaminated with constituent elements of the collimator 700.

<Gas Cluster Ion Beam>

In the foregoing, the case when an ion beam is formed by using a monomer gas has been described. However, an ion beam may also be formed by an ionized gas cluster. When an ion beam is formed by a gas cluster, an ion beam having dispersion (solid angle) can be output.

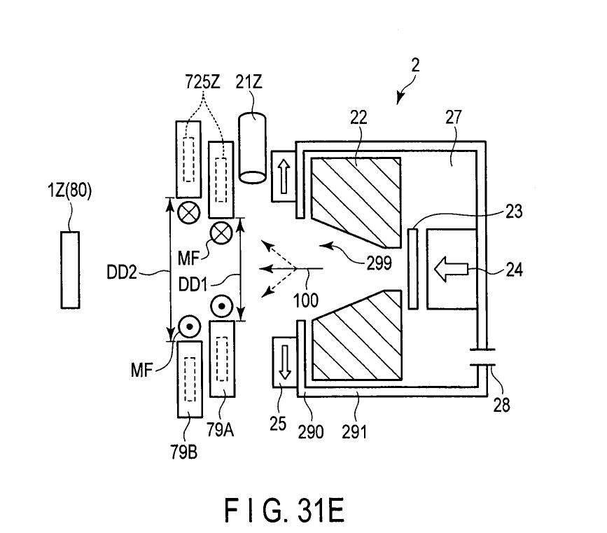

The configuration of an ion source that outputs an ion beam of a gas cluster having a solid angle will be described with reference to FIGS. 33 to 37B.

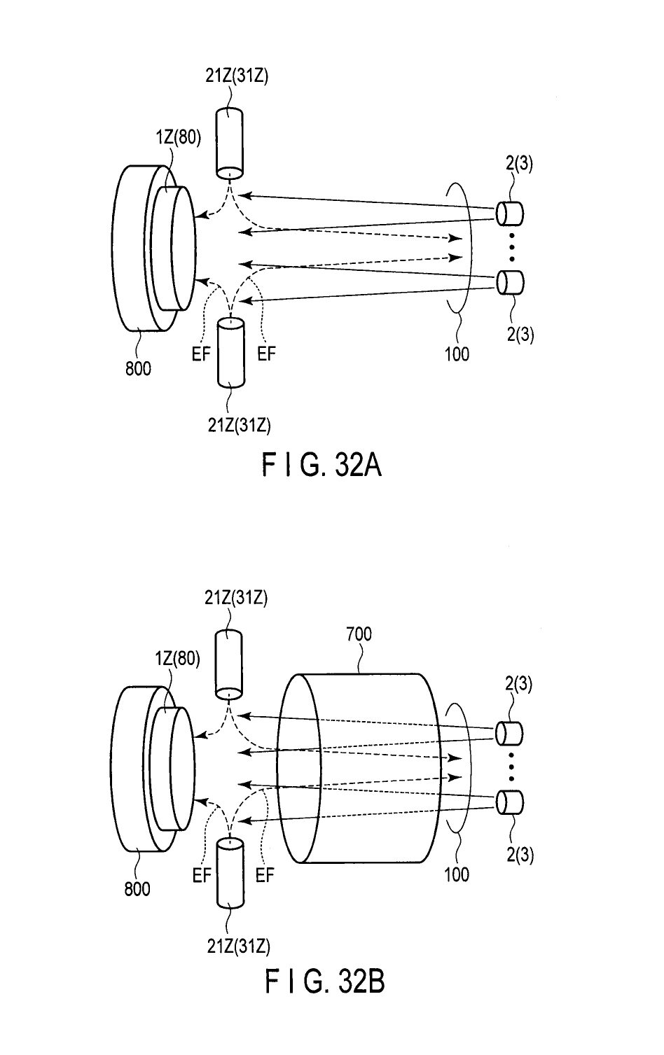

FIG. 33 shows a sectional structure and a planar structure of an ion source that outputs an ion beam by a gas cluster (GCIB: Gas Cluster Ion Beam). FIG. 34 is a diagram illustrating the process of a gas supplied to the ion source until the gas is clustered.

In the example shown in FIG. 33, an ion beam by a gas cluster is formed by the above cylindrical ion source. However, a gas cluster ion beam may also be formed by an end Hall ion source.

When, as shown in FIGS. 33 and 34, an ion beam is formed from a gas cluster, an inner wall (sectional shape along the extending direction of the pipe) of a gas introduction hole (gas supply pipe, nozzle) 48 is processed into a hyperbolic shape.

The gas to form GCIB is supplied into a gas pressure chamber 49 as a monomer gas GA. Then, when the gas (atoms) GA moves from the gas pressure chamber side to the discharge region side via the nozzle 48, a pressure in accordance with the sectional shape of the nozzle 48 on the gas pressure chamber side and the discharge region side is applied to the atoms GA constituting the gas. The gas output from the side of the gas pressure chamber 49 to the discharge region side causes adiabatic expansion before the gas (atoms) is clustered.

A formed gas cluster GC is ionized when passing through a high electron density region near magnets 45, 46 on an inner wall 43 and an outer wall 44 of an ion source 4 and accelerated as a gas cluster ion beam (GCIB). The substrate on which a laminated structure is formed is irradiated with a gas cluster ion beam formed from a plurality of atoms (ions) GC. A gas cluster ion beam has a relatively large solid angle (for example, 10°) by the gas cluster ion beam being formed by a cylindrical ion source (or an end Hall ion source)

Thus, when an ion beam including a solid angle (dispersion) is formed from a gas cluster ion beam, the many-body collision effect specific to the gas cluster ion beam can be added to the etched laminated structure when the processed layer (laminated structure) on the substrate is etched.

For example, an irradiation portion of a gas cluster ion beam in the laminated structure rises to a high temperature instantaneously and locally, thus defects generated on the etching surface of the processed layer can be repaired by the heat generated by the collision of the cluster gas.

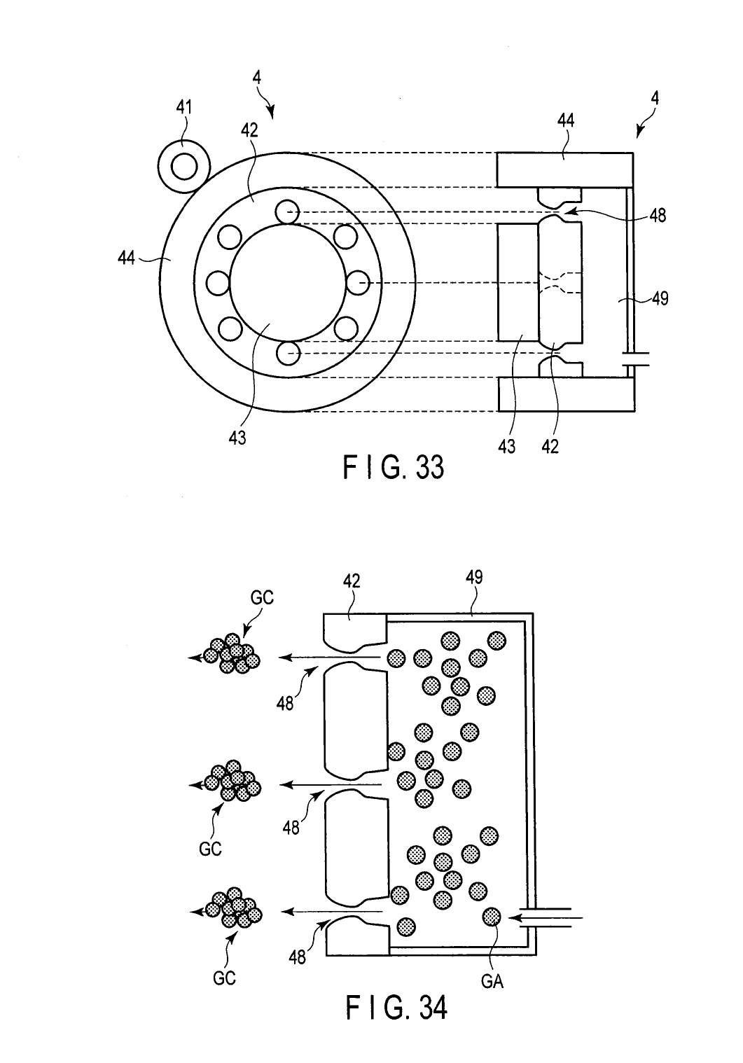

Incidentally, the nozzle to form a gas cluster is formed by, for example, the process shown in FIGS. 35A to 35D.

FIGS. 35A to 35D are sectional process drawings showing each formation process of a nozzle to form a gas cluster. As shown in FIG. 35A to 35D, the nozzle 48 to discharge a gas from the gas pressure chamber side to the discharge chamber side to form a gas cluster can be formed by using a patterning process of a thin film. Accordingly, many small holes as gas introduction holes can be formed in a size of the order of micrometers.

As shown in FIG. 35A, the back side of an Si (001) plane substrate 490 is coated with an Au film 491 for lamination. A resist film 499 is applied to the front side of the Si (001) plane substrate 490 (surface opposed to the surface on which the Au film 491 is formed). The resist film 499 is patterned by lithography so that a rectangular opening is formed in the resist film 499. The front side of the Si (001) plane substrate 490 is exposed via the opening of the resist film 499.

As shown in FIG. 35B, an etch pit is formed on the front side of the Si (001) plane substrate 490 by a mixed solution of HF (fluoric acid) and H₂O₂ (hydrogen peroxide solution). The Si (001) plane substrate 490 is etched from the front side to the back side of the Si (001) plane substrate 490 around the etch pit by isotropic etching based on wet etching. Accordingly, a through hole 410 in a pyramidal sectional shape is formed in the Si (001) plane substrate 490. The opening dimension (aperture) of the through hole 410 on the front side (resist film side) of the Si (001) plane substrate 490 is larger than the opening dimension (aperture) of the through hole 410 on the back side (Au film side) of the Si (001) plane substrate 490.

Also, the Au film 491 at the position corresponding to the hole on the back side of the Si (001) plane substrate 490 is removed by ion beam etching from the front side of the Si (001) plane substrate 490. Accordingly, a through hole 411 is formed in the Au film 401.

Incidentally, wet etching using a mixed solution of HF and H₂O₂ may be combined with RIE of SF₆ (sulfur hexafluoride) or CF₄ (tetrafluoromethane) or plasma irradiation. In addition, the Au film 491 may be coated with a resist film by forming the resist film on the Au film 491.

A plurality of the Si (001) plane substrates 490 having the pyramidal through hole 410 are prepared by the above process. A plurality of through holes 210 may be formed in the one Si (001) plane substrate 490.

As shown in FIG. 35C, the resist film is removed after the pyramidal through hole is formed in the Si (001) plane substrate 490.

As shown in FIG. 35D, the two Si (001) plane substrates 490 are aligned based on the position of the through hole on the back side of the Si (001) plane substrate 490 and the Au films 491 of the Si (001) plane substrates 490 are mutually laminated. The two pyramidal through holes 410 of the Si (001) plane substrates 490 are connected.

Accordingly, the nozzle 48 having a through hole in a hyperbolic sectional shape is formed.

As shown in FIGS. 35A to 35D, the most narrowed portion inside the through hole of the nozzle 48 can be set to a size of the order of a few micrometers by the nozzle 48 to form a gas cluster formed by a thin film process.

Thus, by limiting the aperture inside the through hole of the nozzle to a size that allows the viscosity of a gas fluid to become conspicuous, when compared with a case in which the narrowing size of a hyperbolic through hole is a few tens of micrometers or more, the dispersion (variation) of the size of the formed gas cluster can be decreased. The dispersion of the size of a gas cluster leads to a smaller energy dispersion per atom. That is, by making the size of a gas cluster uniform, fluctuations of the effect caused by irradiation of an ion beam can be reduced. As a result, the yield of the MTJ element formation can be improved.

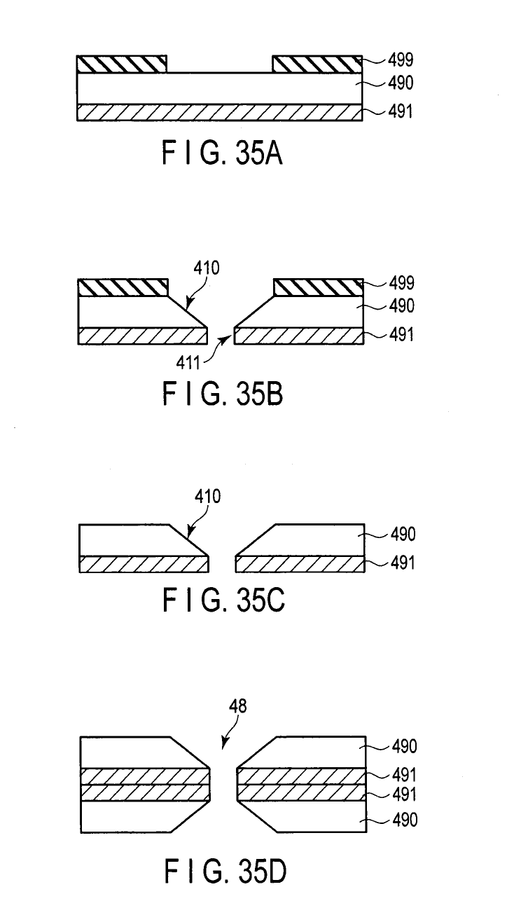

FIG. 36 shows a modification of the ion source that outputs a gas cluster ion beam.

As shown in FIG. 36, a side wall (protective plate) 47 may be provided on the inner wall of the discharge region in a plasma generating container 44.

The protective plate 47 is made of a hard-to-etch material, for example, a ceramic of alumina (aluminum oxide). With the inner wall of the discharge region being covered with the protective plate 47, the durability of an ion source 4Z that outputs GCIB can be improved or impurities resulting from the ion source 4Z can be prevented from being mixed into the MTJ element 1.

Like the ion source that outputs an ion beam from a monomer gas, an ion beam etching apparatus may be formed from a plurality of the ion sources 4 that output GCIB.

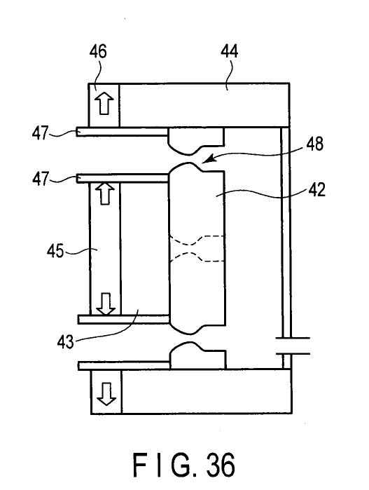

FIGS. 37A and 37B show a configuration example of an etching apparatus including a plurality if ion sources that output GCIB.

The ion beam etching apparatus in FIG. 37A is formed by using the four ion sources 4 that output GCIB.

As shown in FIG. 37B, an ion beam etching apparatus may be configured by combining the ion source 4 of GCIB and an ion source of a monomer ion beam so that an ion beam etching apparatus including both of the ion source 4 of GCIB and an ion source of a monomer ion beam.

FIG. 37B shows an example in which two units of the cylindrical ion source 3 of a monomer ion beam and two units of the ion source 4 of GCIB are placed side by side in an ion beam etching apparatus 400B. In the ion beam etching apparatus 400B, the number of the ion sources 3 of a monomer ion beam and the number of the ion sources 4 of a gas cluster ion beam may be different. Incidentally, an etching apparatus may be formed from an end Hall ion source and a GCIB ion source.

The irradiation of an ion beam of a monomer gas and the irradiation of GCIB may be performed separately or at the same time. After the laminated structure (processed layer) to form an MTJ element is processed at high energy and high speed by etching using an ion beam of a monomer gas, damage due to processing may be repaired by irradiation of GCIB. Also, the laminated structure may be etched and repaired concurrently by simultaneously irradiating the laminated structure with a monomer ion beam and GCIB. When the laminated structure is irradiated with an ion beam of a monomer gas and GCIB simultaneously, the time needed to form an MTJ element and a magnetoresistive memory can be shortened, contributing to the reduction of manufacturing costs.

Repairs to damage of the processed layer (magnetic layer) using the annealing effect by GCIB irradiation may be done after a protective film (for example, a silicon nitride film or aluminum oxide film) is formed on the sidewall of an MTJ element. In this case, not only the quality of the magnetic layer of an MTJ element, but also the quality of the protective film covering the MTJ element can be improved.

As a result, oxygen or moisture caused by annealing can be inhibited from diffusing into constituent members of the MTJ element after the magnetic layer and protective film are irradiated with GCIB. Thus, characteristics of the MTJ can be inhibited from deteriorating and the yield of the MTJ element can be improved.

As described above, characteristics of an MTJ element can be improved by enhancing the processing of the laminated structure to form the MTJ element using GCIB and constituent members of the MTJ element by irradiation of GCIB.

<Utilization of a Chemical Reaction of GCIB>

When a gas cluster ionized by a Hall ion source is irradiated as an ion beam, a chemical reaction by the gas cluster makes a contribution to enhancement of characteristics of the MTJ element.

When, for example, a laminated structure to form an MTJ element is irradiated with a gas cluster including about 100 atoms by an acceleration voltage in a region of 200 V to 300 V or less in which the discharge is relatively easy, activated elements of 2 eV to 3 eV or less per atom can be supplied to the substrate on which the laminated structure is formed.

If the energy for each atom contained in a gas cluster is equal, it is known that damage done to a processed layer (region to which a gas cluster is supplied) decreases with a decreasing size of the gas cluster.

Further, ions of a few eV can be formed by a gas cluster that cannot be formed by RIE or a monomer gas at equivalent high temperature and high pressure specific to the gas cluster and can be irradiated on a processed layer as GCIB.

Thus, chemically reactive processing by the irradiation of GCIB inflicting less damage than the irradiation of an ion beam of a monomer gas can be applied to processing of an MTJ element.

In the ion beam etching apparatus 400B including the ion source 4 of GCIB and the ion source 3 of a monomer ion beam as shown in FIG. 37B, GCIB of a second reactive gas can be supplied from the ion source 4 of GCIB to the substrate (processed layer) by setting the acceleration voltage of the ion beam 3 of a monomer ion beam to the threshold voltage (for example, 20 to 30 V) or less of sputtering (ionization) and supplying a first reactive gas from the ion source 3 of a monomer ion beam to the substrate (processed layer). When the acceleration voltage is ions is 0 V, the irradiation of gas by thermal energy occurs.

For example, the first reactive gas is supplied from the ion source 3 of a monomer ion beam to the substrate so that acetate ions (or an acetate gas) of the monomer have an energy (temperature energy) of a few tens of V or less. At the same time or alternately, the substrate is irradiated with GCIB of oxygen from the ion source 4 of GCIB. Oxides on a CoFe magnetic film are removed by a reaction of acetic acid and the oxides in the CoFe magnetic film as a processed layer on the substrate.

At this point, ions can preferentially be supplied to a portion to be etched of the processed layer by attaching the beam spread (incident angle with respect to the processed layer) to acetate ions in the range of energy of the threshold voltage of sputtering (etching) (generally, about to 20 to 30 V). That is, when the bottom side of the processed layer should be etched, an ion beam of acetic acid is caused to be incident in a direction perpendicular to the surface of the substrate on which the processed layer is formed. When the side face of the processed layer should be etched, an ion beam of acetic acid is irradiated on the processed layer irradiated with by inclining the substrate with respect to the ion source, for example, inclining the substrate 45° with respect to the emission direction of an ion beam emitted from the ion source.

In addition, anisotropy of etching of the processed layer can be enhanced by simultaneous or alternate irradiation of a monomer ion beam of acetic acid and GCIB of oxygen.

For example, a gas including at least one of a halogen containing gas, CO₂, CO, N₂, O₂, NH₃, N₂O, CH₃OCH₃, and a rare gas is irradiated as GCIB. Halogen containing gases to form a gas cluster include F₂, CHF₃, CF₄, C₂F₆, C₂HF₅, CHClF₂, NF₃, SF₆, C₁F₃, C₁₂, HCl, CClF₃, CHCl₃, CBrF₃, and Br₂. Rare gases to form a cluster gas include He, Ne, Ar, Kr, and Xe.

When GCIB is used, at least one of the halogen containing gas, HNO₃ (nitric acid), H₃PO₄ (phosphoric acid), H₂SO₄ (sulfuric acid), H₂O₂ (hydrogen peroxide), CH₃COOH (acetic acid), CO₂ (carbon dioxide), CO (carbon monoxide), N₂ (nitrogen), O₂ (oxygen), NH₃ (ammonia), N₂O (nitrogen monoxide), and CH₃OCH₃ (methylethanol) may be ionized and supplied to the substrate (processed layer).

Halogen containing gases supplied to the substrate during irradiation of GCIB include F₂, CHF₃, CF₄, C₂F₆, C₂HF₅, CHClF₂, NF₃, SF₆, ClF₃, Cl₂, HCl, HF, CClF₃, CHCl₃, CBrF₃, and Br₂.

By supplying an ion beam of the threshold voltage or less of sputtering (discharge) of a reactive gas by changing the angle (inclination) of the substrate with the ion source (emission direction of an ion beam), a distribution of the amount of supply of an ion beam can be formed between the bottom side and the side face of the processed layer on the substrate. Accordingly, an MTJ element can be formed by more anisotropic ion beam etching.

<Formation of an Ion Beam Having a Solid Angle Using a Grid Ion Source>

In the above examples, an ion beam of a large solid angle is generated by using an ion source (a gridless ion source or Hall ion source) having no grid and irradiated on the processed layer.

However, an ion beam having a large solid angle (for example, a solid angle of 10° or more) can also be output by using an ion source having a grid.

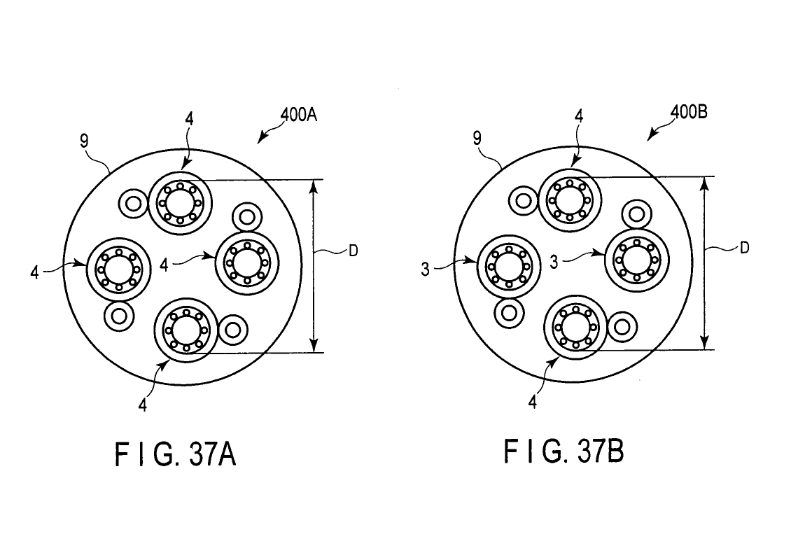

The configuration of a grid ion source that outputs an ion beam having a large solid angle will be described below with reference to FIGS. 38 to 43.

FIG. 38 is a sectional view showing a configuration example of the ion source having a grid.

For example, a general Kauffmann-type ion source using a cathode made of a hot filament is used as an ion source 5.

As shown in FIG. 38, a filament 51 to be a cathode and an anode 52 are provided in a plasma generating container 54. The filament 51 is connected to a DC power supply 57A and the anode 52 is connected to a DC power supply 57B. The anode 52 has, for example, a cylindrical shape. A gas to form an ion beam is supplied into the plasma generating container 54 via a gas introduction pipe (nozzle). A coil 55 that generates a magnetic field to converge plasma is provided outside the plasma generating container 54 to surround the plasma generating container 54.

For example, a grid 50 including three grid electrodes 501, 502, 503 is provided on the side of the ion beam emission of the plasma generating container 54 of the grid ion source 5 in FIG. 38. The screen grid electrode 501, the acceleration grid electrode 502, and the deceleration grid electrode 503 are provided from the side of the plasma generating container toward the side of the processed layer (substrate) in this order. The beam spread of an ion beam can be controlled by controlling the potential of the grid (grid electrode).

The ion beam 100 including dispersion (solid angle) can be formed by increasing the hole diameter (opening dimension) of the screen grid electrode 501, the acceleration grid electrode 502, and the deceleration grid electrode 503 in the order of the screen grid electrode 501, the acceleration grid electrode 502, and the deceleration grid electrode 503. Though an example in which an opening is formed for each of the grid electrodes 501, 502, 503 is schematically shown in FIG. 38 for clarification of the illustration, a plurality of openings are arranged in an array shape in each of the grids 501, 502, 503. Openings of each of the grids 501, 502, 503 will be described later.

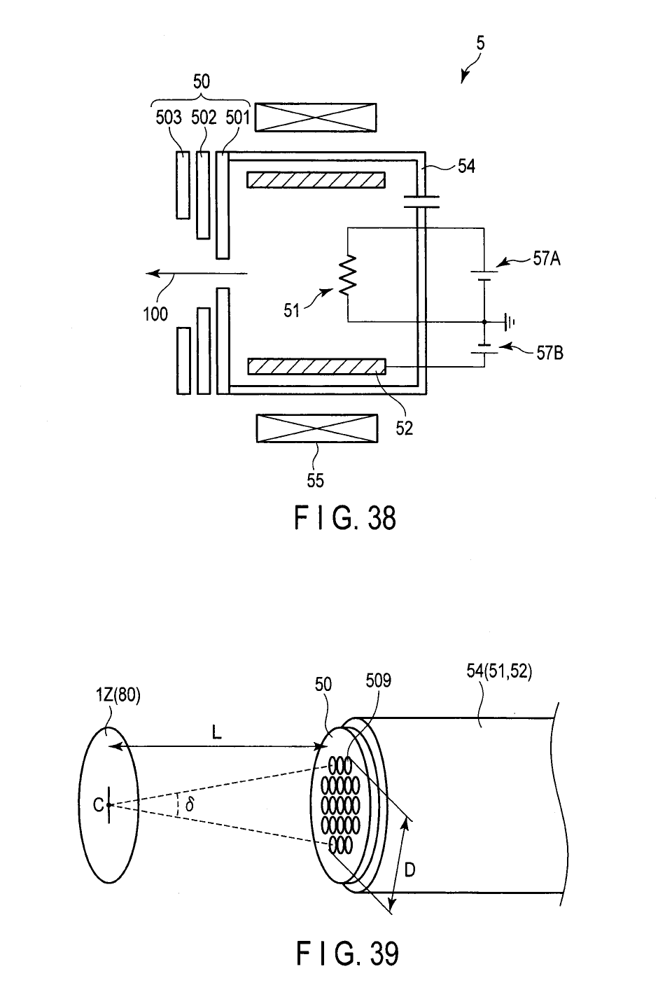

The solid angle of an ion beam from the grid ion beam 5 will be described by using FIG. 39.

FIG. 39 shows the relationship between the solid angle δ of an ion beam from the grid ion source 5 and the value D and the value L to set the solid angle δ.

Substantially like the gridless ion source, the distance from the center C of the substrate 80 on which the processed layer (laminated structure) 1Z is formed to the grid 50 of the ion source 5 is set as “L”.

As shown in FIG. 39, the grid 50 has a plurality of openings (holes). The value D in the grid ion source 5 is the maximum dimension of the distribution of a plurality of holes 509 (formation region of a plurality of holes) of the grid 50.

Thus, the solid angle δ of an ion beam in the grid ion source 5 can be represented by the relationship tan δ=0.5×D/L. Like the gridless ion source (Hall ion source), setting the solid angle δ of an ion beam from the grid ion source 5 to 10° or more and 60° or less (preferably 45° or less) is preferable for processing an MTJ element.

The grid 50 of the ion source 5 may be provided by using only the screen grid electrode 501 and the acceleration grid electrode 502 without providing the three grid electrodes 501, 502, 503.

An ion beam output from a grid ion source (Kauffmann-type ion source) in which two grid electrodes stacked in the emission direction of an ion beam are used will be described.

The two grid electrodes are stacked in the emission direction of an ion beam. A floating potential is applied to the screen grid electrode on the inner side (plasma generating container side) of the two grid electrodes and a feeder potential is applied to the acceleration grid potential on the outer side (processed layer side).

Each meshed grid electrode is formed of a flat circular plate without applying a curved structure. The diameter of each grid electrode is, for example, 300 mm.

In a meshed grid electrode, square holes (voids) whose sides are each about 1 cm long are arranged at a pitch of 1.2 cm.

The aperture ratio (ratio of the area of a hole to the unit area of the electrode) near the center of a grid electrode is calculated as (1 cm×1 cm)/(1.2 cm×1.2 cm) and is about 69%.

To obtain an ion beam with a large solid angle (dispersion angle, divergence angle) from a grid ion source, it is preferable to apply a grid whose aperture ratio is 50% or more. The aperture ratio of the above end Hall ion source and the cylindrical ion source having no grid is 100%.

When an ion beam of Xe is generated by using a grid ion source using two grid electrodes having such an aperture ratio, the voltage (beam voltage) between the anode 52 and the ground is set to about 200 V and the voltage (feeder potential) applied to the acceleration grid electrode 502 is set to about −50 V. At this point, the degree of vacuum in the plasma generating container 54 is set to about 4×10⁻² Pa.

An ion beam of Xe generated by the grid ion source 5 including the two meshed grid electrodes 501, 502 has the solid angle δ of about 20°.

Thus, an ion beam having a large solid angle can be formed by using the grid ion source 5.

Incidentally, by forming the grid ion source 5 using only the deceleration grid electrode 503, the ion source 5 capable of generating an ion beam having a relatively large solid angle can be provided at still lower prices. If the number of grid electrodes decreases, maintenance costs of the grid ion source 5 can be reduced and the solid angle (dispersion) of an ion beam is more likely to be generated.

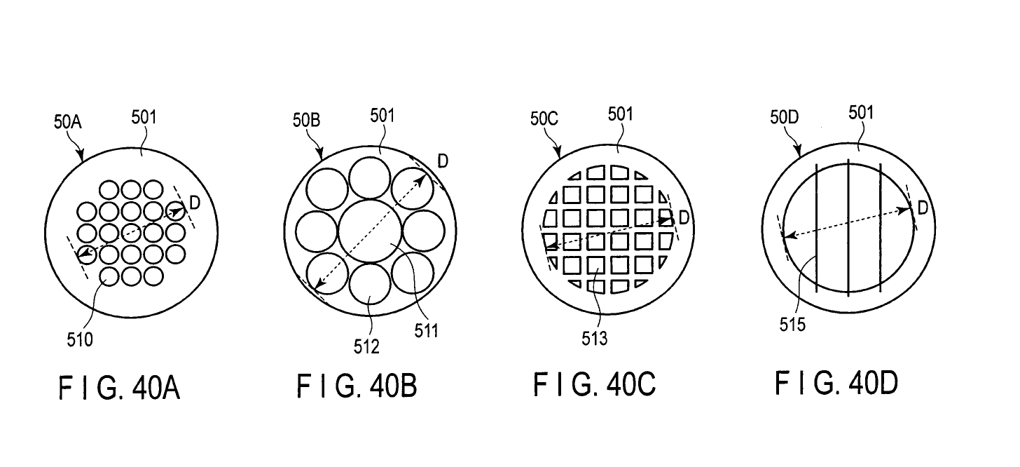

The structure of a grid (grid electrode) using a grid ion source will be described by using FIGS. 40A to 40D.

FIGS. 40A to 40D are top views showing configuration examples of the grid.

For example, as shown in FIG. 40A, a grid 50A may be shaped to have holes 510 in the flat plate 501.

Circular holes with a diameter of 5 mm are formed in the grid 50A. For example, the flat plate of the grid 50A may be formed of cheap stainless steel.

As shown in FIG. 40B, a grid 50B may be structured to have holes of different sizes in the flat plate 501. In the grid 50B of FIG. 40B, for example, a circular hole 511 whose diameter is 2 cm is formed in the center of the flat plate 501 and circular holes 512 whose diameter is 1.5 cm are formed around the perimeter thereof.

As shown in FIG. 40C, a grid 50C having rectangular holes formed therein may be used as the grid ion source 5. For example, rectangular holes 513 of 1 cm×1 cm are arranged at a pitch of 1:2 cm pitches. The grid 50C has a grid-like (meshed) plane shape.

The rectangular hole 513 is formed by the stainless flat plate 501 being punched. Incidentally, the grid 50C having rectangular holes may be formed by a plurality of straight flat plates being mounted on a ring-shaped flat plate so that the straight flat plates cross each other.

As shown in FIG. 40D, a grid-like grid 50D may be formed by wires or straight flat plates 515 being mounted on the ring-shaped plate 501.

In FIG. 40D, for example, tungsten wires with a diameter of about 0.5 mm are mounted on the ring-shaped plate 501.

The grids 50A, 50B, 50C, 50D can be formed as described above at low cost. Then, an ion beam having a relatively large solid angle can be formed by the ion source 5 using inexpensive grids (grid electrodes).

By using the grids as shown in FIGS. 38 to 40D, not only the solid angle (dispersion of the incident angle with respect to a processed layer) of an ion beam, but also the dispersion of energy of an ion beam can be increased.

Thus, according to a grid ion source using inexpensive (simply structured) grids, not only the cost to manufacture MTJ elements and magnetoresistive memories including MTJ elements (for example, maintenance costs) can be reduced, but also the performance of MTJ elements can be improved.

Like the above end Hall ion source and cylindrical ion source, an ion beam generator (ion beam etching apparatus) that outputs an ion beam with a large solid angle by using a plurality of grid ion sources can be provided inexpensively.

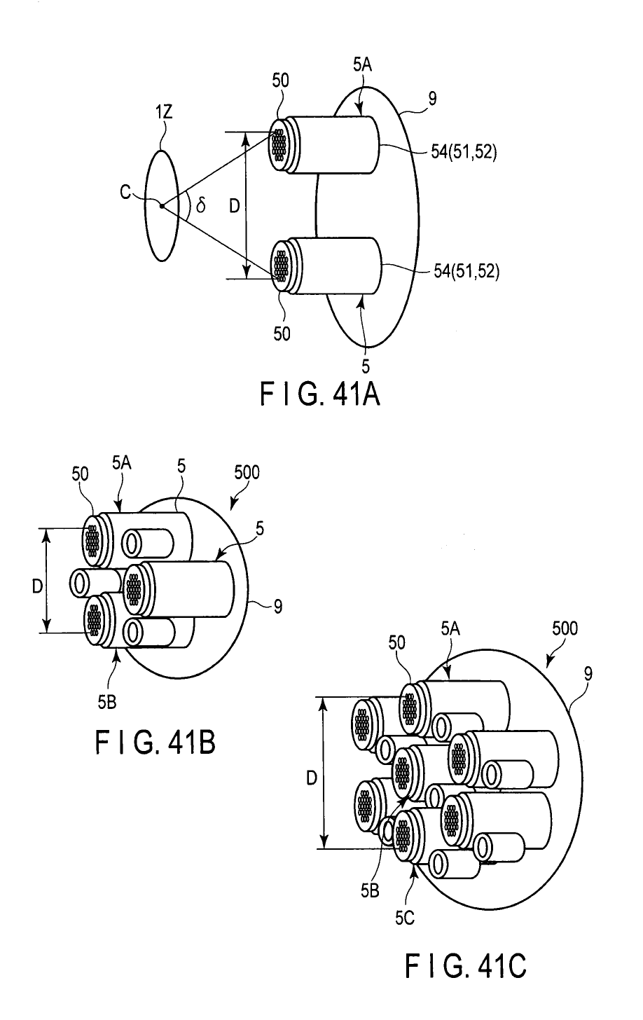

FIGS. 41A to 41C show a configuration example of the ion beam generator (ion beam etching apparatus) formed by using a plurality of grid ion sources.

FIG. 41A shows an ion beam generator 500 configured by two grid ion sources 5A, 5B.

FIG. 41B shows the ion beam generator 500 configured by the three grid ion sources 5.

FIG. 41C shows the ion beam generator 500 in which the seven grid ion sources 5 are used. As shown in FIGS. 41B and 41C, for example, neutralizers may be provided outside the plasma generating container 54 of an ion source.

When, as shown in FIGS. 41A to 41C, the one ion beam generator 500 is formed by using a plurality of the grid ion sources 5, like when an ion beam generator is formed by using a plurality of Hall ion sources, the value D to set the solid angle δ with respect to the processed layer 1Z is set to the distance between endmost portions of holes of the grids 50 of a plurality of the grid ion sources 5 aligned on the same straight line on the stage 9.

A grid ion source having a grid with a larger area becomes more expensive. On the other hand, the price of the grid ion source 5 declines rapidly with a decreasing size thereof.

Thus, when compared with a case in which an ion beam generator is formed by using a grid ion source, as shown in FIGS. 41A to 41C, an ion beam generator configured by using a plurality of the grid ion sources 5 smaller in size for the same occupation area (apparatus size) becomes less expensive and also maintenance costs thereof can be reduced.

In FIGS. 39 to 41C, examples of increasing the dispersion (solid angle) of an ion beam by devising the configuration of the grid (grid electrode) of a grid ion source and adjusting the beam spread of an ion beam have been described.

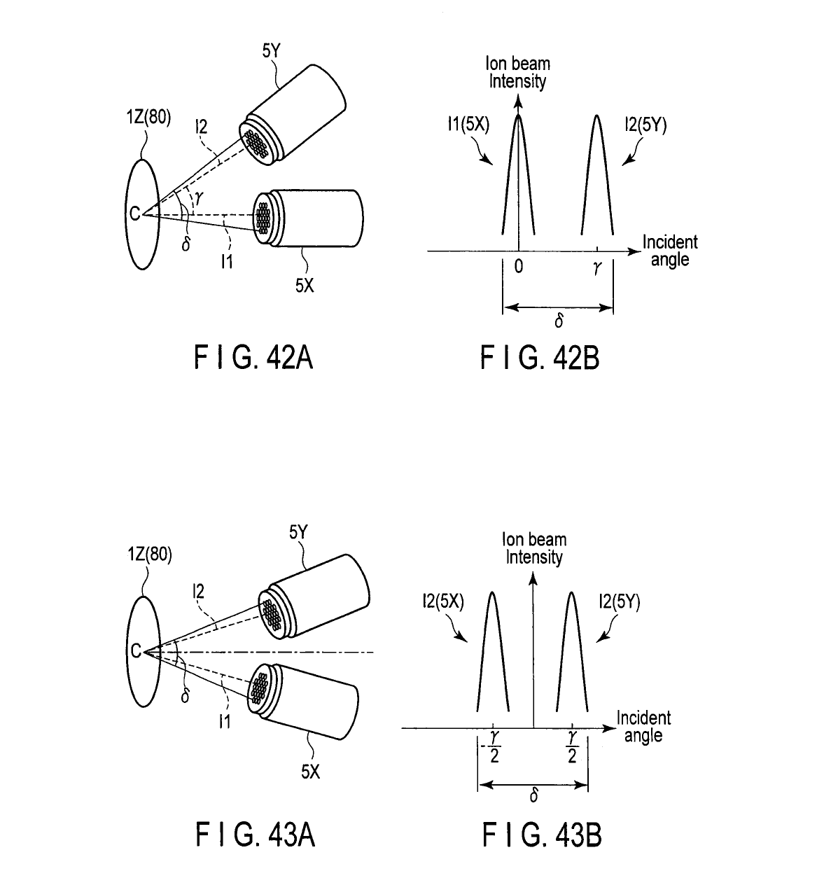

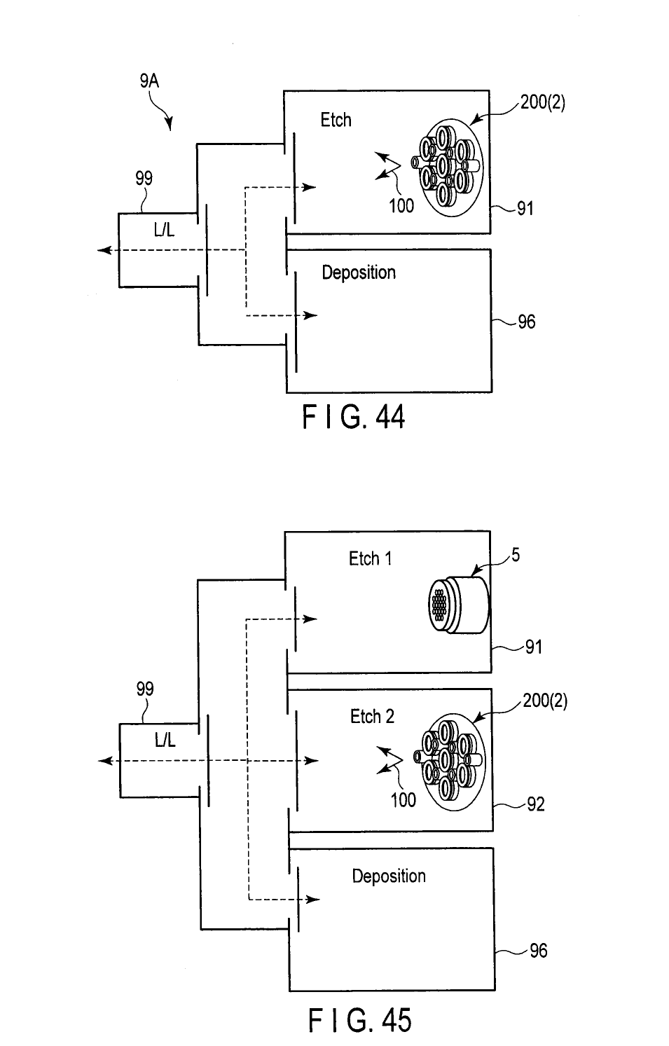

However, as will be described by using FIGS. 42A to 43B below, the solid angle of an ion beam can equivalently be increased by using a plurality of grid ion sources that output an ion beam with a narrow beam spread.

FIGS. 42A to 43B are diagrams schematically showing the physical relationship between the processed layer (substrate) 1Z and a plurality (for example, two) of the grid ion sources 5.

As shown in FIGS. 42A to 43B, two grid ion sources 5X, 5Y irradiate the surface of the processed layer 1Z with ion beams I1, I2 from different directions.

As shown in FIG. 42A, the one grid ion source 5X of the two grid ion sources 5X, 5Y irradiates the processed layer 1Z with the ion beam I1 from a direction perpendicular to the surface of the processed layer (substrate) 1Z (80). The grid ion source 5X is installed on the normal of the surface of the processed layer 1Z.

In contrast, the other ion source 5Y of the two grid ion sources 5X, 5Y irradiates the processed layer 1Z with the ion beam 12 from a direction inclined an angle γ with respect to the emission direction of the ion beam I1 from the one ion source 5X. The processed layer 1Z is irradiated with ion beam 12 of the other ion source 5Y from a direction inclined an angle of 90°−γ with respect to the surface of the processed layer 1Z.

FIG. 42B shows an example of the relationship between the incident angle and beam intensity of an ion beam output by the grid ion source of FIG. 42A. In FIG. 42B, the horizontal axis of the graph represents the incident angle of an ion beam with respect to the normal (0°) of the surface of the processed layer (substrate) and the vertical axis of the graph represents the beam intensity (any unit) of the ion beam.

As shown in FIG. 42B, the two grid ion sources 5X, 5Y output ion beams of the same intensity. Each of the ion beams I1, I2 output by the grid ion sources 5X, 5Y has a dispersion (solid angle) of, for example, about 5°.

The ion source 5X has an ion beam peak energy I1 at the incident angle of 0° with respect to the normal of the surface of the processed layer and the ion source 5Y has an ion beam peak energy 12 at the incident angle of γ with respect to the normal of the surface of the processed layer.

The solid angle δ formed by the ion beams I1, I2 from the two grid ion sources 5X, 5Y corresponds to the size between outer tails (tails on sides that are not adjacent to each other) of the respective distributions.

Thus, an ion beam having an equivalently large solid angle δ can be formed by using a plurality of the grid ion sources 5X, 5Y to irradiate the processed layer with ion beams with a narrow beam spread from mutually different directions.

By using the grid ion sources 5X, 5Y, the beam current and energy of the (two) grid ion sources 5X, 5Y can be controlled independently for each of the ion sources 5X, 5Y.

For example, the ion source 5X irradiating an ion beam from the direction perpendicular to the surface of the processed layer is driven to output a beam voltage of 250 V and a beam current of 300 mA to increase the etching rate of the processed layer and the ion source 5Y irradiating an ion beam from the direction inclined 30° (=γ) with respect to the normal of the surface of the processed layer is driven to output a beam voltage of 150 V and a beam current of 400 mA to remove reattachments (residues) formed on the side face of the processed layer at low energy.

The grid ion sources 5X, 5Y shown in FIG. 43A irradiate the processed layer 1Z with ion beams from directions different from those in FIG. 42.

The grid ion sources 5X, 5Y are arranged by being inclined at the same angle γ/2 from the normal of the surface of the processed layer 1Z to irradiate the processed layer 1Z with the ion beams I1, I2 from the directions inclined at the angle γ/2 from the normal.

FIG. 43B shows an example of the relationship between the incident angle and beam intensity of an ion beam output by the grid ion source of FIG. 43A. The horizontal axis of the graph of FIG. 43B represents the incident angle of an ion beam with respect to the normal (0°) of the surface of the processed layer and the vertical axis of the graph of FIG. 43B represents the beam intensity of the ion beam.

As shown in FIG. 43B, like the ion source in FIGS. 42A and 42B, the grid ion sources 5X, 5Y output ion beams of the same intensity and have the dispersion (angle of divergence) of about 5°.

As shown in FIG. 43B, the ion beams I1, I2 from the two ion sources 5X, 5Y are distributed in symmetric positions with respect to the normal of the surface of the processed layer 100 in the positive and negative directions. The processed layer 1Z is irradiated with The ion beams I1, I2 from positions shifted symmetrically in the positive and negative directions from the center C of the processed layer 100.

Also, in the example shown in FIGS. 43A and 43B, like the example shown in FIGS. 42A and 42B, the solid angle δ formed by the ion beams I1, I2 from the two grid ion sources 5X, 5Y corresponds to the size between outer tails (on sides that are not adjacent to each other) of the respective distributions.

When, like in FIGS. 43A and 43B, the ion beams I1, I2 from the ion sources 5X, 5Y are irradiated from directions tilted from the direction perpendicular to the surface of the processed layer 1Z, ions including in the ion beams I1, I2 will continue to collide against the side face of the processed layer. Thus, the configuration of the ion sources 5X 5Y in FIGS. 43A and 43B can be controlled so that reattachment of a sputtered material to the processed layer 1Z can be prevented.

In the two grid ion sources 5X, 5Y in FIG. 42A or 43A, in addition to power (the voltage and current), different types of gas (for example, a rare gas and a reactive gas) may be used for each of the ion sources 5X, 5Y as a parameter to independently control each of the ion sources 5X, 5Y.

For example, in FIGS. 42A and 42B, a relatively cheap Ar gas is supplied to the ion source 5X to process the processed layer 1Z deeply and roughly (at high speed) by the ion beam I1 from the ion source 5X. A relatively expensive Xe gas is supplied to the ion source 5Y to softly cut the processed layer 1Z by the ion beam 12 from the ion source 5Y with which the side face of the processed layer 1Z is irradiated.

Incidentally, a shutter may be provided in the emission port in each of the ion beams I1, I2 of the respective ion sources 5X, 5Y. For example, the shutters provided in each of the ion sources 5X, 5Y are alternately opened/closed at a speed of 1 s or less. Accordingly, for example, a plurality of the ion sources 5X, 5Y irradiating the ion beams I1, I2 can alternately be switched at high speed between the ion sources 5X, 5Y so that the processed layer are alternately irradiated with ion beams from the two ion sources 5X, 5Y.

Accordingly, in the state of the side face of the processed layer shown in FIG. 8B, the formation of a reactant on the processing surface of the processed layer by irradiation of an ion beam of a reactive gas and the removal of the reactant by irradiation of an ion beam of a rare gas can alternately be performed at high speed.

When, as shown in FIGS. 41A to 43B, the processed layer is irradiated with ion beams from a plurality of grid ion sources, causing one of a plurality of ion sources to operate so as to irradiate an ion beam of low energy of 100 eV or less to repair defects of the magnetic layers such as distortion is effective in processing an MTJ element of the element size (maximum dimension in a direction parallel to a surface of the substrate) of 30 nm or less.

When, as shown in FIGS. 42A to 43B, the two grid ion sources 5X, 5Y are used, the frequency of maintenance of the grid ion sources is approximately halved. Therefore, just as described by using FIG. 41, maintenance costs of ion sources can also be reduced in the examples shown in FIGS. 42 and 43.

### (4) Application Examples

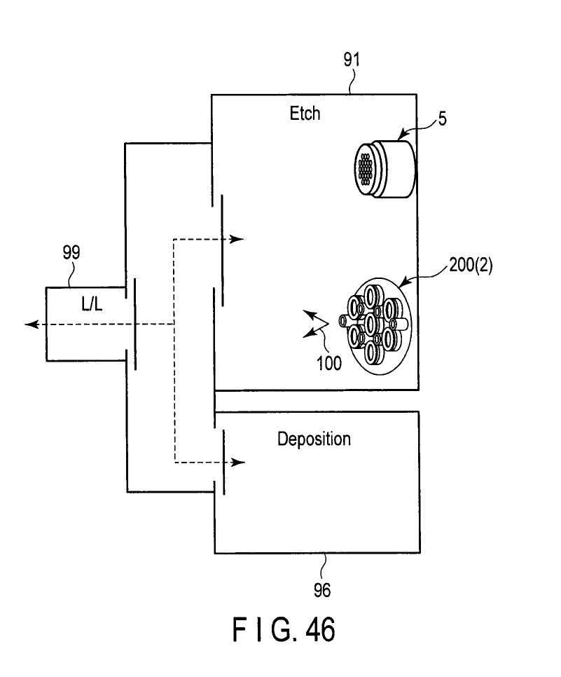

Application examples of the manufacturing apparatus of a magnetoresistive effect element according to the present embodiment will be described with reference to FIGS. 44 to 48.

As shown in FIGS. 44 to 48, a semiconductor manufacturing module (semiconductor manufacturing system) including an ion beam generator that outputs an ion beam having a large solid angle by one or more ion sources may be configured.

The semiconductor manufacturing module shown in FIG. 44 includes an ion beam generator (ion beam etching apparatus) 200 and a film deposition apparatus 96. The ion beam etching apparatus 200 according to the present embodiment is provided inside an etching chamber 91. The etching apparatus 200 and the etching chamber 91 are connected to the film deposition apparatus (deposition chamber) 96 via a transport path (transport mechanism) capable of ensuring a vacuum (predetermined degree of vacuum). The substrate on which a processed layer (laminated structure to form an MTJ element) is formed is moved between the etching apparatus 91 and the film deposition apparatus 96 via the transport path.

The laminated structure to form an MTJ element is deposited on the substrate by a magnetic layer, a tunnel barrier layer, a metallic film, and an insulating film being deposited in a predetermined order by using the film deposition apparatus 96.

The substrate on which the laminated structure is formed is transported from the film deposition apparatus 96 to the etching chamber 91. A processed layer is processed inside the etching chamber 91 by the above ion beam 100 having a large solid angle (ion beam having the solid angle of 10° or more) generated by the ion beam generator 200.

The substrate is transported between the ion beam etching apparatus (etching chamber) 91 and the film deposition apparatus (deposition chamber) 96 and processing of films and deposition films are repeated until an MTJ element and a magnetoresistive memory including the MTJ element are formed.

The formed MTJ element (for the formed magnetoresistive memory) is extracted out of the module (atmosphere) from a load lock chamber 99.

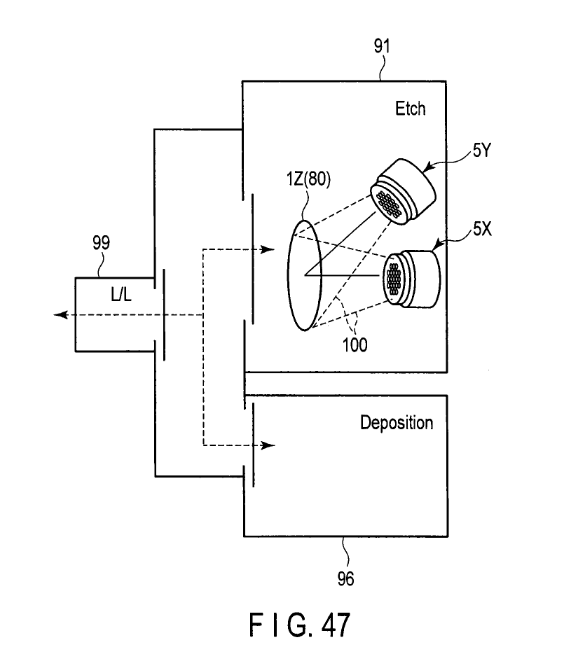

As shown in FIG. 45, ion beam etching apparatuses using a plurality of the ion sources 2, 5 that output ion beams of different characteristics may be provided in a semiconductor manufacturing module. The ion sources 2, 5 are provided in different chambers 91, 92 and connected via the transport path.

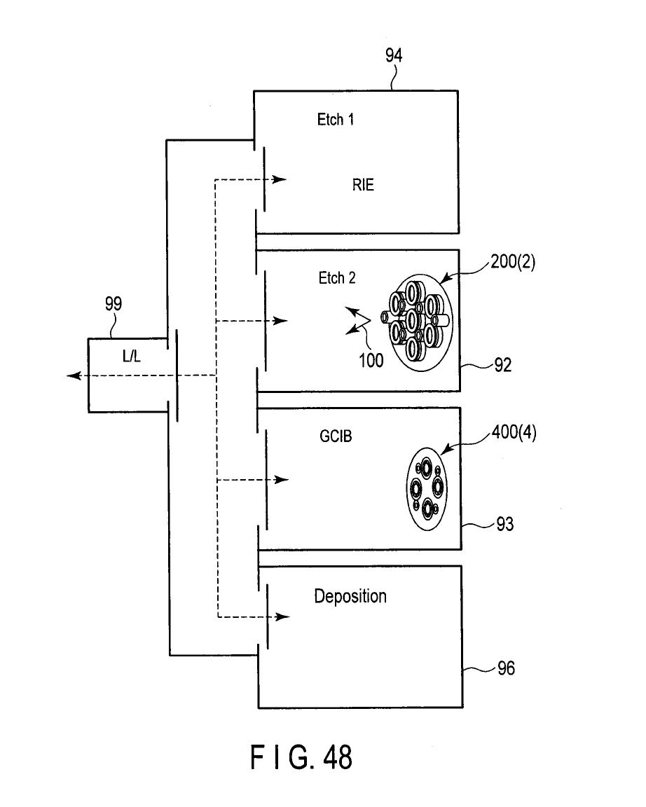

As shown in FIG. 46, the two ion sources 2, 5 or more may be provided in the one etching chamber 91.

In the example shown in FIG. 46, an ion beam etching apparatus is formed by the ion source (for example, the end Hall ion source) 2 that outputs the ion beam 100 having a large solid angle and the grid ion source 5 being provided in the one chamber 91. The ion sources 2, 5 having different characteristics can be switched quickly by both of the end Hall and grid ion sources 2, 5 being provided in the same chamber 91 of the ion beam etching apparatus.

For example, the time to process a thin film (magnetic layer) is short, thus even if a grid ion source is used for processing of a thin film, the wear on the grid is small.

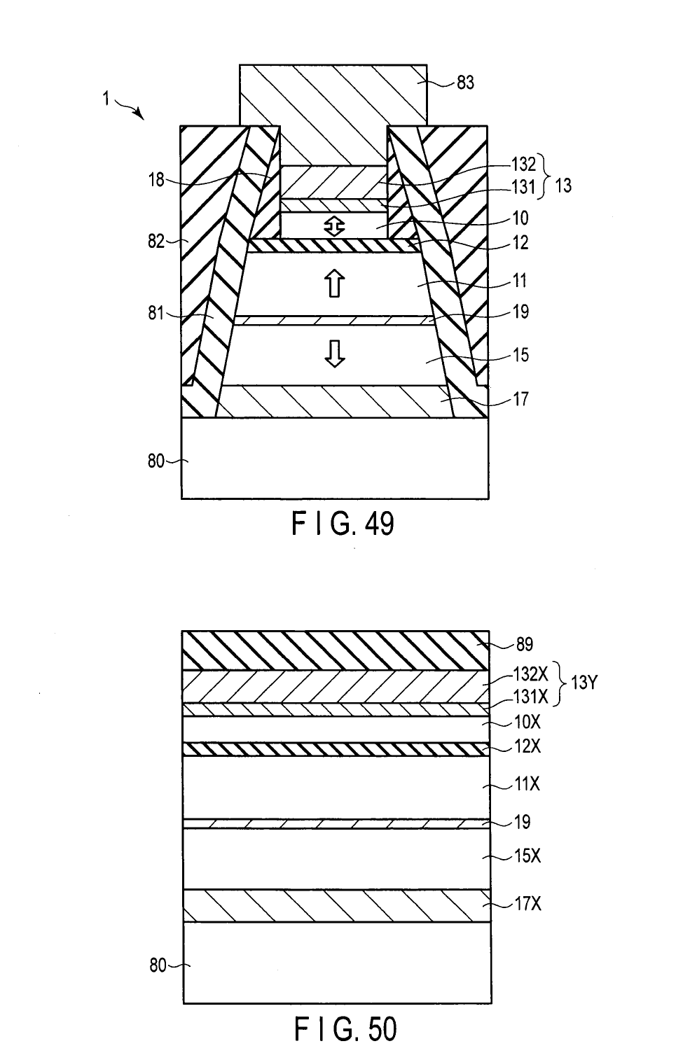

In the one ion beam etching apparatus 91, as shown in FIG. 47, the two grid ion sources 5X, 5Y shown in FIG. 42 may be provided in the same chamber 91. The two grid ion sources 5X, 5Y irradiate the processed layer 1Z with ion beams of different incident angles with respect to the processed layer 1Z. By irradiating ion beams having mutually different energy and angles and a narrow beam spread, etching by the ion beam 100 having a large energy dispersion and a large angle dispersion can equivalently be performed.

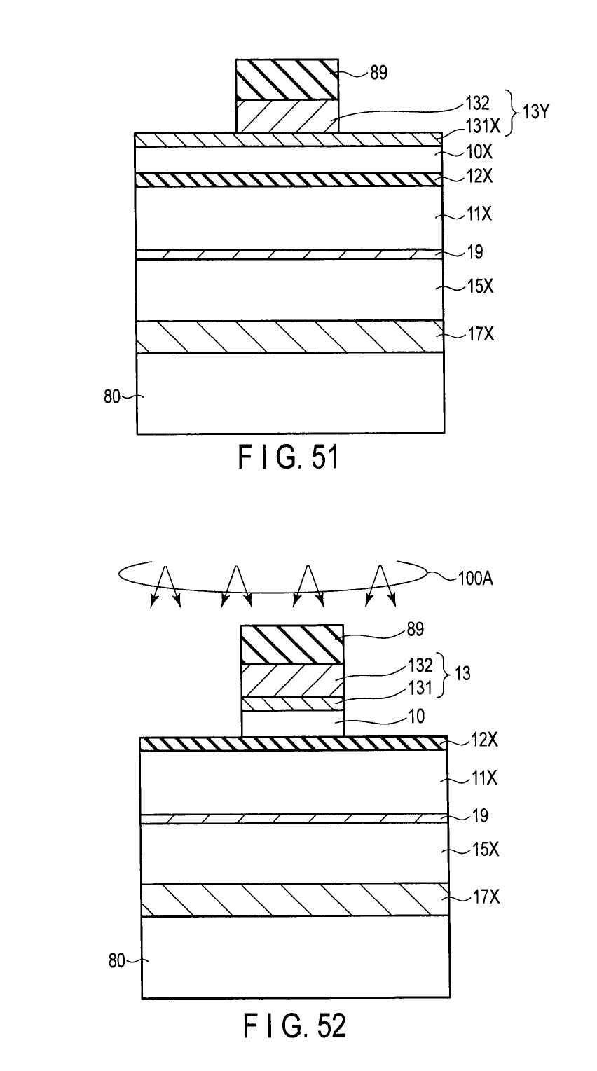

As shown in FIG. 48, an ion beam apparatus 400 of GCIB may be provided in a chamber 93 of a semiconductor manufacturing module. Accordingly, after etching of the magnetic layer is completed, damage to the processed magnetic layer can be repaired by irradiation of GCIB.

Incidentally, the ion source 4 of GCIB may be provided in the same chamber as the end Hall ion source 2. When the end Hall ion source 2 and the ion source 4 of GCIB are provided in the same chamber, GCIB can be directed on the processed layer simultaneously with an ion beam output from the end Hall ion source 2 or alternately.

Incidentally, as shown in FIG. 48, a RIE apparatus 94 may be provided in the semiconductor manufacturing module together with the ion beam etching apparatus.

As described above, a semiconductor manufacturing module capable of executing the manufacturing method of a magnetoresistive effect element (or a magnetoresistive memory) according to the present embodiment can be provided.

### (5) Summary

In the present embodiment, as described above, a magnetoresistive effect element is processed by using an ion beam having a large solid angle (for example, the solid angle of 10° or more).

When high-density STT (Spin Transfer Torque)-MRAM of the order of gigabits is formed by using magnetoresistive effect elements as memory elements, it is desirable to form the magnetoresistive effect element in the size of 30 nm or less.

Materials including magnetic metal such as Co and Fe used for a magnetoresistive effect element (MTJ element) are normally difficult to process by dry etching and are frequently irradiated with an ion beam using an inert gas such as Ar to physically perform etching.

The reason therefore is that the magnetic layer (reference layer/storage layer) is frequently configured by a plurality of films of the nanometer order having different constituent elements and magnetic materials (metals) are generally more likely to corrode than semiconductor materials, thus RIE used in manufacturing processes of semiconductor integrated circuits (silicon devices) is harder to apply.

A magnetoresistive effect element has a structure in which a storage layer and a reference layer are stacked across a thin tunnel barrier layer, thus the interval between the storage layer and the reference layer is small.

Thus, when the laminated structure to form a magnetoresistive effect element is processed, the storage layer/reference layer are cut together with the tunnel barrier layer, and so in the general processing by ion beam etching using an inert gas such as Ar, conductive reattachment (residue) resulting from the magnetic layer may attach to the storage layer/reference layer across the tunnel barrier layer on the side face of the laminated structure. In this case, a path of a leak current is generated by the reattachment connecting the storage layer and the reference layer, and the storage layer and the reference layer are shorted, leading to magnetoresistive effect element defects. As a result, the yield of magnetoresistive effect elements drops.

To prevent the yield from dropping, after a process of performing ion beam etching at an angle close to the direction perpendicular to the surface of the substrate on which a laminated structure is formed to perform etching in the depth direction (lamination structure) of the laminated structure, a process of performing ion beam etching at a shallow angle with respect to the surface of the substrate (angle close to the direction parallel to the substrate surface) to remove conductive attachments attached to the side face of the laminated structure by the etching in the direction perpendicular to the substrate surface is successively performed. Alternatively, the etching process in the direction perpendicular to the substrate surface to process the laminated structure and the etching process at a shallow angle to remove reattachments are repeated alternately.

In this case, as described by using FIGS. 8A and 8B, a phenomenon in which a reattachment (constituent atoms thereof) on the side face of the laminated structure is implanted in the magnetoresistive effect element may occur due to irradiation of an ion beam. Implanted atoms of the attachment may adversely affect magnetic properties of the magnetic layer and electric characteristics of the tunnel barrier layer (for example, MgO).

Particularly, if the element size (dimension in the direction parallel to the film surface) of an MTJ element is about 30 nm or less, like an MRAM of the order of gigabits, adverse effects when constituent atoms of attachments are implanted in the MTJ element are significant.

When, for example, the diameter of a CoPt magnetic dot processed by an ion beam becomes about 30 nm or less, the uniaxial anisotropic energy of the magnetic dot is degraded. Impurities resulting from reattachments on the side face of the laminated structure being implanted in a magnetic body by collision with ions are considered as one of the causes of degradation of magnetic properties of magnetic dots.

To suppress the phenomenon of implantation of reattachments, the energy of an ion beam can be lowered to a few tens of V; however, this will reduce the sputtering rate. Thus, if the throughput of manufacturing a magnetoresistive effect element and a memory using the magnetoresistive effect element is considered, it is preferable to increase the current of ion energy to compensate for the decreased voltage.

However, a grid ion source irradiates the processed layer with an ion beam by extracting the ion beam from plasma via the grid. In general, it is difficult to extract a large current in a grid ion source at the voltage of a few tens of V. When the grid ion source is driven at a low voltage, the current flowing into the grid increases and the grid forming holes are etched by ions passing through holes. Thus, the life of the grid becomes shorter and it becomes necessary to replace the grid periodically. If the aperture of a wafer (substrate) from which an element is formed increases, the diameter of a grid also increases. If the diameter of a grid increases, the price of the grid goes up.

As a result, manufacturing costs of a magnetoresistive effect element and a memory using the magnetoresistive effect element rise.

For reasons of difficulty of having a large solid angle (dispersion angle) reaching about 60° or a large energy dispersion of an ion beam or creating energy of a few hundred V or more, on the other hand, an ion source having no grid like an end Hall ion source has never been applied to etching of silicon devices.

As described in the present embodiment, reattachments of the processed laminated structure can effectively be removed by processing the laminated structure to form a magnetoresistive effect element by using an ion beam having a large solid angle formed by an end Hall ion source or the like; for example, an ion beam having the solid angle of 10° or more. Alternatively, constituent atoms of a sputtered material can be prevented from attaching to the laminated structure by irradiation of an ion beam having the solid angle of 10° or more.

By processing a laminated structure by using, for example, an ion beam having a large solid angle, a material sputtered by an ion beam can be removed substantially simultaneously with attachments on the processing surface (side face) of the laminated structure.

Thus, shorts between magnetic layers caused by reattachment and degradation of characteristics of the magnetic layer and the tunnel barrier layer can be suppressed.

Also, the laminated structure to form an MTJ element can be irradiated with an ion beam of low energy by using a Hall (gridless) ion source and defects generated on the processing surface of the laminated structure and caused by the ion beam can be repaired. Accordingly, characteristics of each layer forming an MTJ element can be enhanced and characteristics of the MTJ element can be improved.

An ion source using no grid (for example, an end Hall ion source) involves no wear on a grid and requires no replacement of the grid. Therefore, compared with a grid ion source, an ion source having no grid can reduce maintenance costs. As a result, a magnetoresistive effect element formed by the manufacturing method and manufacturing apparatus according to the present embodiment and a magnetoresistive memory using the magnetoresistive effect element can reduce manufacturing costs.

For example, an end Hall ion source or a cylindrical (anode layer type/magnetic layer type) ion source from which it is more likely to obtain an ion beam having a large solid angle at low energy is preferably used in an ion beam generator to form a magnetoresistive effect element according to the present embodiment.

Also, as described above, an ion beam having a large solid angle can be obtained by using one or more grid ion sources. When an ion beam having a solid angle of 10° or more is formed by using a grid ion source, a grid whose aperture ratio is 50% or more is used to obtain an ion beam having a large angle of divergence. Also, an ion beam having a large solid angle can equivalently be generated by using a plurality of grid ion sources.

According to the manufacturing method and manufacturing apparatus of a magnetoresistive effect element according to the present embodiment, as described above, shorts of the magnetoresistive effect element can be reduced and highly reliable magnetoresistive devices (magnetoresistive effect elements and magnetoresistive memories) can be provided.

### [B] Second Embodiment

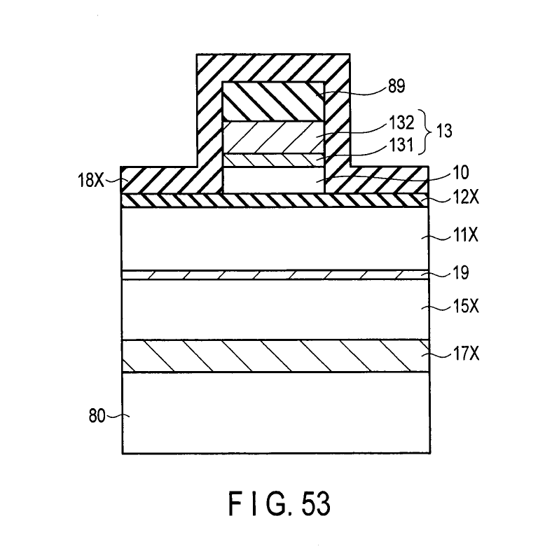

A manufacturing method of a magnetoresistive effect element according to a second embodiment will be described with reference to FIGS. 49 to 57. In the present embodiment, a duplicate description of members, functions, and manufacturing processes common to those in the first embodiment is omitted and a detailed description will be provided when necessary.

### (1) Concrete Example 1

An example of the manufacturing method of a magnetoresistive effect element according to the present embodiment will be described with reference to FIGS. 49 to 54.

FIG. 49 is a sectional view showing the structure of a magnetoresistive effect element of Concrete example 1 according to the second embodiment.

As shown in FIG. 49, a magnetoresistive effect element formed by the manufacturing method in the present embodiment is a bottom-pin magnetoresistive effect element (MTJ element).

That is, in the magnetoresistive effect element in FIG. 49, a TbCoFe film 11 as a reference layer is provided on the side of a lower electrode (foundation layer) 17 and a CoFeB film 10 as a storage layer is provided on the side of an upper electrode (hard mask).

A TbCoFe film as a shift correction layer 15 is provided between the reference layer 11 and the lower electrode 17. The shift correction layer 15 includes fixed magnetization, and the magnetization of the shift correction layer 15 is oriented in the opposite direction to the orientation of the magnetization of the reference layer 11. A metallic film (here, an Ru film) 19 is provided between the reference layer 11 and the shift correction layer 15. The Ru film 19 is provided between the reference layer 11 and the shift correction layer 15 to increase anti-parallel coupling of the reference layer 11 and the shift correction layer 15.

A CoFeB/Ta/CoFeB laminated film (not shown) is provided in a boundary region between an MgO film as a tunnel barrier layer 12 and the TbCoFe film 11 as the reference film. The CoFeB/Ta/CoFeB laminated film functions as an interface layer between the reference layer 11 and the tunnel barrier layer 12. The interface layer may also be considered as part of the reference layer and storage layer.

The lower electrode 17 is formed of a Ta film. An upper electrode 13 is formed of a Ta/Ru film. A Ta film 132 is stacked on an Ru film 131.

The magnetoresistive effect element in FIG. 49 is formed as described below.

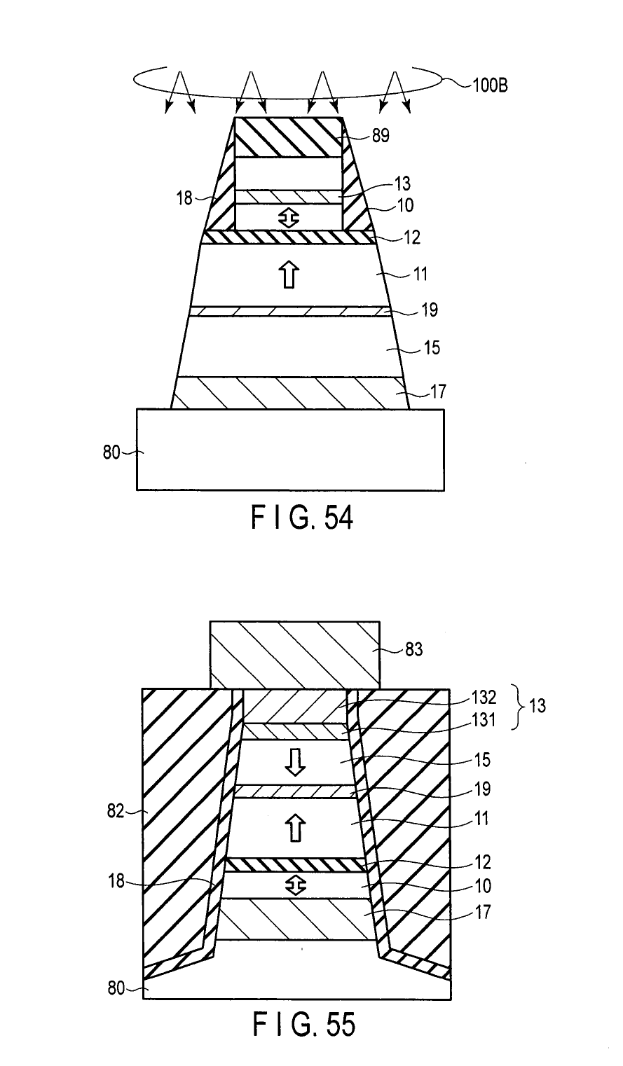

The manufacturing method of the magnetoresistive effect element in FIG. 49 will be described with reference to FIGS. 50 to 54. FIGS. 50 to 54 show sectional process drawings of each process of the manufacturing method of a magnetoresistive effect element of Concrete example 1 according to the second embodiment. The manufacturing method of the present concrete example will be described by using, in addition to FIGS. 50 to 54, FIG. 49 when appropriate.

As shown in FIG. 50, each layer to form a magnetoresistive effect element is successively stacked on a substrate 80 and a laminated structure 1X including magnetic layers 10X, 11X and a tunnel barrier layer 12X is formed on the substrate 80. A mask layer 89 is formed on a hard mask 13X of the laminated structure. The mask layer 89 is formed of SiO₂.

The laminated structure to form an MTJ element is formed by, for example, each layer being deposited in a deposition chamber 96 in a semiconductor manufacturing module shown in FIG. 44.

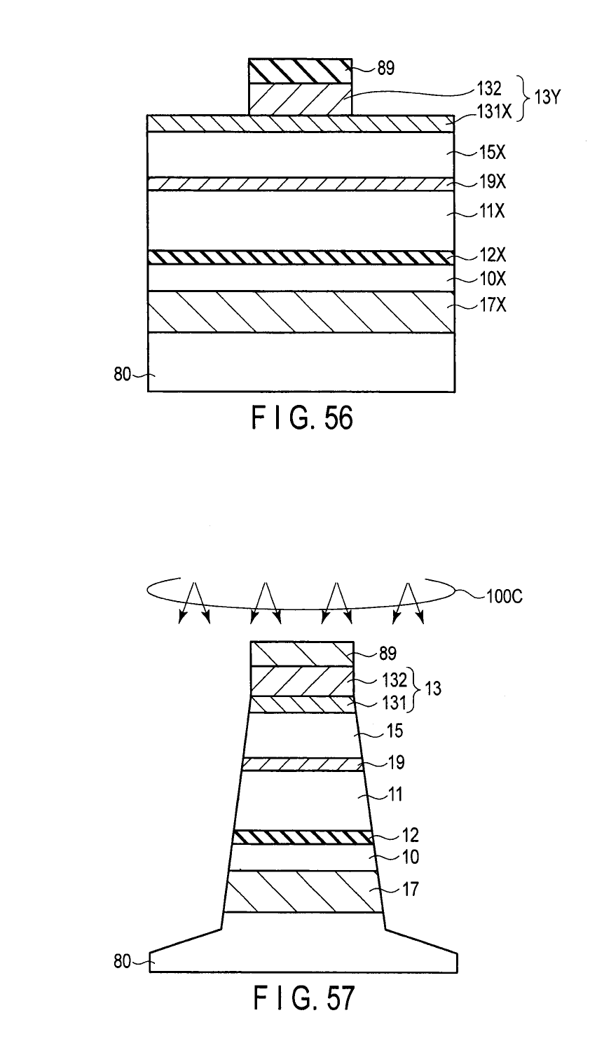

As shown in FIG. 51, the mask layer 89 formed of SiO₂ is etched by RIE using a Freon based gas such as CHF₃ based on a pattern of a resist mask (not shown) formed by photolithography.

After the resist mask is removed by ashing of oxygen, a hard mask formed of a Ta/Ru film is etched by RIE using a chloride based gas while using patterned SiO₂ as a mask.

The Ta film 132 is selectively etched by etching using a chloride based gas and the Ru film 131 functions as a stopper of the etching using a chloride based gas. After the stop of etching is detected on the top surface of the Ru film 131, chloride in the chamber and near the substrate (laminated structure) is removed by the discharge of a hydrogen gas.

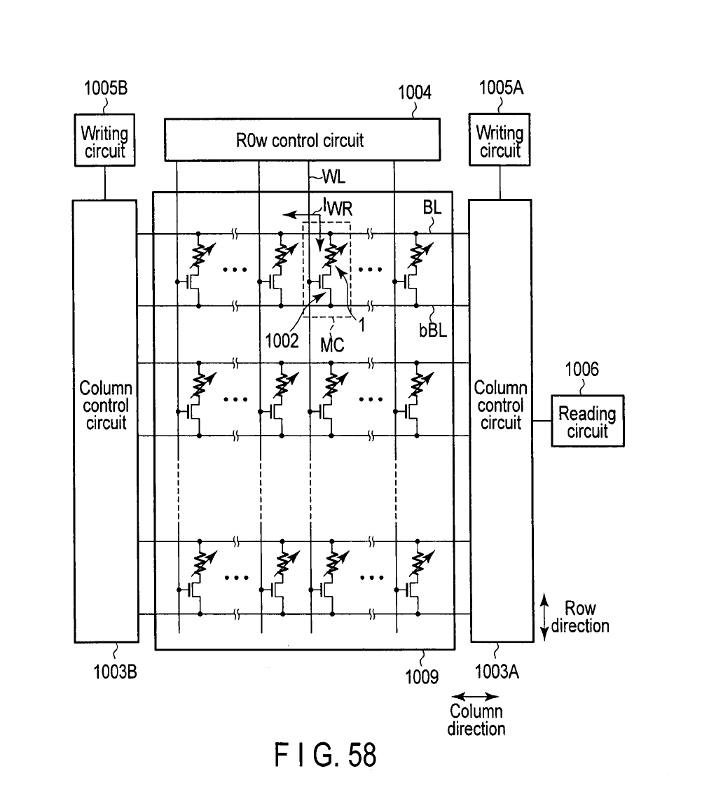

As shown in FIG. 52, the laminated structure 1X including the patterned Ta film 132 is irradiated with an ion beam 100A from, for example, an ion beam generator (etching apparatus, etching gun) 200 including a plurality of end Hall ion sources 2 shown in FIG. 44. The ion beam 100A includes the solid angle of, for example, 10° or more.

Accordingly, the Ru film 131 and the magnetic layer (here, the storage layer formed of CoFeB) 10 thereunder are etched by the ion beam 100A. The main energy peak of the ion beam 100A to process the storage layer 10 is set to, for example, 90 V.

The MgO film 12X whose etching rate is slower than that of the magnetic layer 10 is used as a stopper. By detecting, for example, a slower etching rate of the MgO film by an end point detector, etching by the ion beam 100A is stopped.

For example, etching of the magnetic layer 10 by an ion beam is performed, for example, in an etching chamber 91 inside the semiconductor manufacturing module shown in FIG. 44.

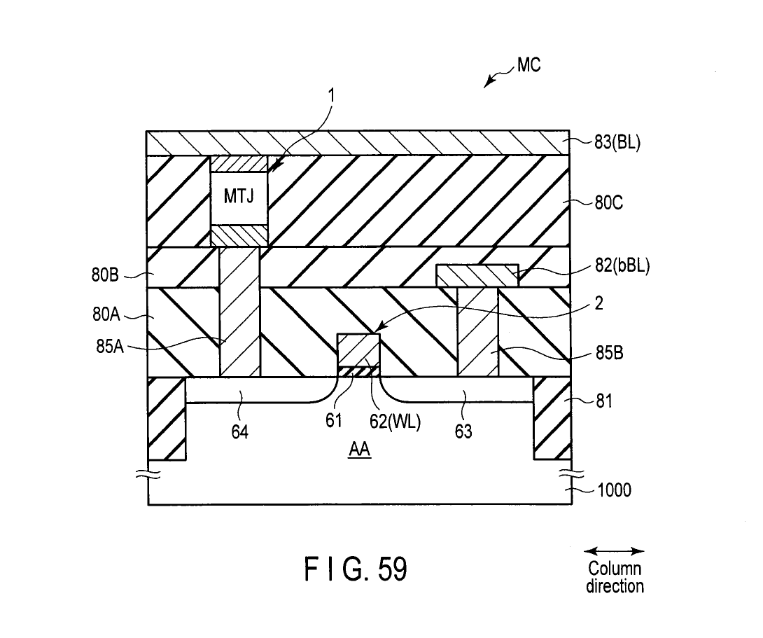

Next, as shown in FIG. 53, the substrate 80 is moved into the deposition chamber 96 in FIG. 44 and an alumina film 18X as a sidewall insulating film is deposited on the processed magnetic layer 10 and the Ta/Ru film 13 by ALD (Atomic Layer Deposition). A dense film 18 is conformally formed on the top surface and the side face of the magnetic layer 10 and the Ta/Ru film 13 by ALD.

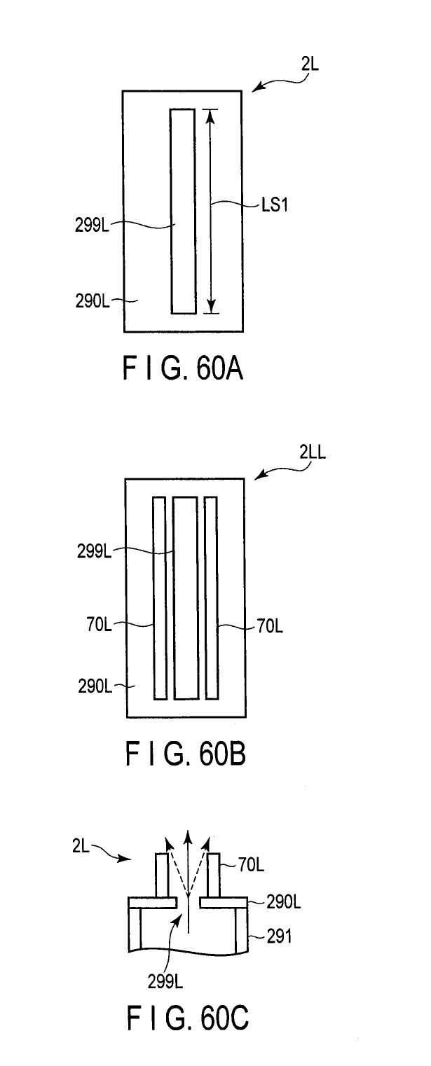

After the substrate 80 is moved again from the deposition chamber 96 to the etching chamber 91, as shown in FIG. 54, an ion beam 100B is irradiated while the alumina film 18 covers the magnetic layer 10 and the MgO film 12X.

The alumina film 18 is etched by the ion beam 100B and also the TbFeCo layer 11 as the reference layer and the TbCFe layer 15 as the shift correction layer thereunder are etched. For example, the lower electrode 17 is also processed by the ion beam 100B common to the TbCoFe layer 11, 15. Accordingly, an MTJ element in a predetermined shape is formed on the substrate 80. Incidentally, the reference layer 11 and the shift correction layer 15 may have a tapered shape.

The ion beam 100B includes the solid angle of, for example, 10° or more. When the reference layer 11 and the shift correction layer 15 are processed, the main energy peak of the ion beam 100B is set to 175 V.

The side face of the magnetic layer (CeFeB film) 10 to form a storage layer is covered with the alumina film 18. The alumina film 18 is not removed and remains on the side face of the magnetic layer 10 to function as a protective film of the MTJ element. Because the magnetic layer 10 as the storage layer is covered with the alumina film 18, characteristic degradation of the storage layer 10 caused by the high energy ion beam 100B can be prevented even if etching to process the magnetic layers as the reference layer 11 and the shift correction layer 15 is performed by using the ion beam 100B of relatively high energy.

By processing of the magnetic layers 10, 15 by an ion beam including a solid angle of 10° or more, a sputtered conductive material can be inhibited from attaching to the processed laminated structure or a conductive material attached to the laminated structure can be removed without changing the incident angle of an ion beam (angle of the substrate).

After the MTJ element is formed, the substrate 80 is moved into the deposition chamber 96 in FIG. 44. Then, as shown in FIG. 49, substantially in the same manner as the manufacturing processes in the first embodiment, an alumina film 81 as a protective film is deposited on the side face of the reference layer 11 and the shift correction layer 15 by ALD. Then, an inter-layer insulating film 82 is deposited on the substrate 80. After the mask layer on the upper electrode 13 is removed, an interconnect 83 connected to the upper electrode 13 is formed.

Then, the substrate 80 on which an MTJ element 1 is formed is moved into a load lock chamber 99 before being extracted into the atmosphere.

By undergoing the above manufacturing process, an MTJ element or a magnetoresistive memory (MRAM) including the MTJ element according to the present embodiment is manufactured.

In the manufacturing process shown in FIGS. 49 to 54, etching to form an MTJ element is performed by etching using an ion beam having a large solid angle (for example, 10° or more) by an end Hall ion source. However, an MTJ element may be processed by combining an ion beam having a large solid angle from an end Hall ion source and an ion beam with a narrow beam spread output by a grid ion source.

In the semiconductor manufacturing module in FIG. 45, for example, etching of the storage layer 10 in the process of FIG. 51 may be performed by an etching apparatus including a grid ion source 5 that outputs an ion beam having a narrow beam spread. The storage layer 10 has a thin film, thus the time needed for processing of the storage layer 10 is short. Thus, the wearing of a grid is small if a grid ion source is used for processing of the storage layer 10.

Then, the tunnel barrier layer 12, the reference layer 11, and the shift correction layer 15 are processed in the process of FIG. 54 by an etching apparatus including an end Hall ion source of an etching apparatus 92 shown in FIG. 45. Because the reference layer 11 and the shift correction layer 15 have a thick film, performing etching of the reference layer and the shift correction layer by a gridless ion source without grid wear is highly advantageous to reduce manufacturing costs.

When, for example, both of a Hall ion source (gridless ion source) and a grid ion source are combined to process an MTJ element, a semiconductor manufacturing module in which an end Hall ion source 2 and the grid ion source 5 shown in FIG. 46 are provided in the same apparatus (etching chamber) 91 may be used to shorten the manufacturing time by making switching of ion sources more smooth and reduce manufacturing costs.

As shown in FIG. 47, an ion beam of an equivalently large energy dispersion and a large solid angle may be formed by two grid ion sources 5A, 5B that output ion beams of different energy and different incident angles (illuminating angle) to perform etching of the laminated structure as a processed layer in the processes of FIGS. 52 and 54.

When a magnetoresistive effect element is formed by using the semiconductor manufacturing module shown in FIG. 48, damage to the magnetic layers 10, 11, 15 caused by etching can be repaired by irradiation of GCIB from a GCIB irradiation apparatus 93 after etching of the magnetic layers 10, 11, 15 is completed in the processes shown in FIGS. 52 and 54. When an ion source of GCIB and a Hall (gridless) ion source are provided in the same chamber, GCIB can be irradiated simultaneously with a monomer ion beam or alternately. The acceleration energy of GCIB may be increased to set the energy per atom to 5 eV or more so that particles in a gas cluster are used in etching.

In the element structure and manufacturing process shown in FIGS. 49 to 55, after the protective film 18 is formed on the side face of the processed storage layer 10, the reference layer 11 and the shift correction layer 15 can self-aligningly be etched by using the processed storage layer 10 as a mask. Accordingly, damage caused to the side face of the storage layer 10 can be suppressed when the reference layer 11 and the shift correction layer 15 are processed. Therefore, when an MTJ element of 30 nm or less is processed, magnetic properties of the magnetic layer of the MTJ element can be inhibited from deteriorating.

According to the manufacturing method of a magnetoresistive effect element according to the second embodiment, as described above, shorts of the magnetoresistive effect element can be reduced and highly reliable magnetoresistive devices (magnetoresistive effect elements and magnetoresistive memories) can be provided.

### (2) Concrete Example 2

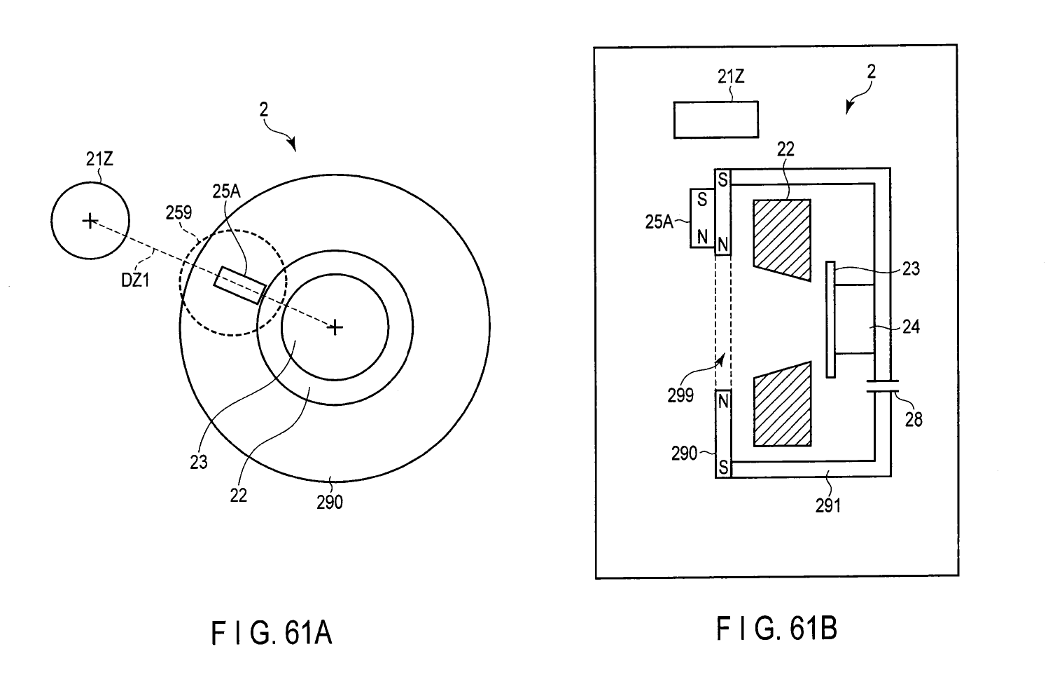

An example of the magnetoresistive effect element according to the present embodiment and the manufacturing method thereof will be described with reference to FIGS. 55 to 57.

FIG. 55 is a sectional view showing the structure of a magnetoresistive effect element of Concrete example 2 according to the second embodiment. The magnetoresistive effect element in FIG. 55 is a top-pin magnetoresistive effect element (MTJ element).

The storage layer 10 is formed of a CoFeB film and stacked on an Ru/Ta film as a foundation layer. An MgO film as the tunnel barrier layer 12 is provided on the storage layer 10. The reference layer 11 is formed of a TbCoFe film and provided on the MgO film 12. For example, a CoFeB/Ta/CoFeB laminated film (not shown) is provided in a boundary region between the tunnel barrier layer 12 and the TbCoFe film 11 as an interface layer.

The shift correction layer 15 is provided on the TbCoFe film 11 as the reference layer. The shift correction layer 15 is formed of a TbCoFe film. The metallic film (for example, the Ru film) 19 is provided between the reference layer 11 and the shift correction layer 15.

The Ta/Ru film 13 as an upper electrode and a hard mask is provided on the shift correction layer 15. The Ru film 131 is stacked on the shift correction layer 15 and the Ta film 132 is stacked on the Ru film 131.

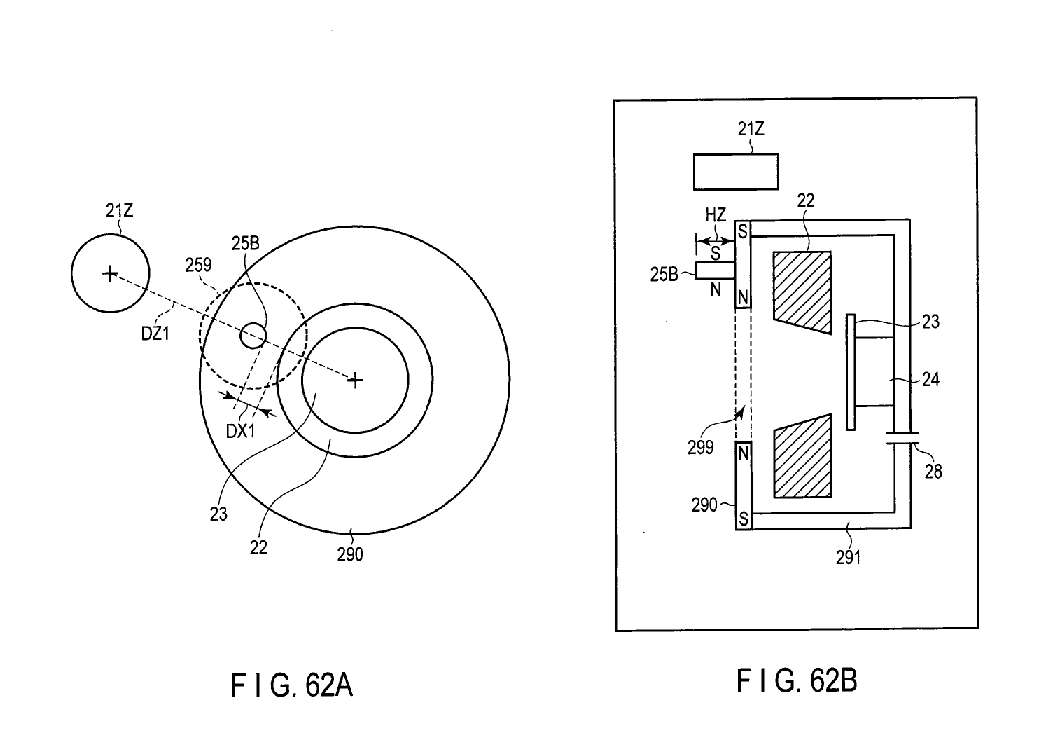

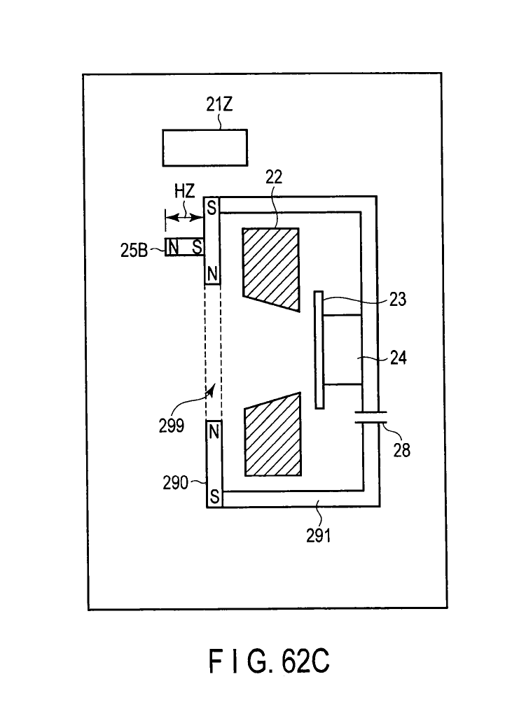

The manufacturing method of the MTJ element shown in FIG. 55 will be described by using FIGS. 56 and 57. FIGS. 56 and 57 show sectional process drawings of each process of the manufacturing method of a magnetoresistive effect element of Concrete example 2 according to the second embodiment. The manufacturing method of the present concrete example will be described by using, in addition to FIGS. 56 and 57, FIG. 55 when appropriate.

As shown in FIG. 56, each film to form the MTJ element in FIG. 55 is successively stacked on the substrate (inter-layer insulating film) 80. The SiO₂ film 89 is deposited on a Ta/Ru film 13Y as the top layer. A resist film (not shown) is applied to the SiO₂ film 89. The resist film is patterned to a predetermined shape by lithography.

The patterned resist film is used as a mask to etch the SiO₂ film 89 using a Freon based gas (for example, CHF₃).

After the resist mask is removed by ashing using oxygen, RIE using a chloride based gas is performed on the Ta film 132 of the hard mask 13Y using the patterned SiO₂ film 89 as a mask.

An Ru film 131X functions as a stopper for RIE during RIE on the Ta film 132 and etching using a chloride based gas is stopped on the top surface of the Ru film 131X. Accordingly, the Ta film 132 is selectively etched.

After chloride is removed during an H discharge, as shown in FIG. 57, the layers 15, 19, 11, 12, 10 between the Ru film 131 and the foundation layer 17 are etched by an etching gun (see, for example, FIG. 21) formed of a plurality of end Hall ion sources using an ion beam 100C having a solid angle of 10° or more. For example, the main peak of energy of the ion beam 100C is set to 175 V.

An MTJ element is formed by the ion beam 100C having a solid angle of 10° or more. Accordingly, a sputtered conductive material can be inhibited from attaching to the laminated structure or a conducive material attached to the laminated structure can be removed relatively easily.

After the MTJ element in a predetermined shape is formed by irradiation of an ion beam according to the present embodiment, as shown in FIG. 55, substantially in the same manner as the first embodiment, the protective film 18, the inter-layer insulating film 82, and the interconnect 83 are successively formed.

By undergoing the above manufacturing process, an MTJ element or a magnetoresistive memory (MRAM) including the MTJ element according to the present embodiment is manufactured.

Incidentally, RIE may be used to process the laminated structure. However, after the laminated structure is processed by RIE, residues are removed by using an ion beam having a large solid angle. In the semiconductor manufacturing module shown in FIG. 48, for example, etching of the magnetic layers 10, 11, 15 is performed by RIE using a methanol gas and etching of the MgO film (tunnel barrier layer) is performed by physical etching using irradiation of an ion beam of an Ar gas.

After each layer of the MTJ element is etched, the substrate 80 is moved into the chamber 92 for ion beam etching to remove residues (conductive reattachment) on the side face of the MTJ element by irradiation of an ion beam having a large solid angle from the Hall ion source 2.

Further, residues on the side face of the processed laminated structure (MTJ element) may be oxidized by irradiation of an oxygen ion beam of extremely low ion energy of about 50 eV in the end to suppress electrical conductivity of the residues. By using a Hall ion source that more easily outputs a large amount of ion beam of extremely low energy, only the surface (exposed surface, processing surface) of the magnetic body can be oxidized without inflicting damage on the inside of the magnetic body included in the laminated structure.

For example, the irradiation of an ion beam of extremely low energy can be applied when, after RIE using a halogen based gas is performed, the processed layer is irradiated with an ion beam of hydrogen or a rare gas from a Hall ion source to remove halogen components remaining on the processed surface of the processed layer.

Also, when, after general RIE or etching using an ion beam from a grid ion source, an ion beam of extremely low energy is irradiated by using the above Hall ion source, processing that reduces damage inflicted on the magnetic body can be performed.

When, for example, an MTJ element is formed by the manufacturing module in FIG. 48, distortion of the magnetic layer caused by RIE processing and residue removal may be enhanced by transporting the substrate 80 on which the MTJ element is formed from the etching chamber 92 into the GCIB chamber 93 and irradiating the side face of the processed MTJ element 1 with GCIB.

Thus, by removing residues on the side face of the MTJ element using an ion beam having a large solid angle, shorts of the MTJ element caused by reattachments can be reduced, and also, high-speed processing by chemical etching using RIE can be performed.

Also, in the ion beam irradiation using the one grid ion source 5 or more in FIGS. 41 to 43 and 47, shorts due to conductive attachments on an MTJ element can be suppressed, and also, characteristics of the MTJ element can be enhanced.

As described by using Concrete example 1 and Concrete example 2 in the present embodiment, a magnetoresistive effect element can also be formed by using an ion beam having a large solid angle (solid angle of 10° to 60°) for magnetoresistive effect elements having a structure other than the structure of a magnetoresistive effect element according to the first embodiment.

Also, in the manufacturing method of a magnetoresistive effect element according to the second embodiment, like in the first embodiment, etching of an MTJ element is performed by an ion beam having a large solid angle and large energy dispersion. Thus, according to the manufacturing method of a magnetoresistive effect element in the present embodiment, when compared with a case of etching by an ion beam from a grid ion source having a narrow beam spread, shorts caused by conductive attachments on the side face of the MTJ element are suppressed and magnetic properties of the MTJ element are enhanced. Also, according to the manufacturing method of a magnetoresistive effect element in the present embodiment, manufacturing costs of magnetoresistive effect elements and magnetoresistive memories can be reduced.

According to the manufacturing method of a magnetoresistive effect element according to the second embodiment, as described above, shorts of the magnetoresistive effect element can be reduced and highly reliable magnetoresistive devices (magnetoresistive effect elements and magnetoresistive memories) can be provided.

### [C] Application Example

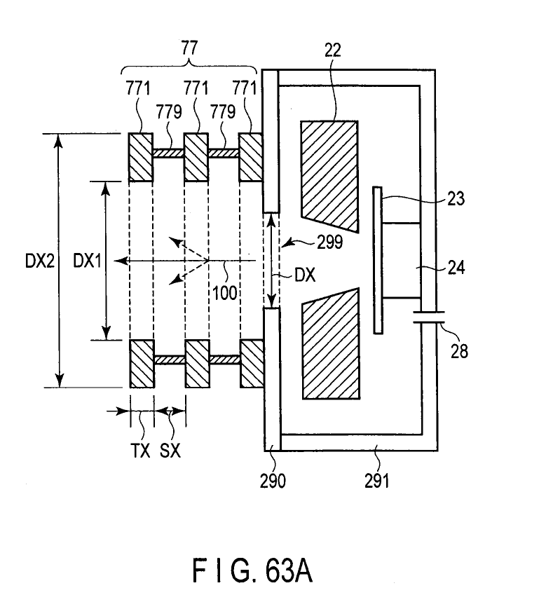

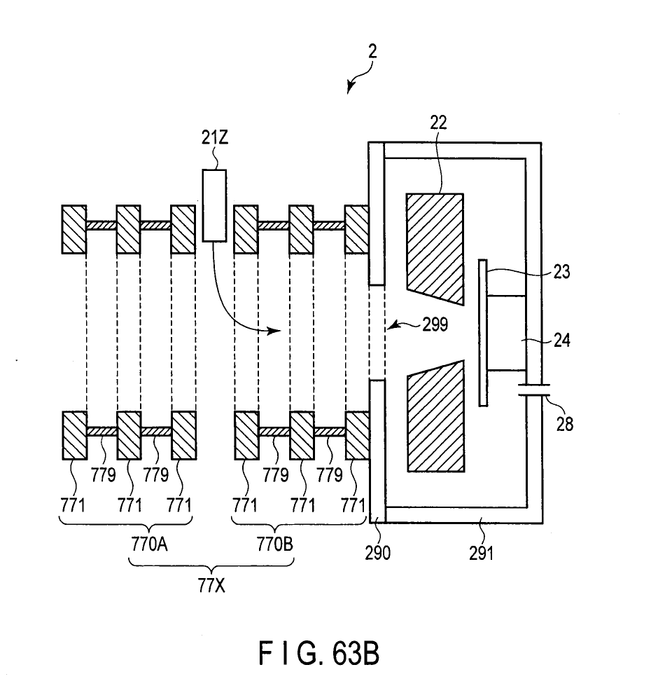

An application example of a magnetoresistive effect element according to the embodiments will be described with reference to FIGS. 58 and 59. The same reference numerals are attached to substantially the same components as those described in the above embodiments and the description of the configuration thereof will be provided when necessary.

(1) Configuration

A magnetoresistive effect element according to the above embodiments is used as a memory element of a magnetoresistive memory, for example, MRAM (Magnetoresistive Random Access Memory). In the present application example, an STT-type MRAM (Spin-torque transfer MRAM) is illustrated.

FIG. 58 is a diagram showing the circuit configuration of a memory cell array of MRAM of the present application example and the neighborhood thereof.

As shown in FIG. 58, a memory cell array 1009 includes a plurality of memory cells MC.

The memory cells MC are arranged in an array shape inside the memory cell array 1009. A plurality of bit lines BL, bBl and a plurality of word lines WL are provided inside the memory cell array 1009. The bit lines BL, bBL extend in the column direction and the word lines WL extend in the row direction. The two bit lines BL, bBL form a pair of bit lines.

The memory cell MC is connected to the bit lines BL, bBL and the word line WL.

The memory cells MC arranged in the column direction are connected to the common pair of bit lines BL, bBL. The memory cells MC arranged in the row direction are connected to the common word line WL.

The memory cell MC includes, for example, a magnetoresistive effect element (MTJ element) 1 as a memory element and a selection switch 1002. The magnetoresistive effect element (MTJ element) 1 described in the first or second embodiment is used in the MTJ element 1 inside the memory cell MC.

The selection switch 1002 is, for example, a field effect transistor. The field effect transistor as the selection switch 1002 will be called the selection transistor 1002 below.

One end of the MTJ element 1 is connected to the bit line BL and the other end of the MTJ element 1 is connected to one end (source/drain) of a current path of the selection transistor 1002. The other end (drain/source) of a current path of the selection transistor 1002 is connected to the bit line bBL. A control terminal (gate) of the selection transistor 1002 is connected to the word line WL.

One end of the word line WL is connected to a row control circuit 1004. The row control circuit 1004 controls activation/inactivation of a word line based on an address signal from outside.

Column control circuits 1003A, 1003B are connected to one end and the other end of the bit lines BL, bBL respectively. The column control circuits 1003A, 1003B control activation/inactivation of the bit lines BL, bBL based on an address signal from outside.

Writing circuits 1005A, 1005B are connected to one end and the other end of the bit lines BL, bBL via the column control circuits 1003A, 1003B respectively. The writing circuits 1005A, 1005B include a source circuit such as a current source or voltage source to generate a write current and a sink circuit to absorb the write current respectively.

In an STT-type MRAM, the writing circuits 1005A, 1005B supply a write current I_{WR} to the memory cell selected from outside (hereinafter, called a selected cell) when data is written.

When data is written to the MTJ element 1, the writing circuits 1005A, 1005B pass a write current to the MTJ element 1 inside the memory cell MC bidirectionally. That is, in accordance with data written to the MTJ element 1, a write current from the bit line BL to the bit line bBl or a write current from the bit line bBL to the bit line BL is output from the writing circuits 1005A, 1005B.

A reading circuit 1006 is connected to one end of the bit lines BL, bBL via a column control circuit 3A. The reading circuit 1006 includes a voltage source or current source that generates a read current, a sense amplifier that detects and amplifies a read signal, and a latch circuit that temporarily holds data. The reading circuit 1006 supplies a read current to the selected cell when data is read from the MTJ element 1. The current value of the read current is smaller than the current value (flux reversal threshold) of the write current so that the magnetization of a recording layer should not be reversed by the read current.

The current value or potential at a reading node is different in accordance with the magnitude of resistance of the MTJ element 1 to which the read current is supplied. The data stored in the MTJ element 1 is determined based on variations (read signal, read output) in accordance with the magnitude of the resistance.

In the example shown in FIG. 58, the reading circuit 1006 is provided on the one end side in the column direction of the memory cell array 1009, but two reading circuits may be provided, one on one end and the other on the other end in the column direction.

For example, a row/column control circuit and circuits (hereinafter, called peripheral circuits) other than the writing circuit and the reading circuit are provided in the same chip as the memory cell array 1009. For example, a buffer circuit, a state machine (control circuit), or an ECC (Error Checking and Correcting) circuit may be provided as a peripheral circuit in the chip.

FIG. 59 is a sectional view showing an example of the structure of the memory cell MC provided in a memory cell array 9 of an MRAM in the present application example.

The memory cell MC is formed in an active area AA of a semiconductor substrate 1000. The active area AA is partitioned by the insulating film 89 embedded in an element isolation area of the semiconductor substrate 1000. Inter-layer insulating films 80A, 80B, 80C are provided on the semiconductor substrate 1000. The MTJ element 1 is provided on the inter-layer insulating films 80A, 80B. The MTJ element 1 is covered with the inter-layer insulating film 80C via a protective film (not shown).

The upper end of the MTJ element 1 is connected to the bit line 83 (BL) via an upper electrode 19B. The bit line 82 is provided on the inter-layer insulating film 80C covering the MTJ element 1. The lower end of the MTJ element 1 is connected to a source/drain diffusion layer 64 of the selection switch 1002 via a lower electrode 19A and a contact plug 85A in the inter-layer insulating films 80A, 80B. A source/drain diffusion layer 63 of the selection transistor 1002 is connected to the bit line 82 (bBL) via a contact plug 85B in the inter-layer insulating film 80A.

A gate electrode 62 is formed on the active area AA surface between the source/drain diffusion layer 64 and the source/drain diffusion layer 63 via a gate insulating film 61. The gate electrode 62 extends in the row direction and is used as the word line WL.

The MTJ element 1 is provided directly above the plug 85A, but may be arranged in a position deviating from the position directly above the contact plug (for example, above the gate electrode of the selection transistor).

In FIG. 59, an example in which a memory cell is provided in the one active area AA is shown. However, two memory cells may be provided in the one active area AA adjacent to each other in the column direction in such a way that the two memory cells share the one bit line bBL and the source/drain diffusion layer 63. Accordingly, the cell size of the memory cell MC is reduced.

In FIG. 59, a field effect transistor in a planar structure is shown as the selection transistor 1002, but the structure of the selection transistor is not limited to such a structure. For example, a field effect transistor in a three-dimensional structure such as an RCAT (Recess Channel Array Transistor) and FinFET may be used as the selection transistor. An RCAT has a structure in which a gate electrode is embedded in a recess inside a semiconductor region via a gate insulating film. A FinFET has a structure in which a gate electrode three-dimensionally intersects with a semiconductor region (fin) in a thin rectangular shape via a gate insulating film.

(2) Manufacturing Method

A memory cell of a magnetoresistive memory is formed as described below.

For example, the selection transistor 1002 is formed on the semiconductor substrate 1000 according to a known technology. The inter-layer insulating films 80A, 80B are formed on the semiconductor substrate 1000 as if to cover the formed selection transistor 1002.

Contact holes are formed inside the inter-layer insulating films 80A, 80B so that the top surfaces of the source/drain diffusion layers 63, 64 of the selection transistor 1002 are exposed and the contact plugs 85A, 85B are embedded in the contact holes.

As described above, a laminated structure including constituent members of an MTJ element is formed on the inter-layer insulating film 80B. Then, the laminated structure is processed based on a hard mask in a predetermined shape.

The processing of the laminated structure is performed by an ion beam having a large solid angle (for example, the solid angle of 10° or more and 60° or less) output from a Hall ion source. Alternatively, the laminated structure is processed by irradiating ion beams output from a plurality of grid ion sources on the laminated structure from mutually different directions to use an ion beam having an equivalently large solid angle. At this point, it is preferable to generate an ion beam so that the ion beam includes at least 10% of ions having an energy of 100 eV or less.

Shorts caused by conductive attachments on the side face of an MTJ element are suppressed by performing etching of the MTJ element by an ion beam having a large solid angle and large energy dispersion so that magnetic properties of the MTJ element can be enhanced.

After the MTJ element 1 is formed by irradiation of an ion beam having a solid angle of 10° or more, a protective film (not shown) covering the MTJ element 1 is formed by the ALD method. Then, the inter-layer insulating film 80C is deposited on the inter-layer insulating films 80A, 80B to cover the MTJ element 1. The bit line 83 is formed on the inter-layer insulating film 80C so as to be connected to the MTJ element 1.

By undergoing the above process, a memory cell of an MRAM is formed.

A magnetoresistive memory in which shorts of a magnetoresistive effect element are reduced can be manufactured by the manufacturing method of a magnetoresistive effect element according to the present embodiment being applied to the formation of a magnetoresistive effect element included in a magnetoresistive memory. Therefore, the yield of manufacturing magnetoresistive memories can be improved at relatively low manufacturing costs and highly reliable magnetoresistive memories can be provided.

### Modification Example

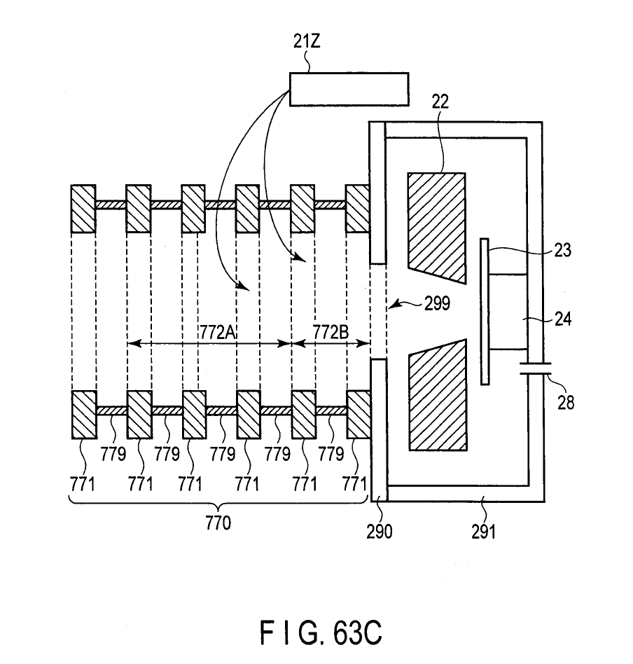

A modification example of an ion beam according to the above embodiments will be described with reference to FIGS. 60A to 60C.

The manufacturing method of a magnetoresistive effect element according to the embodiments and an exemplary ion source used for the manufacturing method of a magnetoresistive effect element will be described by using FIGS. 60A to 60C.

As shown in FIGS. 60A to 60C, a linear ion source 2L may be used for the manufacturing method of a magnetoresistive effect element and the manufacturing apparatus of a magnetoresistive effect element as an ion source that generates and outputs an ion beam having a solid angle of 10° or more.

FIG. 60A schematically shows a top view of a linear ion source on the side of the emission port of an ion beam.

The linear ion source 2L is an ion source having a rectangular ion beam emission port 299L. The configuration of the linear ion source in respect of the shape of the ion beam emission port 299L is similar to the configuration of an end Hall ion source thus the description thereof is omitted. The rectangular ion beam emission port 299L has a length LS1 in a long side direction (length direction) of the emission port. The ion beam emission port 299L is a linear slit formed on the side of the emission surface 290 of the cabinet.

Incidentally, the ion beam emission port of the linear ion source 2L may include a plurality of rectangular (linear) slits. The ion beam emission port of the linear ion source 2L may be a loop slit.

When the linear ion source 2L is used for processing of a magnetoresistive effect element, uniformity of element processing can be improved by combining the ion beam irradiation by the linear ion source and the movement (reciprocating motion) of the substrate by a linear motor.

As shown in FIG. 60A, the dispersion of an ion beam may become large at an edge in a short side direction (breadth direction, width direction) of the rectangular ion beam emission port 299L.

Thus, it is preferable to set the size of the ion beam emission port 299L of the linear ion beam 2L so that the length LS1 of the long side of the ion beam emission port 299L is longer than the size SS1 of the substrate 80 on which the processed layer 1Z is provided by about 20%, that is, the relation LS1=120×SS1 holds.

Accordingly, the influence of dispersion of an ion beam caused by the shape of the ion beam of the ion beam emission port 299L can be reduced in the linear ion source 2L.

FIGS. 60B and 60C show a modification of the linear ion source. FIG. 60B schematically shows a top view of a linear ion source on the emission port side of an ion beam. FIG. 60C schematically shows a sectional view near the ion beam emission port of the linear ion source in FIG. 60B.

As shown in FIGS. 60B and 60C, a collimator 70L may be provided in the linear ion source 2L.

As shown in FIGS. 60B and 60C, the wall collimator 70L may be provided along the long side direction of the rectangular ion beam emission port 299L.

Accordingly, an increase in dispersion in the short side direction of the opening 299L caused by the linear shape can be reduced.

With the wall collimator 70L installed in the breadth direction of the linear ion beam emission port 299L, excessive dispersion of an ion beam can be controlled and the influence of an excessive solid angle of an ion beam can be reduced.

### [E] Design Example

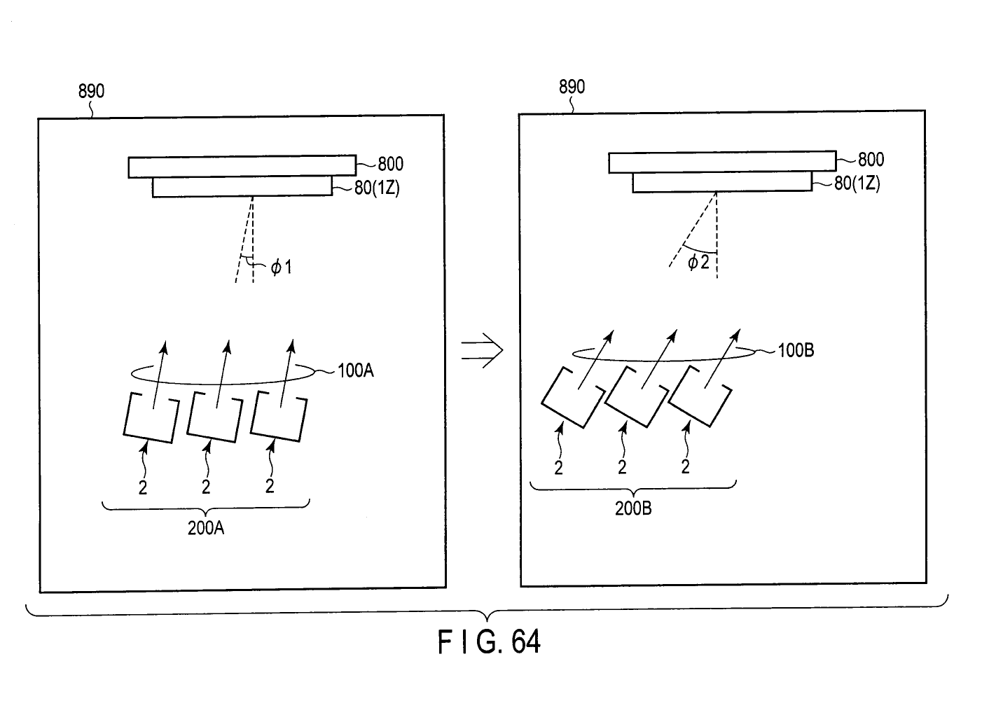

A design example of an ion beam generator (ion beam etching apparatus) according to the above embodiments will be described with reference to FIGS. 61A to 86B.

An end Hall ion source will mainly be described below as an ion source to form a magnetoresistive effect element. However, ion sources other than the above end Hall ion source can also be applied within the range in which configuration consistency is achieved.

(1) Installation Position of a Magnet with Respect to the Ion Source

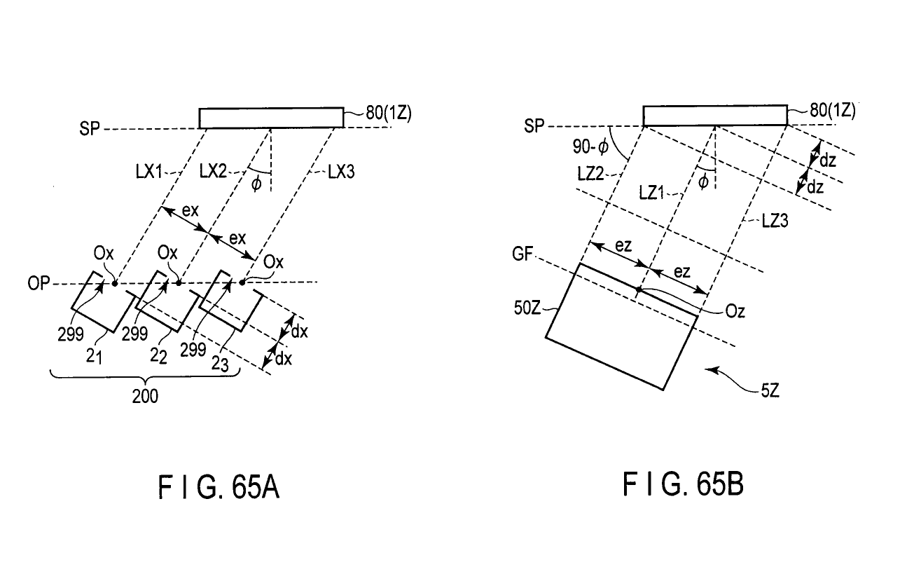

The installation of a magnet with respect to the ion source will be described by using FIGS. 61A to 62C.

FIG. 61A is a plan view showing a planar structure of an end Hall ion source in which a magnet is provided. FIG. 61B is a sectional view showing a sectional structure of the end Hall ion source in which the magnet is provided.

As shown in FIGS. 61A and 61B, a structure that reinforces a magnetic field near the ion beam emission port like a magnet may be provided on the side of the ion beam emission port of a cabinet of the end Hall ion source. For example, a magnet 25A is provided on an emission surface side plate (for example, a yoke) 290 of cabinets (plasma generating containers) 290, 291 including the anode 22.

Accordingly, the discharge region of the ion source 2 can be expanded and the discharge to generate an ion beam can be stabilized.

Incidentally, as shown in FIG. 61B, the gas distributor 23 may be in contact with the magnet 24 in the cabinets 290, 291.

As shown in FIGS. 61A and 61B, the magnet 25A is preferably installed near the hollow cathode 21Z.

The path on which electrons supplied from the hollow cathode 21Z are supplied from the hollow cathode 21Z to the anode 22 in the lowest state in terms of energy is geometrically the path of shortest distance from the hollow cathode 21Z to the anode 22.

For example, the magnet 25A is installed on the emission surface side plate (hereinafter, also called an emission surface) 290 in such a way that the magnet 25A is present on a straight line DZ1 connecting an electron supply window of the hollow cathode 21Z and the center of the anode 22.

Accordingly, a region 259 in which a magnetic field is reinforced (hereinafter, called a magnetic field reinforced region) is formed on, among paths leading from the hollow cathode 21Z into the ion source 2, a path of the lowest energy. As a result, a gas supplied into the cabinets 290, 291 can efficiently be ionized by electrons from the hollow cathode.

As a result, conditions for allowing a discharge of the ion source can be expanded or a discharge is enabled at a lower gas pressure.

By arranging magnets in regions other than the installation position of the magnet 25A shown in FIGS. 61A, 61B, discharge conditions can further be expanded or a discharge is enabled at a still lower gas pressure.

(Trigger Magnet)

FIG. 62A is a plan view showing the planar structure of the end Hall ion source in which a magnet is provided. FIG. 62B is a sectional view showing the sectional structure of the end Hall ion source in which the magnet is provided.

For example, by forming a region in which the magnetic field is locally strong on the side of the ion beam emission surface in the ion source shown in FIGS. 62A and 62B, a magnetic field as a trigger for a gas discharge can be provided to the neighborhood of the ion beam emission port.

For example, as shown in FIGS. 62A and 62B, a magnet 25B is mounted on the ion emission surface. The magnet 25B is installed on the ion emission surface 290 in such a way that a distance DX1 from the end of the ion beam emission port 299 (outer edge of the emission port 299) to the end of the magnet 25B is about 1.5 cm. The magnetic field strength on the surface of the magnet 25B is about 3 kGauss.

As a result, the trajectory of electrons is increased by a Lorentz force in the magnetic field reinforced region 259 formed by the magnet 25B and the supplied gas is easily ionized.

As described by using FIGS. 61A and 61B, the installation position of a magnet is preferably on the straight line DZ1 connecting the center of the hollow cathode 21Z and the center of the ion beam emission port 299 or near the straight line DZ1.

Further, the magnet 25B preferably projects toward the substrate (not shown) side with a dimension HZ of 5 mm or more in the ion beam emission direction (direction perpendicular to the surface of the emission surface side plate 290); in other words, the magnet 25B preferably has a thickness H of 5 mm or more.

The ion beam emission direction including a solid angle is defined as an average direction of emitted ion beams.

The material of the magnet 25B for triggering is desirably a material having a high Curie temperature and a high saturation magnetic flux density. For example, an Alnico magnet (Al—Ni—Co) satisfies such characteristics and further is cheap. Thus, the Alnico magnet is desirably used as the magnet 25B for triggering.

As shown in FIG. 62B, the orientation of the magnetic field of the magnet 25B is preferably set in the same direction as the orientation of magnetic field of the ion emission surface.

FIG. 62C shows a modification of the magnet provided in the ion source in FIG. 62B. As shown in FIG. 62C, the orientation of the magnetic field of a magnet 25C may be polarized in the ion bean emission direction (direction perpendicular to the surface of the emission surface 290).

Like the example shown in FIGS. 61A and 61B, the expansion of the discharge region or a discharge at a lower gas pressure can be realized by an ion source including the magnet 25B for triggering shown in FIGS. 62A to 62C.

When a magnet is arranged on the entire surface on the side of the ion beam emission port (see, for example, FIG. 18C), the peak of the current density is located near the end of the ion beam emission port. In this case, an ion beam in an almost doughnut shape is formed under extreme magnetic field conditions.

As shown in FIGS. 62A to 62C, the expansion of the discharge region or a discharge at a lower gas pressure can be realized by at least one of the magnets 25B for discharge triggering being arranged on the side of the ion beam emission surface (on the emission surface 290). Further, the shape of an ion beam becomes a more uniform ion beam shape as a whole, thus it becomes easier to ensure uniformity of etching of a processed layer.

(2) Collimator Configuration

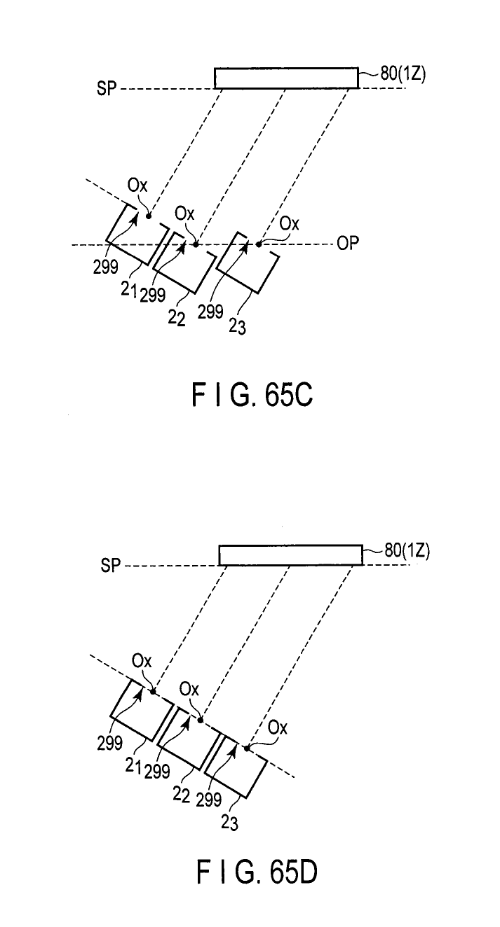

A configuration example of a collimator provided in an ion source will be described by using FIGS. 63A to 63C.

As described above, the installation of a structure in a ring shape or cylindrical shape along the ion beam emission direction leading from the ion beam emission port of an ion source to the processed layer limits the influence of an excessive divergence of an ion beam so that the collision (chamber etching) of an ion beam against the chamber including an ion source and a substrate stage can be prevented.

Such a structure capable of narrowing down the divergence of an ion beam is called a collimator.

FIG. 63A shows a configuration example of the collimator.

A collimator 77 in FIG. 63A has a structure in which a plurality (here, three) of rings 771 are stacked in the emission direction of an ion beam for the emission port 299 of an ion beam.

The three rings 771 included in the collimator 77 are installed on the emission surface side plate 290 so as to be electrically connected mutually.

The diameter of each of the rings 771 is larger than the diameter of the ion beam emission port 299. If, for example, the diameter of the ion beam emission port 299 is set to about 6 cm, the diameter of the ring 771 is set to 7 cm.

More specifically, an inside diameter DX1 of the ring 771 is set to 7 cm, an outside diameter DX2 of the ring 771 is set to 8 cm, and a thickness TX of the ring 771 is set to 3 mm. An interval SX between the rings 771 is set to about 1 cm. The adjacent rings 771 are mutually connected by a stainless spacer screw 779 while the predetermined interval SX is ensured.

The rings 771 of the collimator 77 are configured so as to be at the same potential. The collimator 77 is also installed so as to be at the same potential as that of a magnetic metal (cabinet) forming the ion beam emission surface. The ring 771 is formed of, for example, stainless steel.

The number of the rings 771 forming the collimator 77 is not limited to three and may be four or more or two or less.

The physical relationship between a collimator and a cathode will be described by using FIGS. 63B and 63C.

FIG. 63B is a schematic sectional view illustrating the physical relationship between a collimator and a hollow cathode provided in the ion source.

As shown in FIG. 63B, a collimator 77X may be configured so that electrons from the hollow cathode 21Z are supplied from an intermediate region between the end on the processed layer side in the collimator 77X and the end on the ion source side in the collimator 77X.

For example, the one collimator 77X includes two ring laminated structures (multi-ring) 770A, 770B arranged in the ion beam emission direction. The hollow cathode 21Z to be the cathode of the ion source 2 is provided between the two ring laminated structures 770A, 770B. An electron beam output by the hollow cathode 21Z is supplied to the anode 22 of the ion source 2 from between the two ring laminated structures 770A, 770B.

For example, the two ring laminated structures 770A, 770B of the collimator 77X are set to the same potential (for example, the same floating potential).

The region of the ring laminated structure 770B between the hollow cathode 21Z and the anode 22 becomes an ionization region in which a supplied gas is ionized by the discharge and an acceleration region in which the ions are accelerated and the region of the ring laminated structure 770A between the hollow cathode 21X and the processed layer/substrate (not shown) becomes a uniform motion region of ions by an electron beam from the hollow cathode 21Z being supplied from between the two ring laminated structures 770A, 770B constituting the collimator 77X.

With the ring laminated structure 770B of the collimator 77X as the acceleration region (hereinafter, also called a discharge region), the discharge region is limited to within the ring and the ionization region is advanced to the processed layer/substrate side.

An excessive divergence of an ion beam is converged by the ring laminated structure 770A of the collimator 77X as the uniform motion region (hereinafter, also called a beam narrowing region).

FIG. 63C is a schematic sectional view illustrating the physical relationship between the collimator and hollow cathode provided in the ion source in a different example from the example in FIG. 63B.

As shown in FIG. 63C, electrons from the hollow cathode 21Z may be supplied from a gap between the rings 771 ensured by the spacer screw 779 in the collimator 77 forming physically continuous ring laminated structures. In this case, relative to the position of the height of the electron supply window of the hollow cathode 21Z, a region 772B on the side of the anode 22 from the position of the electron supply window of the hollow cathode 21Z becomes the acceleration region and a region 772A on the side of the processed layer/substrate from the position of the electron supply window of the hollow cathode 21Z becomes the uniform motion region.

(3) Adjustment of the Incident Angle of an Ion Beam with Respect to the Substrate

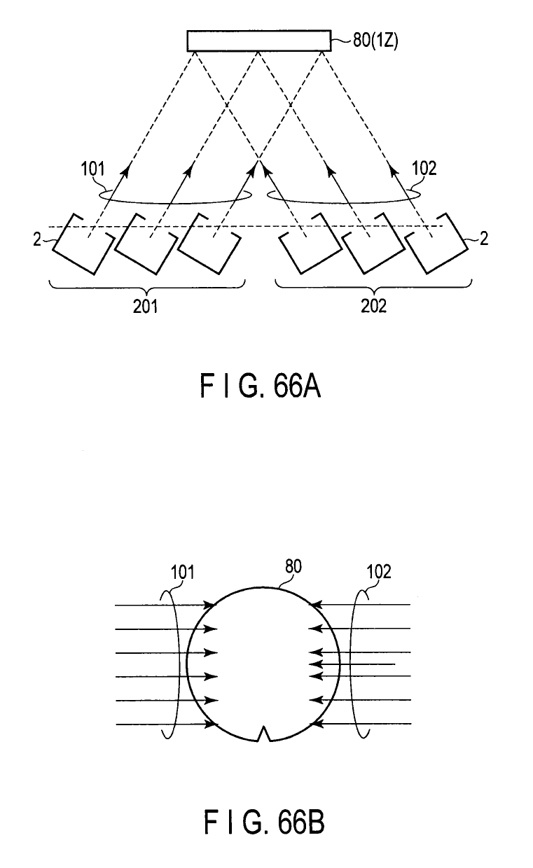

An arrangement example of the ion source with respect to the substrate will be described by using FIG. 64.

By adjusting the physical relationship between the substrate and ion source, the incident angle of an ion beam with respect to the substrate on which a processed layer is formed is adjusted to be able to achieve improvements of uniformity of etching of the processed layer.

To adjust the incident angle of an ion beam with respect to the processed layer, it is preferable to move a group of ion sources including one or more ion sources in accordance with the incident angle of the ion beam.

FIG. 64 is a schematic diagram illustrating a case when the processed layer on the substrate is processed by using ion beams having different incident angles.

Here, as an example, a case when etching by the ion beam 100A whose incident angle φ1 is set to 20° is performed, and then etching by the ion beam 100B whose incident angle φ2 is set to 40° is performed is considered.

In this case, instead of changing the angle of the substrate 80 (substrate installation stage 800), the processed layer 1Z on the substrate 80 is etched by the ion beam 100A whose incident angle φ1 is set to 20° irradiated from some ion source group (first ion source group) 200A, and then the processed layer 1Z is etched by the ion beam 100B whose incident angle φ2 is set to 40° irradiated from another ion source group (second ion source group) 200B. The ion source groups 200A, 200B that output the ion beams 100A, 100B having the mutually different incident angles φ1, φ2 respectively may be provided in the same chamber 890 or mutually different chambers 890.

When etching of a certain substrate is performed by the second ion source group 200B, the first ion source group 200A can perform etching of the next substrate transported into the chamber.

Thus, speedy substrate processing can be performed by combining the two ion sources (ion source groups) 200A, 200B having the different incident angles φ1, φ2 to perform etching by the ion beams 100A, 100B having the different incident angles φ1, φ2 with respect to the processed layer 1Z.

Further, the simpler substrate installation stage 800 can be configured by obviating an operation to change the angle of the substrate, and also, substrate processing can be performed by the simpler substrate installation stage 800, thus the reliability of an ion beam generator (etching apparatus) can be improved.

(4) Application of a Small Ion Source

Compared with an ion source having an ion emission port of a large diameter, an ion source group in which a plurality of ion sources having an ion emission port of a small diameter are arranged side by side can improve the function of an ion beam etching apparatus, in addition to reducing the manufacturing costs of an ion beam generator and magnetoresistive effect element.

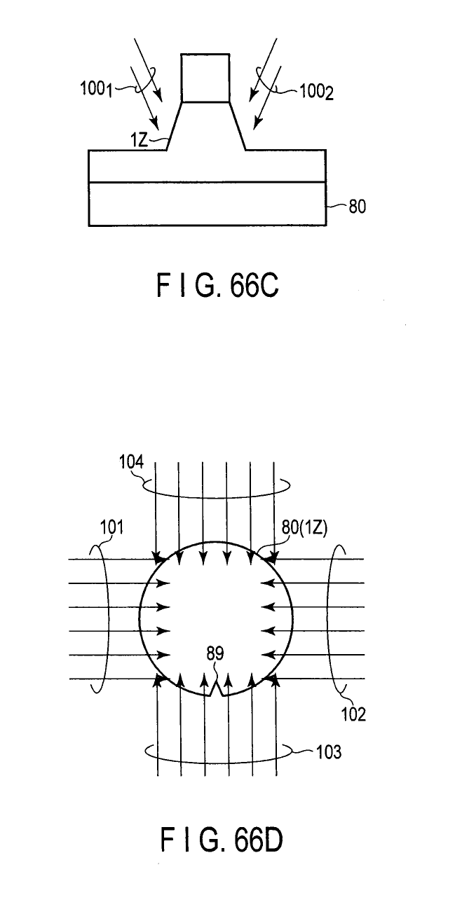

The configuration of an ion source group in which a plurality of ion sources are arranged side by side will be described by using FIGS. 65A to 65D.

FIG. 65A is a schematic sectional view showing the physical relationship between small ion sources and the substrate.

FIG. 65A is a sectional view showing the relationship between an ion source group and the substrate when a plurality of the ion sources having a small diameter (for example, the nine end Hall ion sources) 2 included in the ion source group are arranged in an array shape (3×3).

FIG. 65B is a sectional view showing the relationship of arrangement of an ion source group and the substrate when an ion source having a large diameter is arranged.

Each of the ion sources 2 of an ion source group 200 has the ion beam emission port 299 provided in the cabinet (plasma generating container). In each figure below, the center point of the ion beam emission port 299 is denoted by “Ox”.

In FIG. 65A, three ion sources 2₁, 2₂, 2₃ in the ion source group 200 are shown. The incident angle of an ion beam from each of the ion sources 2₁, 2₂, 2₃ is set to an angle φ.

The positions of the center Ox of the ion beam emission port 299 of the ion sources 2₁, 2₂, 2₃ adjacent to each other are mutually shifted by a dimension dx in the direction parallel to the ion beam emission direction.

The ion sources 2₁, 2₂, 2₃ are arranged in such a way that the interval between the centers Ox of the ion beam emission ports 299 of the ion sources 2₁, 2₂, 2₃ adjacent to each other in the direction perpendicular to the ion beam emission direction (hereinafter, called an ion beam sectional direction) is a dimension ex.

As a result, a straight line (plane) OP connecting the center Ox of the ion beam emission port of each of the ion sources 2₁, 2₂, 2₃ is parallel to a straight line SP parallel to the surface of the substrate 80.

With the arrangement between the ion sources 2₁,2₂,2₃ and between each of the ion sources 2₁,2₂,2₃ and the substrate 80 as described above, distances LX1, LX2, LX3 between the center position Ox of the ion sources 2₁, 2₂, 2₃ and the substrate 80 are respectively equal.

Accordingly, the substrate 80 is irradiated with the ion beam 100 with a solid angle δ emitted from each of the ion sources 2₁, 2₂, 2₃ in the ion source group 200 including a plurality of ion sources in the same current density.

In FIG. 65B, on the other hand, the center of a grid 50Z of a large (large-diameter) ion source 5Z is denoted by “OZ”. The radius (value of half the maximum dimension of an opening 299Z) of the grid 50Z of the grid ion source 5Z is denoted by “ez”.

When the ion source 5Z irradiates the substrate 80 with an ion beam having the incident angle φ, a straight line GF parallel to the surface of the grid 50Z is not parallel to the straight line SP parallel to the surface of the substrate 80 and the angle φ corresponding to the incident angle of an ion beam is formed.

Thus, if the distance from the center OZ of the grid 50Z to the substrate 80 is “LZ1”, the distance between the substrate 80 and an edge of the grid 50Z on the side closer to the substrate 80 is “LZ2” (<LZ1), and the distance between the substrate 80 and an edge of the grid 50Z on the side farther from the substrate 80 is “LZ3” (>LZ1), the distance represented by dz=ez tan⁻¹φ arises between the center OZ of the grid 50Z and an end of the grid 50Z.

In the large ion source 5Z, a difference in current density in accordance with the solid angle of an ion beam arises in the ion beam emitted on the substrate 80 due to a difference of distance dz between the substrate 80 and the grid 50Z. As a result, a difference of the etching rate of the processed layer 1Z arises.

Therefore, as shown in FIG. 65A, an emission surface OP of an ion beam is preferably parallel to a surface SP of the substrate 80 on which the processed layer 1Z is formed to ensure uniformity of processing of the processed layer 1Z on the substrate 80.

However, a straight line OP connecting each ion source inside the ion source group 200 and the ion beam emission port and the surface of the substrate 80 may not be exactly parallel to each other.

For example, under the influence of mutual interference of ion beams from ion sources adjacent to each other, an ion beam from a certain ion source may be irradiated on other ion sources or hollow cathodes so that such ion sources or hollow cathodes may be etched by ion beams. In addition, the processed layer may be contaminated with members generated by etching of ion sources or hollow cathodes.

To prevent the contamination, the ion source group 200 may be arranged with respect to the substrate 80 in such a way that the straight line OP connecting centers Ox of the ion emission ports of ion sources in a plurality of ion sources of the ion source group in FIG. 65A is not parallel to the surface of the substrate 80.

FIGS. 65C and 65D are schematic sectional views showing a modification of the physical relationship between the ion source group and substrate in FIG. 65A.

For example, as shown in FIG. 65C, the ion sources 2₁, 2₂, 2₃ may not be arranged inside the ion source group 200 in such a way that the centers of the ion beam emission ports 299 of all the ion sources 2₁, 2₂, 2₃ inside the ion source group 200 are aligned on the same straight line.

In FIG. 65C, for example, the centers Ox of the ion beam emission ports 299 of the two ion sources 2₂, 2₃ inside the ion source group 200 are arranged along the same straight line and the straight line OP connecting the centers Ox of the ion beam emission ports 299 of the ion sources 2₂, 2₃ is parallel to the surface SP of the substrate 80.

Among a plurality of the ion sources 2₁, 2₂, 2₃ inside the ion source group 200, the one ion source 2₁ is moved (arranged) so that a center Oxx of the ion beam emission port 299 is closer to the substrate 80 than the ion sources 2₂, 2₃ arranged on the straight line OP parallel to the surface of the substrate 80.

By shifting the arrangement of a portion of the ion sources 2₁, 2₂, 2₃ inside the ion source group 200 with respect to the substrate 80 relative to the arrangement of other ion sources in this manner, contamination of the processed layer by members generated by etching of adjacent ion sources or hollow cathodes can be suppressed.

In FIG. 65D, the ion beam emission ports of the ion sources 2₁, 2₂, 2₃ inside the ion source group 200 are aligned on the same straight line. In the ion sources 2₁, 2₂, 2₃ in FIG. 65D, however, an angle substantially equal to the incident angle φ of an ion beam is formed between a straight line OPP connecting the centers of the ion beam emission ports 299 and the straight line SP parallel to the surface of the substrate 80.

The same problem as that of the large-diameter ion source 5Z in FIG. 65B may arise for the ion source group 200 in FIG. 65D. However, with the ion source group 200 formed from the ion sources 2₁, 2₂, 2₃, the angle and position/distance with respect to the substrate 80 can relatively easily be adjusted for each of the ion sources 2₁, 2₂, 2₃ inside the ion source group 200. Thus, compared with a large ion source, versatility of the ion source group 200 including the ion sources 2₁, 2₂, 2₃ is increased. As a result, when compared with a case in which a large ion source is used, the ion source group 200 in FIG. 65D can suppress an increase in costs (for example, maintenance costs) of an ion beam generator (ion beam etching apparatus).

(5) Arrangement of a Plurality of Ion Source Groups

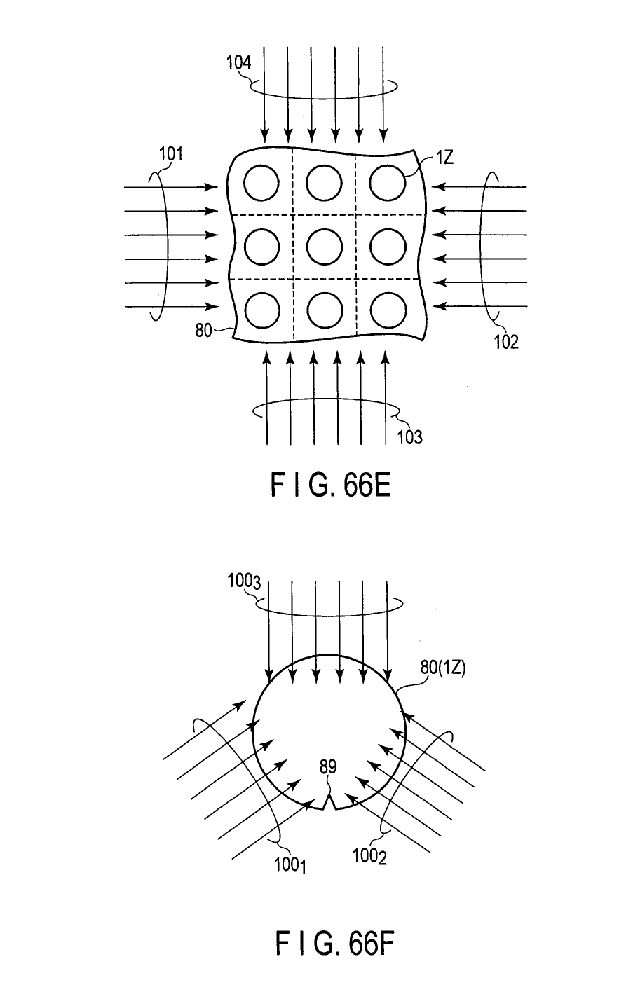

A case when a magnetoresistive effect element (and MRAM) is formed by using a plurality of ion source groups will be described by using FIGS. 66A to 66G.

When a substrate is irradiated with an ion beam at an incident angle, the substrate may be irradiated with not only an ion beam from an ion source group from a direction, but also ion beams from a plurality of directions by using a plurality of ion source groups.

Accordingly, reattachments on the processed layer (MTJ element) can be removed more reliably.

FIG. 66A is a sectional view schematically showing the configuration when the processed layer on the substrate is processed by using a plurality of ion source groups. FIG. 66B is a plan view schematically showing the configuration when the processed layer on the substrate is processed by using the ion source groups. FIG. 66C is a sectional view schematically showing a state during processing of the processed layer when the processed layer on the substrate is processed by using the ion source groups.

For example, as shown in FIGS. 66A and 66B, two ion source groups 201, 202 are provided for the one substrate 80 to etch the processed layer on the substrate. The two ion source groups 201, 202 are arranged inside a chamber (not shown) opposite each other across a line (normal of the substrate 80) perpendicular to the surface of the substrate 80.

The two ion source groups 201, 202 emit ion beams 101, 102 on the substrate 80 respectively from directions linearly symmetrical to the line perpendicular to the surface of the substrate 80. The two ion source groups 201, 202 have ion beam incident angles φ1, φ2 having the same magnitude respectively.

The incident angles φ1, φ2 of the ion beams 101, 102 of the ion source groups 201, 202 have the relation φ1=−φ2 relative to the line perpendicular to the surface of the substrate 80.

As shown in FIG. 66B, when viewed from the direction perpendicular to the surface of the substrate 80, the ion beams 101, 102 irradiated from the two ion source groups 201, 202 respectively are incident on the substrate 80 from directions opposite each other in the direction parallel to the surface of the substrate 80. It is assumed here that the position of a notch (or an orientation flat) 89 of the substrate (silicon wafer including inter-layer insulating films) 80 is a 6 o'clock direction of a clock, the direction of incidence of the ion beam 101 from the one ion source group 201 on the substrate 80 is a 9 o'clock direction, and the direction of incidence of the ion beam 102 from the other ion source group 202 on the substrate 80 is a 3 o'clock direction.

When, as shown in FIGS. 66A and 66B, the substrate 80 is irradiated with the ion beams 101, 102 from the two ion source groups 201, 202 by using the direction perpendicular to the substrate surface as an axis of symmetry, as shown in FIG. 66C, side faces opposite each other of the processed layer (MTJ element) 1Z on the substrate 80 are irradiated with the ion beams 101, 102 so that the side faces opposite each other of the processed layer 1Z are processed simultaneously.

When, for example, the processed layer on the substrate is processed by an ion source group, the side face of the processed layer on the opposite side of the side on which an ion beam is irradiated becomes a shadow in the direction of incidence of the ion beam. Thus, most reattachments attach to the side face of the processed layer on the opposite side of the direction of incidence of an ion beam. In general, reattachments on the side face of the processed layer are removed by performing processing by an ion beam while rotating the substrate. However, a shadow portion in the direction of incidence of an ion beam arises in principle in the processed layer in the end time of rotation of the substrate, thus reattachments may remain on some side faces of the processed layer.

On the other hand, as shown in FIGS. 66A to 66C, reattachments on the side face of the processed layer 1Z are etched when the substrate 80 is irradiated with the ion beams 101, 102 from directions opposite each other while processing of the processed layer 1Z is in process.

Thus, when the substrate 80 is irradiated with the ion beams 101, 102 having a certain solid angle or more, the processed layer 1Z can be processed into an MTJ element in a predetermined shape with reattachments hardly formed on the side face of the processed layer by the processed layer 1Z being irradiated with the ion beams 101, 102 from a plurality of directions.

As a result, insulating properties (electrical isolation) between magnetic layers of an MTJ element can be ensured and the reliability of the MTJ element can be enhanced.

Further, reattachments can be removed from the side face of the processed layer (MTJ element) more efficiently by the substrate 80 being rotated by 90 degrees in a direction parallel to the substrate surface so that ion beams are incident from the 6 o'clock direction (side of the notch 89) and 12 o'clock direction of the substrate 80 during processing of the processed layer 1Z. Accordingly, the reliability of the MTJ element is further enhanced.

FIGS. 66D to 66G are schematic diagrams illustrating modifications of FIGS. 66A to 66C.

As shown in FIGS. 66D and 66E, processed members can further be inhibited from reattaching the processed layer by the substrate 80 being irradiated with ion beams 101, 102, 103, 104 simultaneously from four directions (for example, the 0 o'clock direction, 3 o'clock direction, 6 o'clock direction, and 9 o'clock direction of the substrate).

In this case, as shown in FIG. 66E, creation of a shadow portion in the irradiation direction of an ion beam of MTJ elements (processed layers) can be mostly avoided by emitting the ion beam from a direction from which a gap between MTJ elements arranged in a certain region (for example, a memory cell array of MRAM) is visible. Accordingly, an MTJ element having a large aspect ratio (ratio of the height and width of the MTJ element) can be formed. As a result, a plurality of MTJ elements can be formed in the unit area so that an MRAM of a high storage density can be provided.

As shown in FIG. 66F, three ion source groups may be arranged at a 120° angle in the direction parallel to the surface of the substrate 80. The three ion source groups are provided for the one substrate 80. In this case, the substrate 80 is irradiated with the ion beams 101, 102, 103 from three directions of the 0 o'clock direction, 4 o'clock direction, and 8 o'clock direction of the substrate 80.

With the irradiation of the ion beams 101, 102, 103 from three directions, the processed layer 1Z on the substrate 80 is irradiated uniformly with ion beams from a small number of ion source groups to etch the processed layer 1Z.

Further, as shown in FIG. 66G, a plurality of ion source groups may be arranged approximately annularly around the substrate 80. For example, eight ion source groups are provided for a substrate. Then, the processed layer 1Z on the substrate 80 is irradiated with ion beams 101, 102, 103, . . . , 107, 108 to etch the processed layer 1Z.

Also, in the example shown in FIG. 66G, substantially the same effect as that of the examples shown in FIGS. 66A to 66F can be obtained.

Even if the substrate is irradiated with ion beams from three directions or more as shown in FIGS. 66D to 66G, the orientation of the substrate may be rotated during processing of the processed layer.

When, as described above, an MTJ element is formed by using a plurality of ion source groups, uniformity of processing of the MTJ element can be enhanced and the reliability of the MTJ element can be improved. However, the arrangement of ion sources in an ion source group may not be isolatable for the irradiation of ion beams from different directions in accordance with the magnitude of the incident angle of an ion beam with respect to the substrate and the distance between the substrate and ion source.

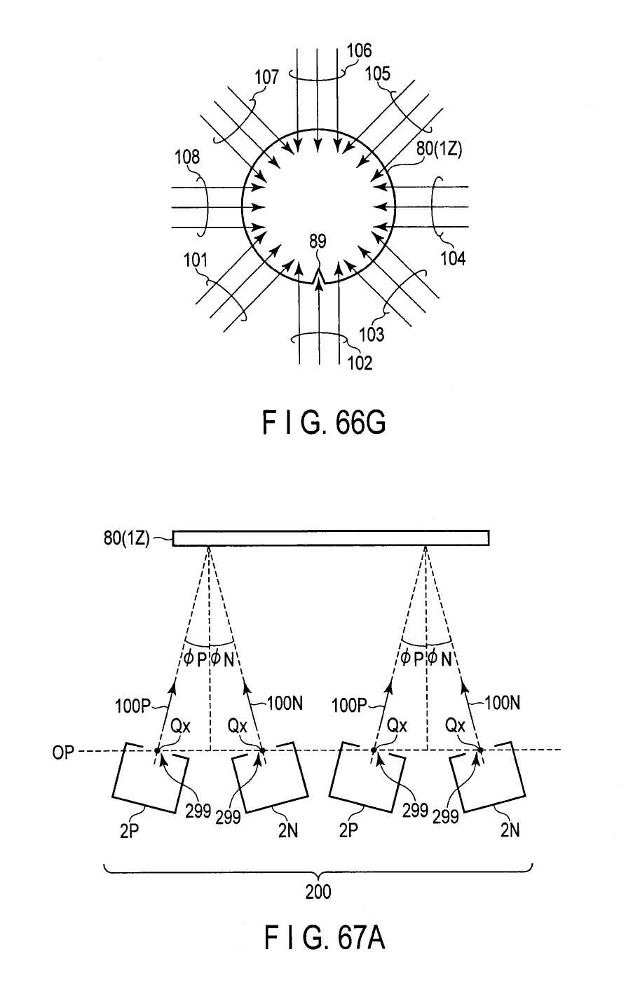

An internal configuration example of an ion source group when the arrangement of ion sources in the ion source group cannot be isolated will be described by using FIGS. 67A to 67C.

FIG. 67A is a sectional view schematically showing the arrangement of ion sources in an ion source group. FIGS. 67B and 67C are plan views schematically showing the arrangement of ion sources in the ion source group.

As shown in FIG. 67A, the ion source group 200 includes a plurality of ion sources 2P, each of which outputs an ion beam 100P having an incident angle φ_{P} with respect to the substrate 80, and a plurality of ion sources 2N, each of which outputs an ion beam 100N having an incident angle φ_{N} with respect to the substrate 80.

When, for example, the position of the notch of the substrate is set to the 6 o'clock direction, the ion beam 100P at the incident angle φ_{P} is irradiated on the substrate 80 from the 9 o'clock direction of the substrate and the ion beam 100N at the incident angle φ_{N} is irradiated on the substrate 80 from the 3 o'clock direction of the substrate. Regarding the incident angle with respect to the direction perpendicular to the surface of the substrate 80, the incident angle φ_{P} of an ion beam irradiated from the 9 o'clock direction of the substrate is called a positive incident angle and the incident angle φ_{N} of an ion beam irradiated from the 3 o'clock direction of the substrate is called a negative incident angle.

As shown in FIG. 67A, the ion source 2P that outputs the ion beam (ion beam from the 9 o'clock direction) 100P having the positive incident angle φ_{P} with respect to the direction perpendicular to the surface of the substrate 80 and the ion source 2N that irradiates the ion beam (ion beam from the 3 o'clock direction) 100N having the negative incident angle φ_{N} with respect to the direction perpendicular to the substrate surface are alternately arranged along the direction parallel to the substrate surface.

The ion sources 2N, 2P are arranged so that the centers Qx of the emission ports of the ion beams 100N, 100P are present in the same plane OP (the same straight line OP). The plane OP including the center Qx of the emission port 299 of each of the ion sources 2N, 2P is parallel to the surface of the substrate 80.

As shown in FIGS. 67B and 67C, the ion sources 2N, 2P are arranged in an array shape (matrix shape) in a predetermined region of the ion source group 200.

In FIGS. 67B and 67C, the ion source 2P that outputs the ion beam (ion beam from the 9 o'clock direction) 100P having the incident angle φ_{P} is denoted by the symbol “+” and the ion source 2N that outputs the ion beam (ion beam from the 3 o'clock direction) 100N having the incident angle φ_{N} (=−φ_{P}) is denoted by the symbol “−”.

FIG. 67A corresponds to the section along line A-A in FIG. 67B.

As shown in FIG. 67B, the ion sources 2N, 2P that output ion beams having different incident angles in magnitude (different irradiation directions) are alternately arranged in a direction parallel to the direction from 3 o'clock toward 9 o'clock of the substrate.

In FIG. 67B, the ion sources 2P that output the ion beam (ion beam from the 9 o'clock direction) 100P having the incident angle φP are arranged on the same straight line in a direction parallel to the direction from 6 o'clock toward 12 o'clock of the substrate. Similarly, the ion sources 2N that output the ion beam (ion beam from the 3 o'clock direction) 100N having the incident angle φ1 are arranged on the same straight line in a direction parallel to the direction from 6 o'clock toward 12 o'clock of the substrate.

As shown in FIG. 67C, the ion source 2N that outputs the ion beam 100N having the incident angle φ_{N} and the ion source 2P that outputs the ion beam 100P having the incident angle φ_{P} may be alternately arranged in a direction parallel to the direction from 6 o'clock toward 12 o'clock of the substrate 80.

For example, an ion beam etching apparatus including the ion source group 200 is configured in such a way that the substrate 80 is reciprocated by the substrate holding stage (not shown) along a direction parallel to the direction from 3 o'clock toward 9 o'clock of the substrate 80 above the ion source group 200 (direction perpendicular to the substrate surface).

As shown in FIGS. 67A to 67C, with a plurality of the ion sources 2N, 2P having different incident angles (directions of incidence) of ion beams with respect to the substrate arranged alternately in a certain direction, a region where the processed layer 1Z on the substrate 80 is uniformly irradiated with the ion beam 100P having the positive incident angle φ_{P} and the ion beam 100N having the negative incident angle φ_{N} is widened. As a result, uniformity of etching of the processed layer 1Z is improved.

FIGS. 67D and 67E are diagrams showing a modification of FIGS. 67A to 67C.

FIG. 67D is a sectional view schematically showing the arrangement of ion sources in an ion source group.

FIG. 67E is a plan view schematically showing the arrangement of ion sources in the ion source group.

As shown in FIGS. 67D and 67E, ion sources having different incident angles of ion beams may be arranged in a staggered configuration in a portion of the ion source group 200.

Though a large ion source can irradiate an ion beam on the processed layer intensively from a certain direction, as described above by using FIG. 65B, non-uniformity of an ion beam from the large ion source may have an influence on processing of the processed layer. Thus, a tapered shape of the processed layer formed by etching may have location dependence.

The influence of non-uniformity of an ion beam of a grid ion source can be reduced by increasing the distance between the substrate and the ion source. In this case, it is desirable to increase the distance to such an extent that a difference of distances arising between both ends of the ion source and both ends of the substrate can be ignored when compared with non-uniformity of an ion beam. However, the mean free path of an ion (gas particle) during operation of an ion source is generally a few tens of cm, thus the beam spread (arrival of ions at the substrate) of an ion beam may be hindered if the distance between the substrate and the ion source is increased.

Thus, as shown in FIGS. 66A to 67E, it is preferable to arrange a plurality of ion sources having a small diameter in a direction parallel to the substrate surface.

(6) Adjustment of the Ion Source Angle with Respect to the Substrate

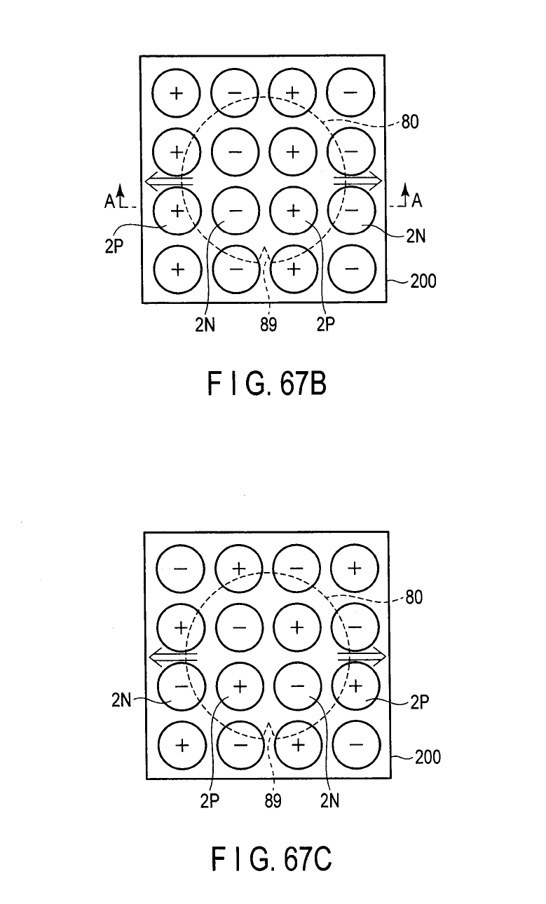

The relationship between the substrate and the angle of an ion source when an ion source group is configured by arranging a plurality of small ion sources will be described by using FIG. 68.

In FIG. 68, a straight line connecting the center Qx of the ion beam emission port 299 of each of the ion sources 2 is denoted by “QP”. Also, a straight line corresponding to the average direction of the ion beam 100 emitted from one of the ion sources 2 is denoted by “DR”. A plane (straight line) orthogonal to the straight line DR at the center Qx of one of the ion beam emission ports 299 is denoted by “NR”. In this case, the straight line QP and the plane NR crossing each other are denoted by “γ”. The angle γ is larger than 0.

The plane (straight line) parallel to the surface of the substrate 80 is denoted by “SP”. The angle formed by the plane SP and the straight line QP is set as “θ_{Z}”.

If the incident angle of the ion beam 100 with respect to the substrate is φ, γ=φ−θ_{Z} holds. In this relation, the angle θ_{Z} is set so that 0≦θ_{Z}≦φ is satisfied.

In this case, the relation of each angle is γ=φ−θ_{Z}>0, where 0≦θ_{Z}≦φ.

When θ_{Z}=0, the distance between each of the ion sources 2 inside the ion source group 200 and the substrate 80 is equal. In this case, the magnitude of the angle γ becomes the magnitude of the angle φ. When γ=φ, γ takes the maximum value. Accordingly, the influence of location dependence of the current density due to dispersion of an ion beam is minimized.

(7) Installation of the Collimator for an Ion Beam Group

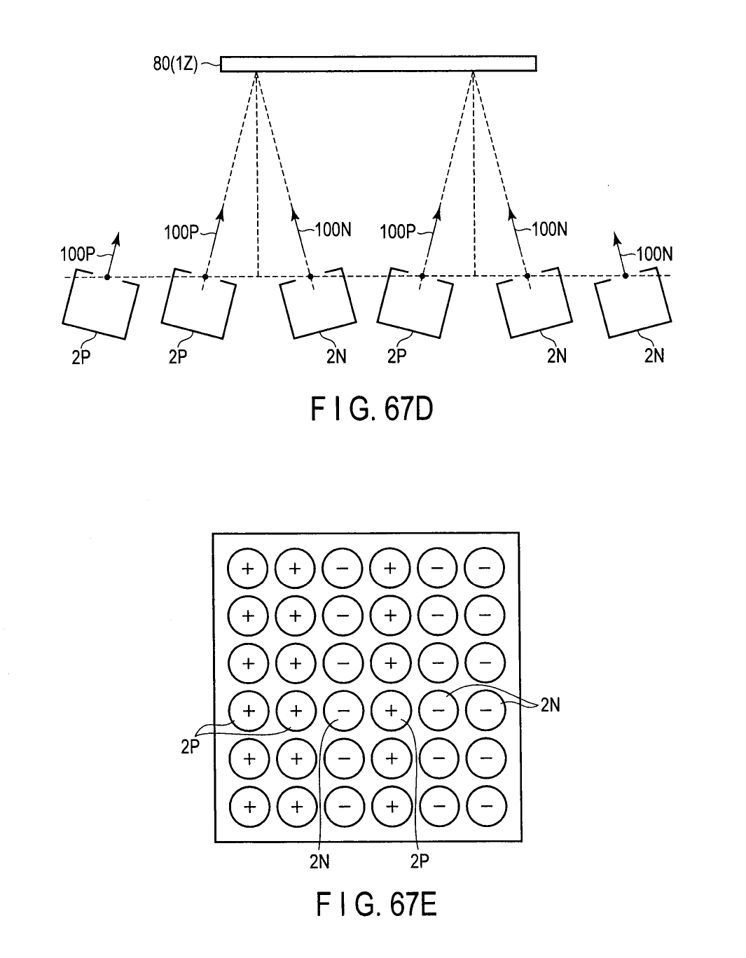

An installation example of the collimator for an ion beam group will be described by using FIG. 69.

FIG. 69 is a sectional view schematically showing the structure of an ion source group.

When the angle γ in FIG. 68 is increased by the angle of an ion source with respect to the substrate being set to a certain value or greater, the cabinet of another adjacent ion source or an attached structure (for example, a hollow cathode) may be irradiated with an ion beam from some ion source.

Members resulting from the cabinet of an ion source or an attached structure generated by the irradiation of an ion beam may cause mixing of impurities into the processed layer on the substrate.

Thus, as shown in FIG. 69, it is preferable to, instead of providing a collimator for the ion source group 200, install a collimator 70 in the ion beam emission port of each of the ion sources 2 in the ion source group 200. Accordingly, excessive dispersion of an ion beam can be suppressed and also the irradiation of adjacent ion sources/attached structures with an ion beam can be suppressed.

(8) Control of an Ion Beam

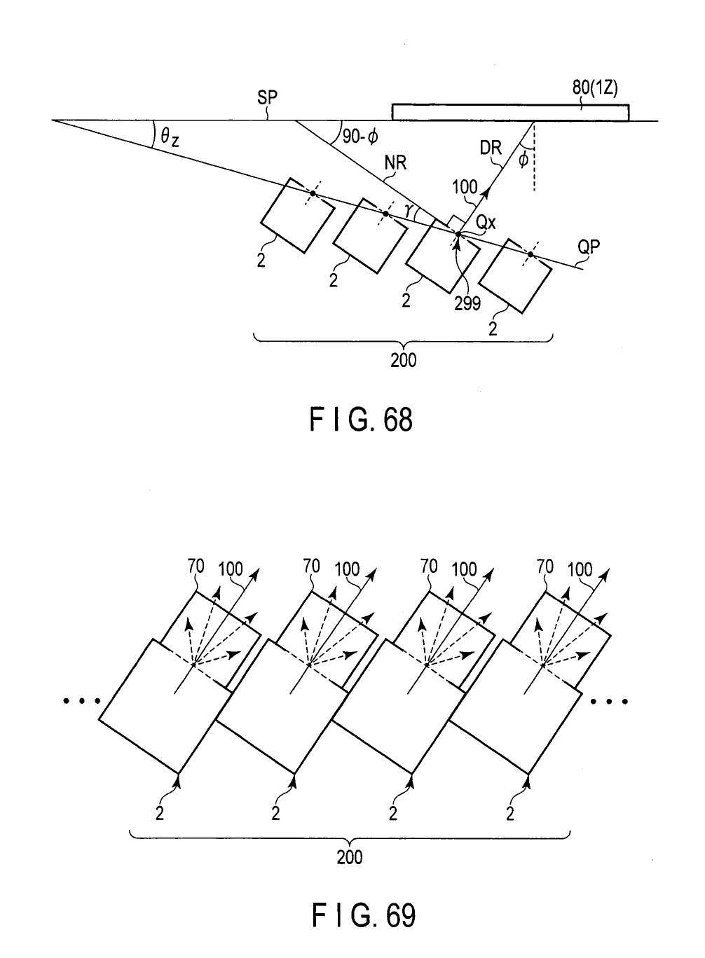

The control of an ion beam output from an ion beam group will be described by using FIGS. 70A to 70D.

It is preferable to form a sheet or linear ion beam to uniformly etch the side face of a processed layer (MTJ element) on the substrate. However, due to limitations of the distribution of the magnetic field of an ion source, it is difficult for a gridless ion source like an end Hall type to have a large diameter (for example, 30 cm in diameter).

When a linear ion beam is formed by an ion source, dispersion of a beam is in principle likely to arise in the line width direction of an ion beam. Thus, the dispersion of an ion beam on the substrate may increase to a predetermined magnitude or more.

Moreover, it is difficult to apply a magnetic flux uniformly to a linear ion beam emission port to form a linear ion beam and thus, dispersion is likely to arise in the ion beam.

A linear ion beam can be formed by, like the above ion source group, ion sources being arranged on the same straight line. In this case, intensity of an ion beam can be controlled for each ion source. When an ion beam is generated by a plurality of ion sources, maintenance can be performed for each ion source for aging of an ion source due to contamination or the like.

FIG. 70A shows a plan view in which a plurality of end Hall ion sources are arranged.

As shown in FIG. 70A, an end Hall ion source 2E has a rectangular cabinet (cubic structure) and the shape of an ion beam emission port 299E is elliptic.

An ion beam emitted from each of the ion sources 2E is brought closer to a linear shape by adopting an elliptic shape for the ion beam emission port 299E. Compared with a rectangular ion beam emission port, the elliptic ion beam emission port 299E is less likely to have a non-uniform magnetic field strength in the elliptic emission port. Thus, a uniform ion beam can easily be obtained from the ion source 2E having the elliptic ion beam emission port 299E.

Of the ion sources 2E adjacent to each other in the minor axis direction of the ellipse of the ion beam emission port 299E, as shown in FIG. 70A, the ion sources 2E are arranged in such a way that an end in the major axis direction of the ellipse of the ion beam emission port 299E in the elliptic shape of each of the ion sources 2E is positioned on the same straight line along a direction parallel to the minor axis direction of the ellipse.

Of the ion sources 2E adjacent to each other in the major axis direction of the ellipse of the ion beam emission port 299E, for example, the ion sources 2E are arranged in such a way that the major axis direction of the ellipse of the ion beam emission port 299E in the elliptic shape of each of the ion sources 2E is positioned on the same straight line.

However, the position of the ion beam emission port 299E in the elliptic shape of each of the ion sources 2 may overlap in a direction parallel to the minor axis direction of the ellipse. Ion sources adjacent to each other in the major axis direction of the ellipse of the ion beam emission port 299E may be arranged in such a way that the minor axis direction of the ellipse of the ion beam emission port 299E deviates from the same straight line.

The substrate 80 is reciprocated in the direction parallel to the substrate surface to etch the processed layer on the substrate above an ion source group (direction perpendicular to the substrate surface) including ion sources having an elliptic ion beam emission port.

A modification of the ion source having an elliptic ion beam emission port will be described by using FIGS. 70B to 70D. FIGS. 70B to 70D show a schematic plan view when the ion source according to the modification is viewed from the emission port side (substrate side).

When the cabinet of the ion source has a rectangular shape, the manufacture of the ion source can be simplified and manufacturing costs can be reduced.

However, as shown in FIG. 70B, the planar structure on the emission port side (emission surface side plate) of the cabinet of the ion source may have an elliptic shape. Compared with an ion source whose planar structure on the emission port side is rectangular, an elliptic ion source 2EE whose emission port side plate 290E has an elliptic planar structure can supply a uniform magnetic flux to the ion beam emission port 299E relatively easily. Thus, the planar structure on the emission port side of the ion source 2EE is preferably set to an elliptic shape to form a uniform ion beam.

Incidentally, the shape of the emission port of an ion beam may be circular.

When the ion beam emission port 299E has an elliptic shape, the magnetic field strength in a region where the radius of curvature of the ellipse (minor axis direction of the ellipse) is large may fall.

Thus, as shown in FIGS. 70C and 70D, it is preferable to arrange the magnet 25E to reinforce the magnetic field strength on the cabinet 290 along the minor axis of the ellipse or near the region where the radius of curvature of the ellipse is large. The radius of curvature of the ellipse is the largest on the minor axis of the ellipse in the ion beam emission port 299E in an elliptic shape. Thus, the magnet 25E is provided on the cabinet (ion beam emission port side plate) 290 near the region where the radius of curvature of the ellipse is the largest.

In addition, the thickness of the magnetic metal (cabinet) 290 on the ion beam emission surface side may be increased in the region where the radius of curvature of the ellipse is large to reinforce the magnetic field strength.

Thus, a uniform ion beam can be formed relatively easily by increasing the magnetic field strength applied to the emission port 299E in accordance with the shape of the ion beam emission port 299E.

An ion source group using a plurality of small-diameter grid ion sources can achieve the same effect as that of an ion source group formed of gridless ion sources.

For example, instead of a grid ion source of 30 cm in diameter, a plurality of grid ion sources whose diameter on the ion beam emission port side is about 10 cm may be arranged along the direction parallel to the substrate surface to process a processed layer on the substrate. However, while the energy of an ion beam to process a processed layer is preferably set to 100 eV or less, it is difficult for a grid ion source to secure a large current density. Thus, it is desirable to form ion sources by combining a grid ion source and a gridless ion source (for example, an end Hall ion source).

(9) Control of Operation Intensity of an Ion Source

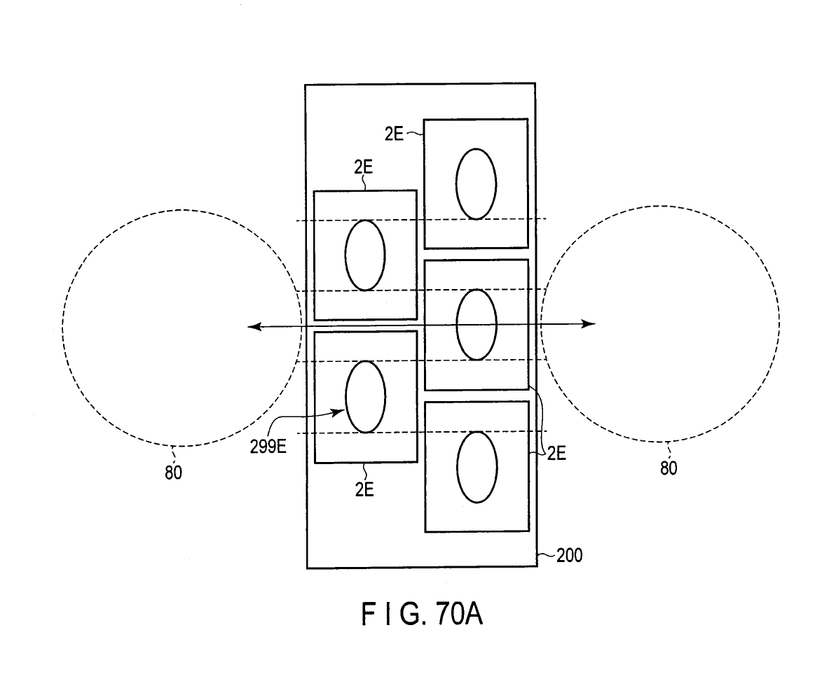

The operation control of an ion source in an ion source group will be described by using FIGS. 71A and 71B.

When in-plane uniformity of the processing surface of a processed layer is ensured by processing the processed layer on the substrate while rotating the substrate, it is preferable to change the operation intensity (for example, a current value) of each ion source in the radial direction of the substrate (direction parallel to the substrate surface) for a plurality of ion sources in an ion source group.

FIG. 71A is a plan view schematically showing an operation state of an ion source group during processing by rotating the substrate.

When the center of layout of a plurality of ion sources arranged in an ion source group and the rotation center of the substrate approximately match, the angle of movement of the substrate in the unit time (that is, the moving distance) is proportional to the radius.

Thus, the amount of ion beams irradiated on the substrate is made equal by increasing the current value of the ion source in the direction in which the radius increases. As a result, in-plane uniformity of the processed layer on the substrate is improved.

In FIG. 71A, the ion source to which a large current is supplied is denoted by “A” and the ion source to which a small current is supplied is denoted by “B”. The center position of the ion source group is denoted by “CC”.

For example, as shown in FIG. 71A, the current supplied to an ion source 2W arranged near the center of the ion source group 200 is decreased. The current supplied to an ion source 2S arranged on the outer circumferential side of the ion source group is made larger than the current supplied to the ion source 2W arranged near the center of the ion source group 200.

By controlling the current value of each of the ion sources 2S, 2W as described above, the ion source 2W arranged near the center of the ion source module 200 discharges weakly and the ion source 2S arranged on the outer circumferential side of the ion source module 200 discharges strongly.

Thus, when the ion source group 200 formed of a plurality of the ion sources 2S, 2W is used to process the processed layer on the substrate, the current and energy can be set to any value for each of the ion sources 2S, 2W, thus uniformity of the shape of an element (here, an MTJ element) formed from the processed layer can be improved.

FIG. 71B is a plan view schematically showing the operation of the substrate during processing of the substrate. FIG. 71B shows a locus of the substrate combining a motion of rotation (broken line in FIG. 70B) RM1 of the substrate and a motion of revolution (solid line in FIG. 71B) RM2 of the substrate around the center CC of the ion source group as the center of revolution. The substrate 80 moves along the direction parallel to the substrate surface above the ion source group by drawing a locus of the motion of rotation RM1 and the motion of revolution RM2 shown in FIG. 71B.

In-plane uniformity of etching of the processed layer can be improved by, in addition to the control of ion beam intensity, the combination of the rotation and revolution of the substrate.

(10) Array of Ion Source Groups

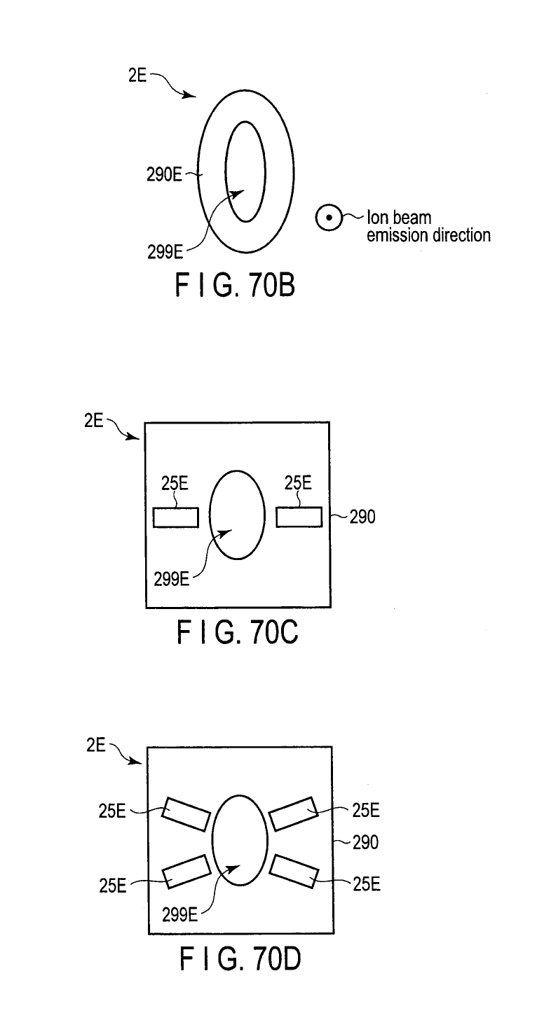

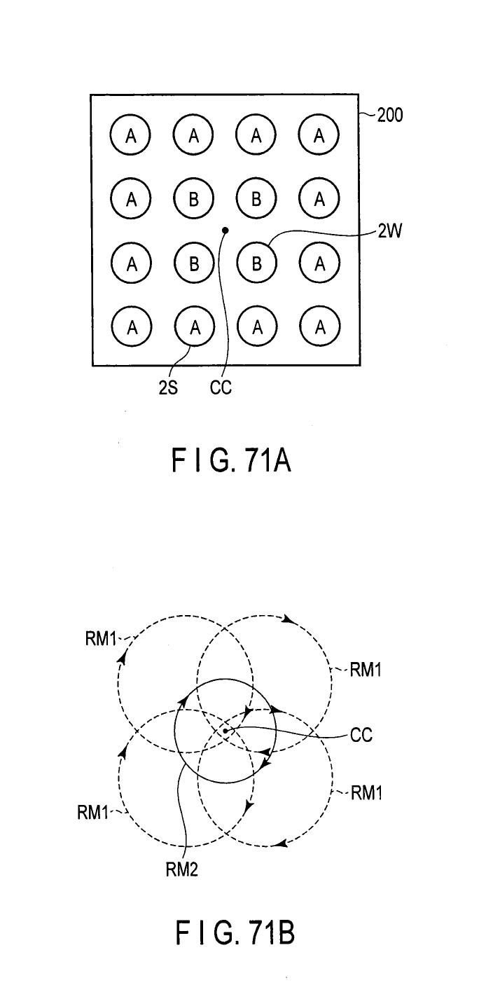

An arrangement example of an ion source group including a plurality of ion sources irradiating ion beams from mutually different directions will be described by using FIGS. 72A to 73. The basic configuration of a plurality of ion sources forming an irradiation surface where ion beams from mutually different directions are irradiated and a plurality of ion beams overlap on the processed layer will be described below as an ion source set.

In an arrangement (a layout) of ion sources in the Ion source set, ion sources are arranged in the ion source set (ion beam etching apparatus) so that the straight lines connecting to the center of the emission port of each of the ion sources form polygon (for example, a triangular shape, a quadrangle shape or a pentagonal shape).

FIG. 72A shows a bird's eye view of an ion source set including a plurality of ion sources irradiating ion beams from a plurality of mutually different directions.

In the example shown in FIG. 72A, an ion source set 205 includes four ion sources 2E, 2N, 2S, 2W. Ion beams 100E, 100N, 100S, 100W having a solid angle of 10° or more from four directions are simultaneously irradiated on the substrate 80. An irradiation surface (hereinafter, also called an ion beam irradiation surface) 190 is formed in a position on the substrate 80 where the four ion beams 100E, 100N, 100S, 100W overlap. Processing of the processed layer 1Z proceeds around the ion beam irradiation surface 190 on the substrate 80.

Thus, the one ion beam irradiation surface (processing surface) 190 is formed on the substrate 80 by ion beams from a plurality of ion sources in an ion source set.

FIG. 72B is a schematic diagram showing the state during irradiation of ion beams by the ion source set when viewed from the back side of the substrate.

Like the above examples, the position of the notch (or the orientation flat) of the substrate (wafer) is defined as the 6 o'clock direction (azimuth) of the substrate.

In the example shown in FIG. 72B, the ion source 2N irradiates the irradiation surface 190 of the substrate 80 with the ion beam 100N from the 0 o'clock direction of the substrate 80. The ion source 2E irradiates the irradiation surface 190 of the substrate 80 with the ion beam 100E from the 3 o'clock direction of the substrate. The ion source 2S irradiates the irradiation surface 190 of the substrate 80 with the ion beam 100S from the 6 o'clock direction of the substrate 80. The ion source 2W irradiates the irradiation surface 190 of the substrate 80 with the ion beam 100W from the 9 o'clock direction of the substrate.

Incidentally, the incident angles of the ion beams 100E, 100N, 100S, 100W from the ion sources 2E, 2N, 2S, 2W with respect to the substrate 80 are all set to the same value.

The formation of a magnetoresistive effect element (processing of a processed layer) by a plurality of ion source sets will be described by using FIG. 73.

FIG. 73 shows a plan view when an ion source group (etching apparatus) including a plurality of ion source sets is viewed from the back side of the substrate. An ion beam generator (ion source group) is formed from a plurality of ion source sets.

The ion source sets are linearly arranged, and, as a result, a plurality of irradiation surfaces formed on the substrate are connected.

In FIG. 73, seven ion source sets; 205₁, 205₂, 205₃, . . . , 205₆, 205₇ are provided. When the ion source sets are not distinguished below, the ion source set is referred to as ion source set 205.

The irradiation surface 190 is formed on the substrate by ion beams in four directions from the four ion sources 2E, 2N, 2S, 2W in each of the ion source sets 205. As described by using FIG. 72B, the irradiation surface 190 is irradiated with the ion beams 100N, 100E, 100S, 100W from the directions (azimuths) of 0 o'clock, 3 o'clock, 6 o'clock and 9 o'clock of the substrate, respectively.

A plurality of the ion source sets 207 is arranged on the same straight line.

A plurality of the ion sources 2N irradiating ion beams from the 0 o'clock direction of the substrate is denoted by “N” in FIG. 73. The ion sources 2N are arranged on the same straight line. A plurality of the ion sources 2E irradiating ion beams from the 3 o'clock direction of the substrate is denoted by “E” in FIG. 73. The ion sources 2E are arranged on the same straight line. A plurality of the ion sources 2S irradiating ion beams from the 6 o'clock direction of the substrate is denoted by “S” in FIG. 73. The ion sources 2S are arranged on the same straight line. A plurality of the ion sources 2W irradiating ion beams from the 9 o'clock direction of the substrate is denoted by “W” in FIG. 73. The ion sources 2E are arranged on the same straight line. The arrangement directions of the ion sources 2E, 2N, 2S, 2W are parallel to each other.

Accordingly, a linear region (etching region, irradiation region) that can be irradiated with ion beams from four directions is formed. The linear region is formed from a plurality of the irradiation surfaces 190 connected in a row.

The substrate passes above a plurality of the ion source sets 205 arranged along a certain direction (region overlapped in a direction perpendicular to the substrate surface) by making a linear motion (or a reciprocating motion). The ion beam irradiation surface 190 on the substrate (processed layer) is aligned on the same straight line along the arrangement direction of the ion source sets 205 (arrangement direction of ion sources on the same straight line). The irradiation surface 190 is distributed uniformly over the entire surface by the substrate being slid (linear motion, reciprocating motion). In FIG. 73, the distance between ion sources arranged on the same straight line and adjacent to each other among a plurality of ion sources is set in such a way that the distribution of the ion beam irradiation surfaces 190 becomes linear and uniform.

As described above, it is preferable to set the direction of incidence of an ion beam as a direction along the arrangement of a plurality of MTJ elements to be formed on the substrate from the viewpoint of supplying an ion beam to a space between MTJ elements to be formed.

(11) Movement of the Substrate During Irradiation of an Ion Beam

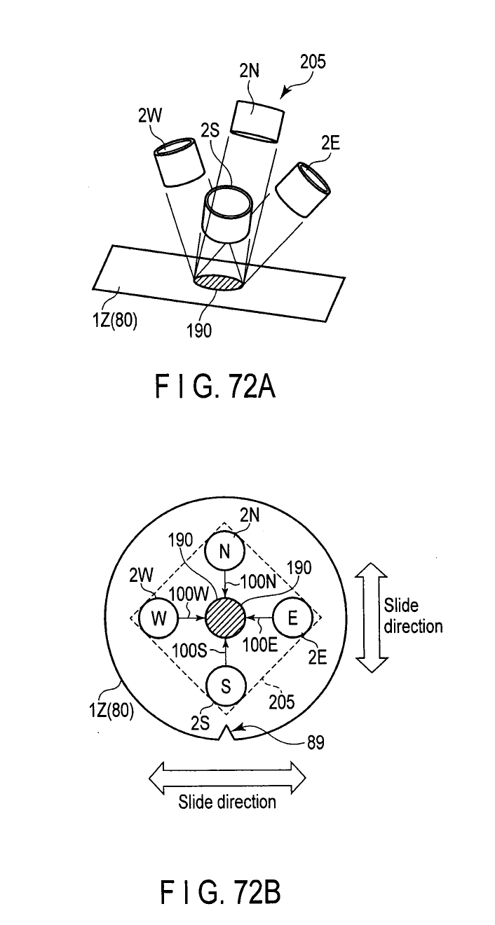

The movement of the substrate during irradiation of an ion beam will be described by using FIG. 74.

An ion beam may be irradiated while the substrate is moved during processing of the processed layer.

The movement of the substrate during irradiation of an ion beam is not limited to movement in a certain direction. The substrate may be irradiated with an ion beam while a motion combining movement along a certain direction (for example, the X direction) and movement along a direction (for example, the Y direction) crossing the certain direction is provided to the substrate.

FIG. 74 is a schematic plan view illustrating setting conditions for movement of the substrate during irradiation of an ion beam.

For example, as shown in FIG. 74, two element arrangement directions (U direction, V direction) of a plurality of MTJ elements in a certain region are set so as to be parallel to the geometrical arrangement of the ion sources 2E, 2N, 2S, 2W in an ion source set including four ion sources just as shown in FIG. 72B. Only one ion source set is schematically shown in FIG. 74, but a plurality of ion source sets are provided on the substrate 80 for irradiation of an ion beam.

When, for example, the position of the notch (or orientation flat) 89 of the substrate 80 is the 6 o'clock direction, masks to form MTJ elements (a plurality of MTJ elements to be formed) are arranged on respective predetermined regions (memory cell arrays) of the substrate 80 in a direction (V direction) parallel to the direction along 0 o'clock to 6 o'clock of the substrate 80 and a direction (U direction) parallel to the direction along 3 o'clock to 9 o'clock of the substrate.

Then, the ion sources 2N, 2S that irradiated an ion beam from the 0 o'clock and 6 o'clock directions of the substrate 80 are arranged along the V direction as the arrangement direction of MTJ elements and the ion sources 2E, 2W that irradiate an ion beam from the 3 o'clock and 9 o'clock directions of the substrate 80 are arranged along the U direction as the arrangement direction of MTJ elements.

Thus, the substrate 80 is rotated counterclockwise (or clockwise) to be set to an angle β₁ with respect to the initial state (0°) of the substrate installation by a substrate installation stage (not shown) in a direction parallel to the substrate surface so that the geometrical arrangement of the ion sources 2E, 2N, 2S, 2W and the arrangement direction of MTJ elements to be formed match.

If, for example, the direction orthogonal to the arrangement direction of irradiation surfaces (straight line EL connecting center points of the irradiation surfaces 190) during irradiation of an ion beam is defined as the “Z direction”, the angle β₁ is an angle formed by the U direction as the arrangement direction of MTJ elements (direction parallel to the 3 o'clock direction—9 o'clock direction) and the Z direction.

The substrate is slid (reciprocating motion, translational motion) above the ion sources by a certain stroke length in a direction (X direction) parallel to the U direction as the arrangement direction of MTJ elements and a direction (Y direction) parallel to the V direction as the arrangement direction of MTJ elements during irradiation of the processed layer with an ion beam. The operation of moving (reciprocation, translation) the substrate above a plurality of ion source sets may be called a scan (a traverse).

The movement stroke length of the substrate in the X direction is denoted by “Sx”. The substrate stroke length in the Y direction orthogonal to the X direction in a direction parallel to the substrate surface is denoted by “Sy”. The diameter of the substrate 80 is denoted by “d”.

The substrate 80 is reciprocated (linear motion) in the X direction as the movement direction (slide direction, scan direction) of the substrate by a length satisfying Sx>(d/cos β₁) as the relationship between the diameter d and the stroke length Sx in the X direction.

Simultaneously with the movement of the substrate in the X direction, the substrate 80 is reciprocated in the Y direction as the movement direction by the stroke length Sy in the Y direction.

The pitch of a plurality of irradiation surfaces formed on the substrate 80 by the four ion sources 2E, 2N, 2S, 2W in an ion source set is set as “PL”. The straight line connecting center points of the irradiation surfaces 190 is denoted by “EL” and the straight line corresponding to the arrangement direction of MTJ elements in a direction from 0 o'clock to 6 o'clock of the substrate 80 is denoted by “VL”. The angle formed by the straight line EL and the straight line V1 is denoted by “β₂”. The stroke length Sy in the Y direction (V direction) preferably satisfies the relation Sy>(0.5·PL·sin β₂) including the pitch PL and the angle β₂.

The frequency (reciprocation count) of sliding (linear motion, reciprocating motion, scan) of the substrate 80 along the X direction is denoted by “Cx” and the frequency of reciprocating motion of the substrate along the Y direction is denoted by “Cy”. That the frequencies Cx, Cy in the X direction and Y direction satisfy the relation Cx>Cy and the frequency Cx and the frequency Cy do not have a multiple relation is preferable as conditions for performing uniform etching of a processed layer (MTJ element).

If, for example, the frequency of the reciprocating motion in the X direction is 2 Hz, it is preferable to set the frequency of the reciprocating motion in the Y direction to values such as 0.3 Hz, 0.6 Hz, 0.7 Hz, 0.9 Hz and so on.

Incidentally, the angle β₁ may be changed by rotating the substrate 80 during irradiation of an ion beam.

Under such setting conditions, processing uniformity of an MTJ element can be improved by moving the substrate during irradiation of an ion beam.

(12) Configuration Example of Etching Apparatus Using a Plurality of Ion Source Sets

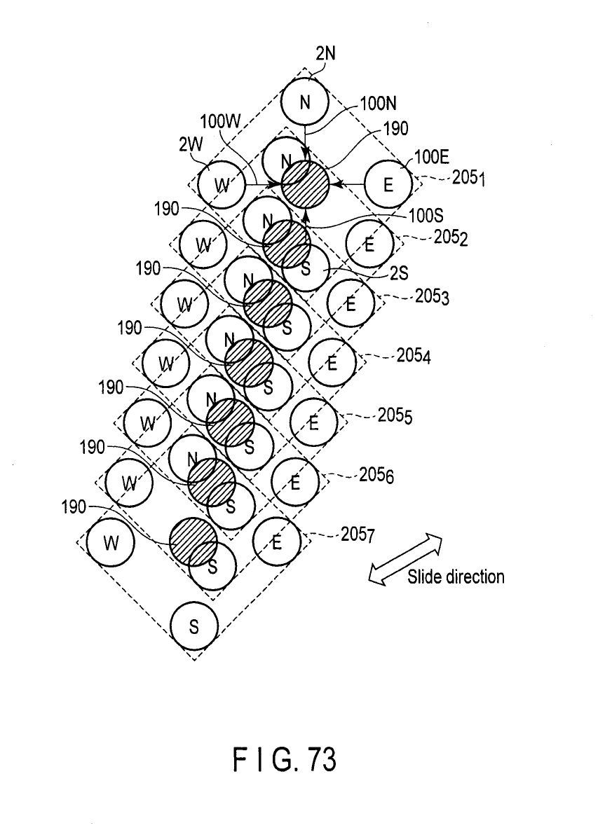

A configuration example of the etching apparatus using a certain number of ion source sets will be described by using FIGS. 75 to 79.

FIG. 75 is a diagram showing an example of layout of a plurality of ion sources in an ion source set.

In FIG. 75, the four ion sources 2E, 2N, 2S, 2W in the ion source set 205 irradiate the substrate with the ion beams 100E, 100N, 100S, 100W from directions antiparallel to each other to form the irradiation surface 190 on the substrate. The ion source set 205 shown in FIG. 75 is used as the basic configuration of an etching apparatus (ion beam generator, ion source group).

A distance LA between the ion source 2N arranged in the 0 o'clock direction of the substrate and the ion source 2S arranged in the 6 o'clock direction of the substrate is substantially the same as a distance LB between the ion source 2E arranged in the 3 o'clock direction of the substrate and the ion source 2W arranged in the 9 o'clock direction of the substrate.

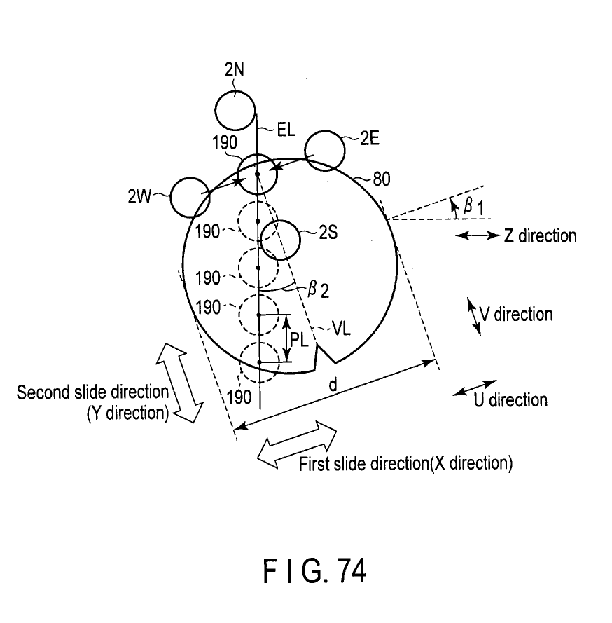

FIGS. 76A and 76B are plan views showing the configuration of an etching apparatus configured by using a plurality of ion source sets.

In FIG. 76A, a plurality (for example, three) of the ion source sets 205₁, 205₂, 205₃ is arranged along a certain direction.

Ion sources irradiating ion beams from the same azimuth are arranged on the same straight line.

In FIG. 76A, for example, ion sources 2N₁, 2N₂, 2N₃ irradiating ion beams from the 0 o'clock direction of the substrate and ion sources 2S₁, 2S₂, 2S₃ irradiating ion beams from the 6 o'clock direction of the substrate are arranged on the same straight line.

As shown in FIG. 76A, a predetermined number of ion source sets can be arranged in the etching apparatus so that an ion beam from each direction is irradiated on the irradiation surface of the substrate.

FIG. 76B shows an example in which a plurality of ion source sets are arranged in a different layout from the layout in FIG. 76A.

As shown in FIG. 76B, a plurality (for example, four) of ion source sets 205₁, 205₂, 205₃, 205₄ may be arranged in a zigzag form in the etching apparatus.

For example, as described with reference to FIG. 74, the substrate moves in a slide direction (X direction/Y direction) above a plurality of the ion source sets 205 arranged along a certain direction (position in a direction perpendicular to the substrate surface) shown in FIGS. 76A and 76B during processing of the processed layer by an ion beam.

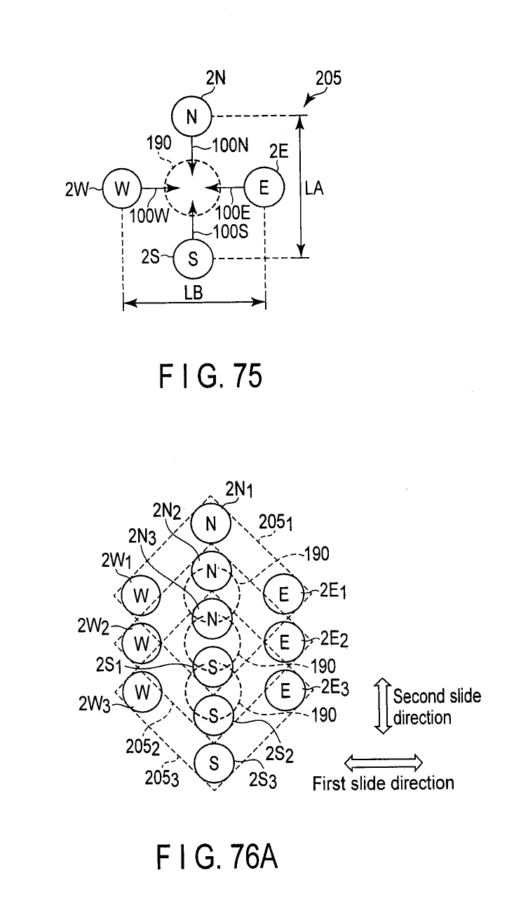

FIGS. 77A and 77B are plan views showing the configuration of the etching apparatus configured by using a plurality of ion source sets.

As shown in FIG. 77A, the three ion source sets 205₁, 205₂, 205₃ are provided in an etching apparatus. The ion source sets 205₁, 205₂, 205₃ in FIG. 77A may be laid out so that the ion source sets 205₁, 205₂, 205₃ are arranged at respective vertices of a triangle.

As shown in FIG. 77B, the ion source sets 205₁, 205₂, 205₃, 205₄ may be laid out so that the four ion source sets 205₁, 205₂, 205₃, 205₄ are arranged at respective vertices of a quadrangle.

FIG. 77C is a plan view schematically showing the motion given to the substrate during irradiation of an ion beam by the etching apparatus (a plurality of ion source sets) in FIGS. 77A and 77B.

In-plane uniformity of a processed layer by etching can be improved by processing the processed layer by using an ion beam while the substrate 80 is revolved by a substrate rotation mechanism (substrate installation stage) above the ion source sets 205 (position in a direction perpendicular to the substrate surface) in FIGS. 77A and 77B. At this point, the substrate motion is set so that an ion beam is incident along the arrangement direction of MTJ elements to be formed (mask arrangement direction) without the rotation of the substrate 80 (without changing the orientation of the notch 89 of the substrate 80). Accordingly, an adverse effect of etching due to a region to become a shadow of an MTJ element for an ion beam can be minimized.

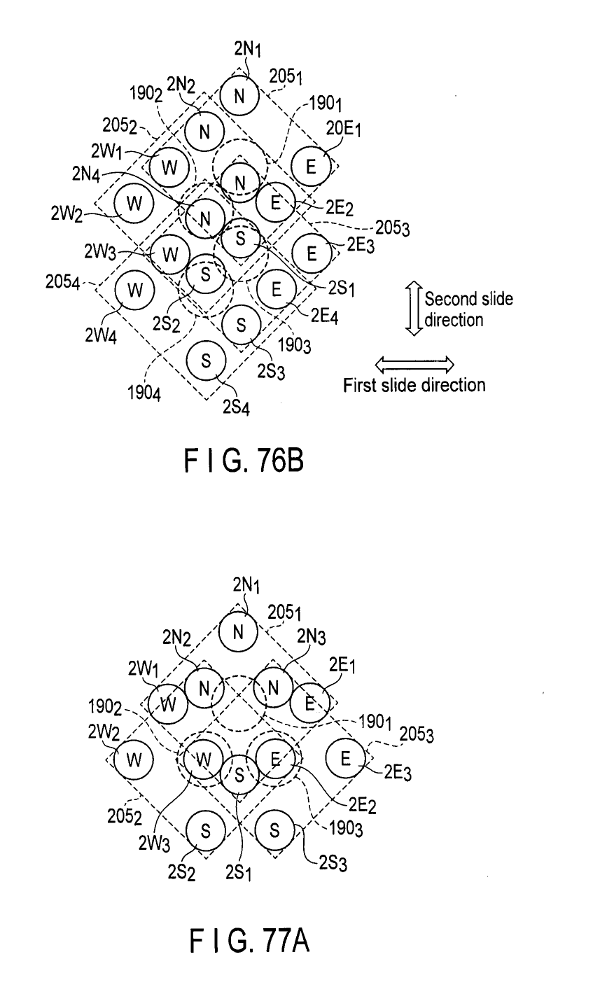

FIG. 78 is a diagram showing an example of layout of ion sources in an ion source set.

In FIG. 78, that an ion source set 206 contains four ion sources as a basic set is the same as the example shown in FIG. 75. However, the distance between two ion sources opposite to each other across an irradiation surface is different between ion sources in directions crossing each other.

A distance LC between the ion source 2N arranged in the 0 o'clock direction of the substrate and the ion source 2S arranged in the 6 o'clock direction of the substrate is shorter than a distance LD between the ion source 2E arranged in the 3 o'clock direction of the substrate and the ion source 2W arranged in the 9 o'clock direction of the substrate.

In the ion source set 206 in FIG. 78, like the ion source set 205 in FIG. 75, the direction (azimuth) in which an ion beam is incident with respect to the irradiation surface of the substrate is rotated by 90° for each of the ion sources 2E, 2N, 2S, 2W.

In the ion source set 206 in FIG. 78, the incident angle of the ion beams 100N, 100S on the substrate of the ion sources 2N, 2S arranged in the 0 o'clock direction and the 6 o'clock direction of the substrate is different from the incident angle of the ion beams 100E, 100W on the substrate of the ion sources 2E, 2W arranged in the 3 o'clock direction and the 9 o'clock direction of the substrate. For example, the incident angle of the ion beams 100E, 100W on the substrate of the ion sources 2E, 2W arranged in the 3 o'clock direction and the 9 o'clock direction of the substrate is larger than the incident angle of the ion beams 100N, 100S on the substrate of the ion sources 2N, 2S arranged in the 0 o'clock direction and the 6 o'clock direction of the substrate.

Incidentally, the incident angle of the ion beam 100N of the ion source 2N arranged in the 0 o'clock direction of the substrate is the same as the incident angle of the ion beam 100S of the ion source 2S arranged in the 6 o'clock direction of the substrate. Also, the incident angle of the ion beam 100E of the ion source 2E arranged in the 3 o'clock direction of the substrate is the same as the incident angle of the ion beam 100W of the ion source 2W arranged in the 9 o'clock direction of the substrate.

By setting the above directions of incidence and incident angles of ion beams, etching of a processed layer (MTJ element) by the ion beams 100E, 100N, 100S, 100W of the ion source set in FIG. 78 is performed.

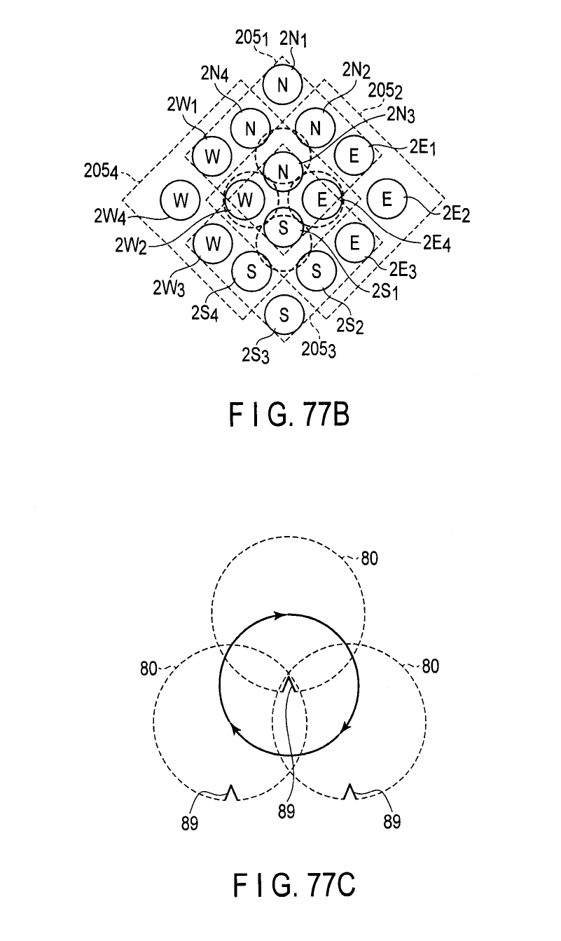

FIGS. 79A to 79C are diagrams schematically showing the structure of an MTJ element formed by ion beams from the ion source set in FIG. 78. FIG. 79A is a plan view schematically showing the structure of an MTJ element formed by ion beams from the ion source set in FIG. 78. FIG. 79B is a schematic sectional view of the MTJ element along line E-E in FIG. 79A. FIG. 79C is a schematic sectional view of the MTJ element along line F-F in FIG. 79A.

As shown in FIGS. 79A to 79C, an MTJ element 1E includes at least two magnetic layers 16A, 16B and the tunnel barrier layer 12 between the two magnetic layers 16A, 16B.

When, like the ion source set 206 in FIG. 78, the processed layer are simultaneously irradiated with ion beams having different incident angles to form an MTJ element, as shown in FIG. 79A, the MTJ element 1E has an elliptic plane shape.

As shown in the MTJ element 1E of FIGS. 79A to 79C, the taper angle of a different magnitude is formed on the side face of the MTJ element.

As shown in, for example, FIGS. 79B and 79C, a taper angle βₓ on the side face of the MTJ element 1E on the side on which the incident angle of an ion beam of the ion source set in FIG. 78 is larger (for example, the direction along line E-E in FIG. 79A) is smaller than a taper angle β_{y} on the side face of the MTJ element 1E on the side on which the incident angle of an ion beam of the ion source set in FIG. 78 is smaller (for example, the direction along line F-F in FIG. 79A). The taper angle on the side face of an MTJ element is an angle formed by the inclined side face of the MTJ element and the bottom surface (direction parallel to the substrate surface) of the MTJ element.

When, for example, an MTJ element having a diameter of 20 nm or less, which is smaller than the activation volume of a magnetic body, is formed, compared with STT-MRAM using an MTJ element having shape anisotropy processed by general etching, the distribution of a reversal threshold current of an MTJ element can be provided by a smaller STT-MRAM by an MTJ element having shape anisotropy as shown in FIGS. 79A to 79C being formed using an etching method inhibiting reattachments from being formed on the side face of the MTJ element like in the present embodiment.

(13) Arrangement Example of an Ion Source Set in Consideration of The Arrangement of MTJ Elements

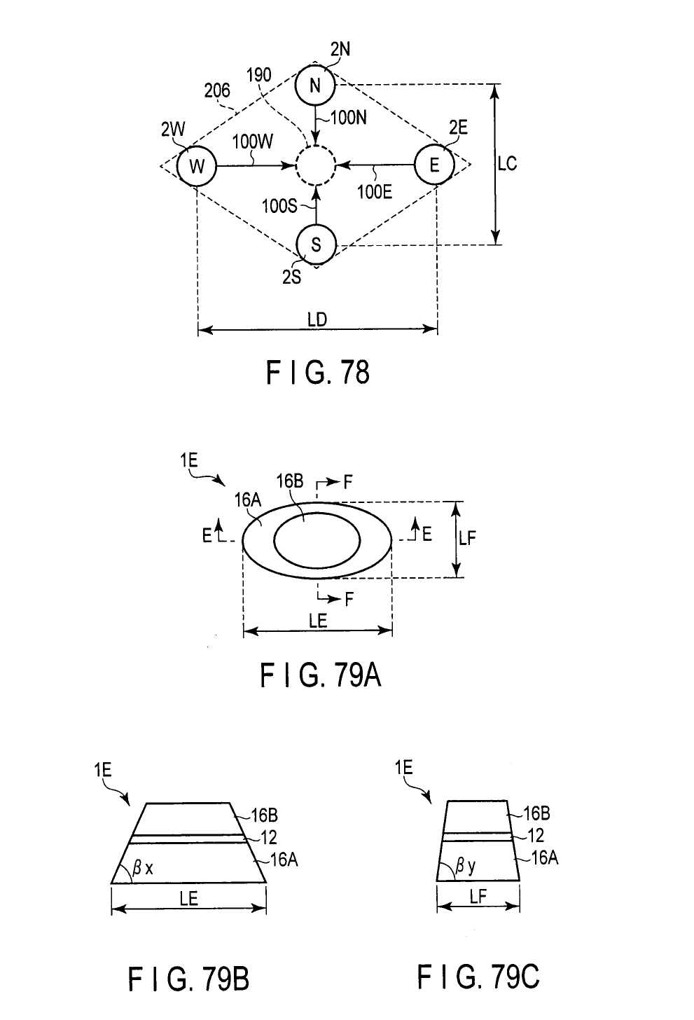

The configuration of an ion source set corresponding to the arrangement of a plurality of MTJ elements on the substrate will be described by using FIGS. 80 to 85.

<Arrangement of MTJ Element Group with a Plurality of Rotational Symmetries>

The arrangement of ion sources (ion source set) when a plurality of magnetoresistive effect elements (MTJ elements) in a certain region has a rotationally symmetric layout will be described below. n-fold rotational symmetry means symmetry in which when a figure (layout) is rotated around some point (axis) by an angle 360°/n (n is an integer equal to 2 or greater), the rotated figure overlaps with the original figure (the figure before the rotation).

FIG. 80 shows the layout of a mask to form MTJ elements when a plurality of MTJ elements (hereinafter, also referred to as an MTJ element group) are arranged in 3-fold rotational symmetry.

As shown in FIG. 80, a plurality of masks 13 are formed on the processed layer 1X of the substrate 80 so as to have a predetermined layout. In FIG. 80, the masks 13 are formed in predetermined positions at predetermined intervals so that a 3-fold rotational symmetric layout is formed.

As shown in FIG. 80, the layout of the masks 13 has a 3-fold rotational symmetric layout. When the layout of the masks 13 in FIG. 80 is rotated around a certain center by an angle of 120°, the rotated layout of the masks 13 overlaps with the original layout.

In this case, the arrangement direction set for each 120° of a plurality of MTJ elements (masks to process MTJ elements) having 3-fold rotational symmetry is defined as the U direction, V direction, and W direction. Ion beams 100U, 100V, 100W are irradiated on the processed layer 1X from the U direction, V direction, and W direction set for each 120° respectively.

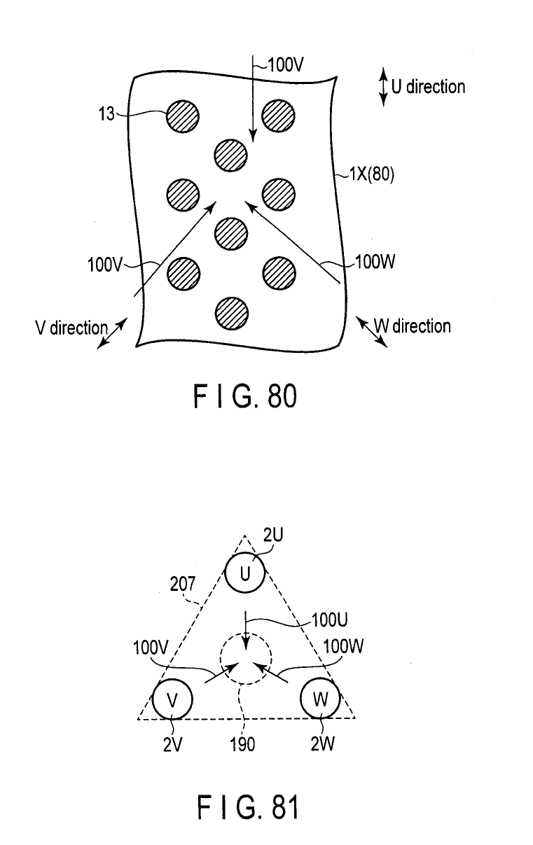

FIG. 81 is a diagram showing the layout of ion sources in an ion source set to form an MTJ element group of a 3-fold rotational symmetric layout.

When a plurality of MTJ elements having a 3-fold rotational symmetric layout are formed, an ion source set 207 includes three ion sources 2U, 2V, 2W.

When the azimuth of an ion beam from the ion source 2U with respect to a certain irradiation surface is 0°, the ion sources 2U, 2V, 2W are arranged at respective vertices of a triangle by shifting the position by 120° each time so that the ion beams 100U, 100V, 100W are shown from, for example, the 0 o'clock position (azimuth of 0°), 4 o'clock position (azimuth of 120°), and 8 o'clock position (azimuth of 240°) of the substrate.

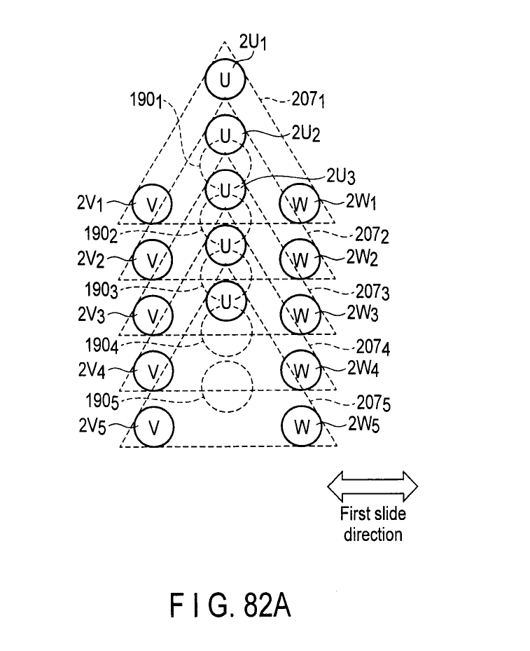

FIG. 82A is a plan view showing a layout example of a plurality of ion source sets to form an MTJ element group of a 3-fold rotational symmetric layout.

As shown in FIG. 82A, a plurality (for example, five) of ion source sets 207₁, 207₂, 207₃, 207₄, 207₅ shown in FIG. 81 are arranged on the same straight line in an etching apparatus.

In this case, ion sources irradiating ion beams on irradiation surfaces 190₁, 190₂, 190₃, 190₄, 190₅ on the substrate from the same direction (azimuth) are aligned in a direction parallel to the arrangement direction of the ion source sets 207₁, 207₂, 207₃, 207₄, 207₅. That is, ion sources 20₁, 20₂, 20₃, 20₄, 20₅ irradiating the ion beam 100U on the substrate from the U direction (for example, 0 o'clock direction of the substrate, azimuth of 0°) are arranged on the same straight line. Ion sources 2W₁, 2W₂, 2W₃, 2W₄, 2W₅ irradiating the ion beam 100W on the substrate from the W direction (for example, 4 o'clock direction of the substrate, azimuth of 120°) are arranged on the same straight line. Ion sources 2V₁, 2V₂, 2V₃, 2V₄, 2V₅ irradiating the ion beam 100V on the substrate from the V direction (for example, 8 o'clock direction of the substrate, azimuth of 240°) are arranged on the same straight line.

Accordingly, the irradiation surfaces 190₁, 190₂, 190₃, 190₄, 190₅ formed of each ion source set are arranged on the same straight line to form a linear etching region (region in which irradiation surfaces are connected) in an etching apparatus.

In the etching apparatus in FIG. 82A, as described by using FIG. 74, the substrate is irradiated with an ion beam while the substrate is moved (reciprocated) to form an MTJ element from a processed layer on the substrate.

Ion sources irradiating ion beams from the same direction may not be arranged on the same straight line. As shown in FIG. 82B, a plurality of ion source sets and ion sources may be arranged in a zigzag form.

FIG. 82B shows an example in which a plurality of ion source sets shown in FIG. 81 are arranged in a zigzag form.

In the example shown in FIG. 82B, the position of the odd-numbered ion source and the position of the even-numbered ion source are arranged by a predetermined distance being shifted in alternate directions in a direction parallel to (direction orthogonal to) the arrangement direction of the ion source sets 207₁, 207₂, 207₃, 207₄, 207₅ for each ion source of the five ion source sets 207₁, 207₂, 207₃, 207₄, 207₅.

A plurality of odd-numbered ion sources are aligned on the same straight line and a plurality of even-numbered ion sources are aligned on the same straight line. The directions in which odd-numbered and even-numbered ion sources are arranged are parallel to the arrangement direction of the ion source sets 207₁, 207₂, 207₃, 207₄, 207₅.

In the example shown in FIG. 82B, the position of two ion sources among five ion sources that irradiate ion beams on the substrate from the same direction is shifted, but the position of only one ion source may be shifted or the position of three ion sources or more may be shifted.

<When the Arrangement of an MTJ Element Group has a Plurality of Rotational Symmetries>

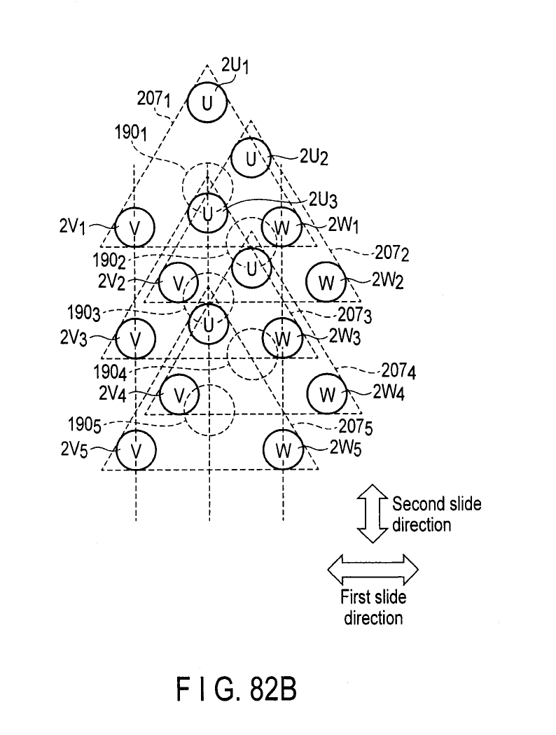

The arrangement of ion sources when the arrangement of an MTJ element group has a plurality of rotational symmetries will be described with reference to FIGS. 83 to 85.

As shown in FIG. 83, the basic grid of arrangement of MTJ elements (masks 13) in, for example, an MTJ element group is a rhombic layout.

The masks 13 are arranged on the processed layer 1X so that, like in FIG. 83, an MTJ element group arranged in a rhombic basic grid is formed. The processed layer 1X is irradiated with ion beams 100T, 100U, 100V, 100W from four directions along each arrangement direction of MTJ elements.

The angle β_{UV} formed by the U direction and the V direction as arrangement directions of MTJ elements is 120°.

The angle formed by the W direction and the T direction as arrangement directions of MTJ elements is 120°.

The angle β_{UT} formed by the U direction and the T direction as arrangement directions of MTJ elements is 60°. The angle formed by the W direction and the T direction as arrangement directions of MTJ elements is 60°.

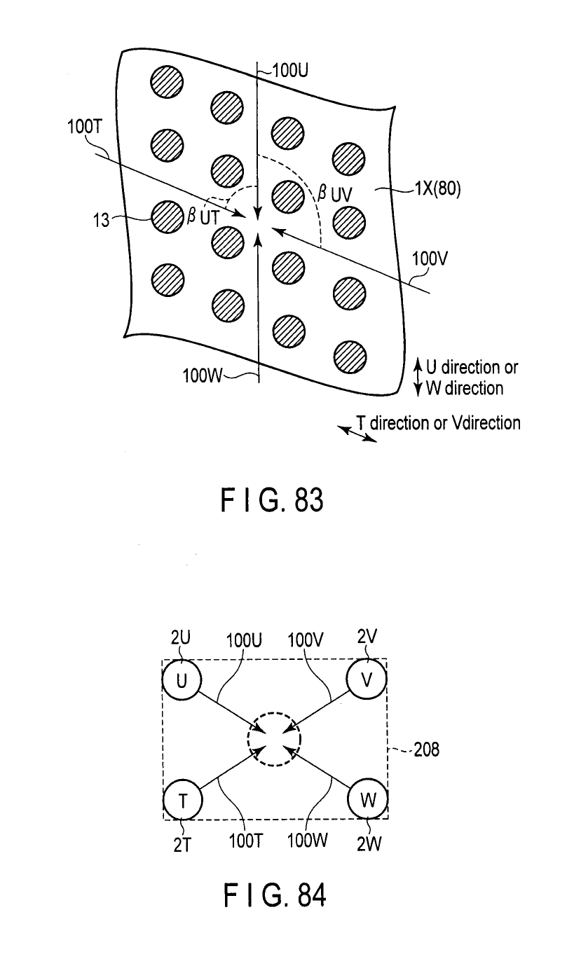

FIG. 84 is a diagram showing the layout of ion sources in an ion source set to form an MTJ element group having a rhombic layout as the basic grid.

An ion source set 208 includes four ion sources; 2T, 2U, 2V, 2W. The ion source set 208 has a rectangular plane shape. The four ion sources 2T, 2U, 2V, 2W in the ion source set 208 are arranged in respective positions of vertices of a rectangle.

The ion source 2U irradiates the substrate with the ion beam 100U from the U direction (here, the 0 o'clock direction). The ion source 2V irradiates the substrate with the ion beam 100V from the V direction (4 o'clock direction). The ion source 2W irradiates the substrate with the ion beam 100W from the W direction (6 o'clock direction). The ion source 2T irradiates the substrate with the ion beam 100T from the T direction (10 o'clock direction). Thus, the directions of ion beams from four ion sources match respective arrangement directions of MTJ elements (masks). For example, if the position of the notch of the substrate is the 6 o'clock direction, the substrate is irradiated with an ion beam from the ion source 2U from the 0 o'clock direction of the substrate.

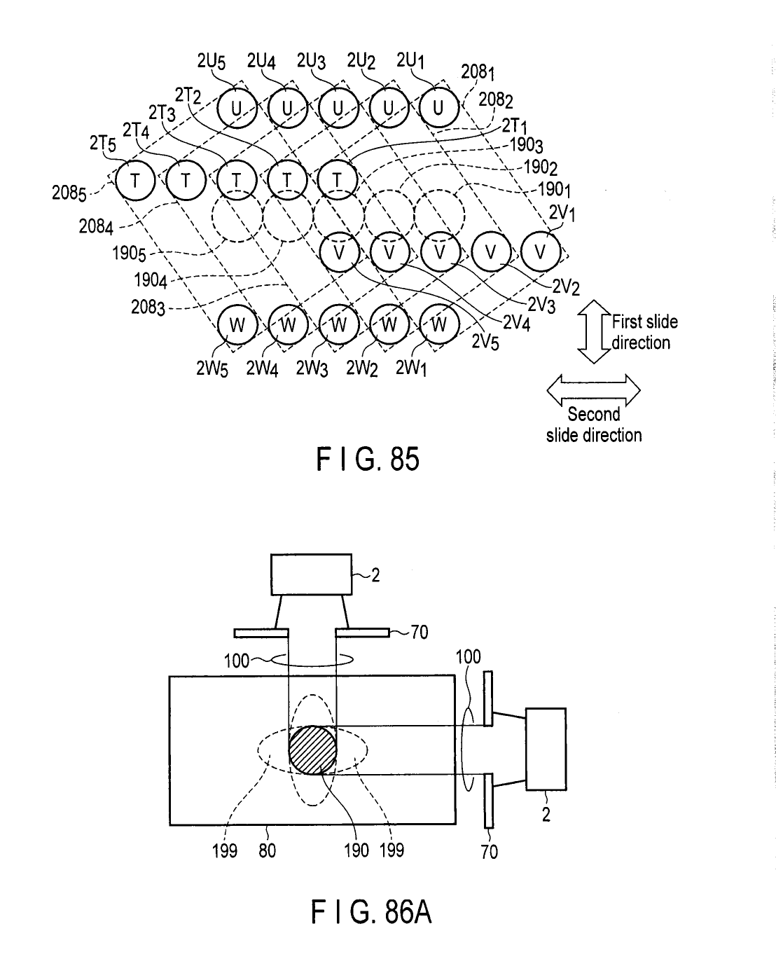

FIG. 85 is a plan view showing a layout example of a plurality of ion source sets to form an MTJ element group having a rhombic layout as the basic grid.

For example, five ion source sets 208₁, 208₂, 208₃, 208₄, 208₅ are arranged linearly in the etching apparatus.

Ion sources 2U₁, 2U₂, 2U₃, 2U₄, 2U₅ irradiating the ion beam 100U on the substrate from the U direction (for example, 0 o'clock direction of the substrate) are arranged on the same straight line. Ion sources 2W₁, 2W₂, 2W₃, 2W₄, 2W₅ irradiating the ion beam 100W on the substrate from the W direction (for example, 6 o'clock direction of the substrate) are arranged on the same straight line. Ion sources 2V₁, 2V₂, 2V₃, 2V₄, 2V₅ irradiating the ion beam 100V on the substrate from the V direction (for example, 4 o'clock direction of the substrate) are arranged on the same straight line. Ion sources 2T₁, 2T₂, 2T₃, 2T₄, 2T₅ irradiating the ion beam 100T on the substrate from the T direction (for example, 10 o'clock direction of the substrate) are arranged on the same straight line. The arrangement directions of the ion sources are parallel to each other.

The rows of the ion sources 2V₁, 2V₂, 2V₃, 2V₄, 2V₅, 2T₁, 2T₂, 2T₃, 2T₄, 2T₅ irradiating the ion beams 100V, 100T from the V direction and the T direction are arranged between the rows of the ion sources 2U₁, 2U₂, 2U₃, 2U₄, 2U₅, 2W₁, 2W₂, 2W₃, 2W₄, 2W₅ irradiating the ion beams 100U, 100W from the U direction and the W direction.

Accordingly, a plurality of irradiation surfaces formed on the substrate are aligned on the same straight line to form a linear etching region. For example, as described by using FIG. 74, an MTJ element may be formed by processing the processed layer using an ion beam while moving (sliding) the substrate.

When, as described by using FIGS. 80 to 85, a plurality of MTJ elements is laid out so as to have a rotational symmetric layout, an MTJ element can be formed by at least an ion source set including a plurality of ion sources irradiating ion beams on the substrate from mutually different directions so as to correspond to a rotational symmetric layout.

(14) Correction of the Processing Shape

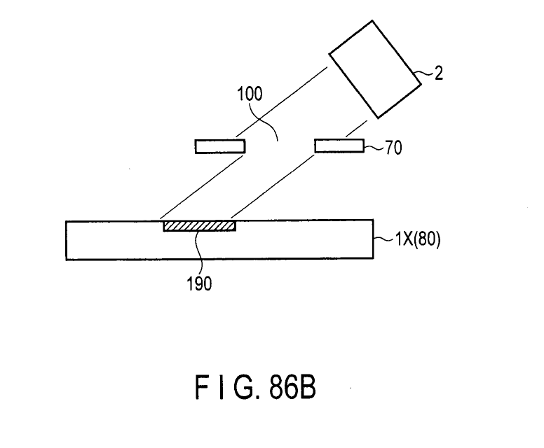

A correction of the processing shape of a processed layer when the processed layer on the substrate is processed by ion beams from a plurality of ion sources will be described by using FIGS. 86A and 86B.

In an ion source whose ion beam emission port has a circular plane shape, the irradiation shape of an ion beam on the substrate may be elliptic in accordance with the dispersion of the ion beam and the distance between the ion source and substrate. As a result, the processing shape of the processed layer on the substrate may be elliptic.

Two ion sources irradiate the substrate with ion beams having a certain ion beam incident angle from directions orthogonal to each other.

When elliptic irradiation surfaces are formed on the substrate by two ion beams irradiated from directions orthogonal to each other, a region where irradiation surfaces (ion beams) overlap and a region where irradiation surfaces do not overlap are formed on the substrate (processed layer). For example, a region where irradiation surfaces do not overlap arises at an end in the major axis direction of an ellipse.

If one of ion beams from two ion sources is strong, processing shapes of MTJ elements may be non-uniform. Thus, it is desirable to suppress an occurrence of a region where ion beams do not overlap to form an MTJ element in a uniform shape.

FIG. 86A is a plan view schematically showing the structure of an ion source including a configuration to correct the processing shape of the processed layer and the plane shape of an ion beam on the substrate. FIG. 86B is a sectional view schematically showing the structure of the ion source including the configuration to correct the processing shape of the processed layer.

As shown in FIGS. 86A and 86B, the substrate 80 is irradiated with the ion beam 100 at a predetermined incident angle from a certain direction. The irradiation surface 190 is formed on the surface of the processed layer 1X of the substrate 80.

For example, as shown in FIGS. 86A and 86B, the collimator 70 having a circular opening (or a through hole) is inserted between the ion source 2 and the substrate 80 (substrate stage 800).

The spread (dispersion) of the ion beam 100 is suppressed by the ion beam 100 being passed through the circular opening of the collimator 70 inserted between the ion source 2 and the substrate 80.

As a result, as shown in FIG. 86A, an elliptic shape 199 of a projected ion beam is corrected by the collimator 70. The circular irradiation surface 190 created by the corrected ion beam 100 is formed on the processed layer 1X of the substrate 80.

Accordingly, regions on the processed layer 1X where irradiation surfaces of the ion beams 100 do not overlap are removed and the circular irradiation surface 190 created by regions where the ion beams 100 overlap is formed on the processed layer 1X of the substrate 80.

Therefore, uniformity of etching by an ion beam can be improved by inserting the collimator 70 between the ion source 2 and the substrate 80.

### [E] Others

A magnetoresistive effect element formed by the manufacturing method and manufacturing apparatus according to the above embodiments may also be applied to other magnetoresistive memories than MRAM. A magnetoresistive memory using a magnetoresistive effect element formed by the manufacturing method and manufacturing apparatus according to the above embodiments is used as an alternative memory such as a DRAM and SRAM.

A magnetoresistive effect element formed by the manufacturing method of a magnetoresistive effect element and manufacturing apparatus of a magnetoresistive effect element described in the above embodiments may be used for a magnetic head of a hard disk drive.

A bit patterned media may be formed by using the manufacturing method of a magnetoresistive effect element and manufacturing apparatus of a magnetoresistive effect element described in the above embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a magnetoresistive effect element comprising:
forming a laminated structure on a substrate, the laminated structure including a first magnetic layer having a variable magnetization direction, a second magnetic layer having an invariable magnetization direction, and a non-magnetic layer between the first and second magnetic layers;
forming a first mask layer having a predetermined plane shape on the laminated structure; and
processing the laminated structure based on the first mask layer by using an ion beam whose solid angle in a center of the substrate is 10° or more.

2. The method according to claim 1, wherein
the magnetoresistive effect element having a maximum dimension of 30 nm or less in a direction parallel to a surface of the substrate is formed by using the ion beam including 10% or more, of ions having an energy of 100 eV or less to process the laminated structure.

3. The method according to claim 1, wherein
the ion beam is generated by using an ion source including a cylindrical plasma generating container having plasma generated therein and having an opening from which the ion beam is emitted and a magnetic field source installed on a center axis of the plasma generating container to generate a first magnetic field,
the plasma to generate the ion beam is generated in the first magnetic field,
the first magnetic field includes a first magnetic field component in a first direction along an emission direction of the ion beam and a second magnetic field component in a second direction perpendicular to the emission direction of the ion beam,
the first magnetic field component on the center axis of the plasma generating container has a stronger magnetic field strength in the center of the plasma generating container than the magnetic field strength in the opening, and
the second magnetic field component in the opening of the plasma generating container has a weaker magnetic field strength in the center of the opening than the magnetic field strength at an edge of the opening.

4. The method according to claim 1, wherein
the ion beam is generated by plasma in a ring shape in the first magnetic field.

5. The method according to claim 1, wherein
the ion beam is generated from plasma and
the laminated structure is irradiated with the ion beam after passing through a clockwise second magnetic field when the substrate is viewed from a region where the plasma is generated.

6. The method according to claim 1, wherein
the ion beam is generated by one or more grid ion source.

7. The method according to claim 1, wherein
the laminated structure is irradiated with an ionized cluster simultaneously with the ion beam or alternately.

8. The method according to claim 1, wherein
the non-magnetic layer is formed on the second magnetic layer;
the first magnetic layer is formed on the non-magnetic layer;
the first mask layer is formed on the first magnetic layer;
the first magnetic layer is etched based on the first mask layer;
a protective film is formed on a side face of the etched first magnetic layer;
and after the protective film being formed, the non-magnetic layer and the second magnetic layer is etched by using the first magnetic layer as a mask and is irradiate with the ion beam so that the protective film remains on the side face of the first magnetic layer.

9. A manufacturing apparatus of a magnetoresistive effect element comprising:
a substrate holding unit that holds a substrate on which a laminated structure to form the magnetoresistive effect element is provided; and
at least one ion source having an opening provided on a side of the substrate holding unit, the ion source generating an ion beam irradiated on the laminated structure via the opening in such a way that a solid angle of the ion beam in a center of the substrate is 10° or more.

10. The apparatus according to claim 9, wherein
the ion source generates the ion beam including 10% or more of ions having an energy of 100 eV or less.

11. The apparatus according to claim 9, wherein
the ion source includes a cylindrical plasma generating container having plasma generated therein and having the opening from which the ion beam is irradiated and a magnetic field source installed on a center axis of the plasma generating container to generate a first magnetic field,
the ion beam is generated from the plasma generated in the first magnetic field,
the first magnetic field includes a first magnetic field component in a first direction along an emission direction of the ion beam and a second magnetic field in a second direction perpendicular to the emission direction of the ion beam,
the first magnetic field component on the center axis of the plasma generating container has a stronger magnetic field strength in the center of the plasma generating container than the magnetic field strength in the opening, and
the second magnetic field component in the opening of the plasma generating container has a weaker magnetic field strength in the center of the opening than the magnetic field strength at an edge of the opening.

12. The apparatus according to claim 9, further comprising
a first structure provided between the ion source and the substrate holding unit and through which the ion beam passes.

13. The apparatus according to claim 12, wherein
the first structure has a coiled shape extending along the emission direction of the ion beam.

14. The apparatus according to claim 12, wherein
the first structure includes a cylindrical partition wall extending along the emission direction of the ion beam.

15. The apparatus according to claim 12, wherein
the first structure includes a plurality of rings provided along the emission direction of the ion beam.

16. The apparatus according to claim 12, wherein
the first structure includes a magnetic field generator that generates a clockwise second magnetic field when the substrate is viewed from the ion source in the emission direction of the ion beam.

17. The apparatus according to claim 9, wherein
a plurality of the ion sources are provided for the substrate,
the plurality of the ion sources are laid out so that straight lines connecting the opening of each of the ion sources form polygon.

18. The apparatus according to claim 9, wherein
the substrate is irradiated with ion beams from mutually different directions by the plurality of the ion sources.
